(19) United States
(12) Patent Application Publication
(10) Pub. No.: US 2026/0262210 A1
(43) Pub. Date: Sep. 3, 2026

(54) Semiconductor Device And Method For Manufacturing The Semiconductor Device

(71) Applicant: Semiconductor Energy Laboratory Co., Ltd., Kanagawa-ken (JP)

(72) Inventors: Shunpei YAMAZAKI, Setagaya, Tokyo (JP); Tsutomu MURAKAWA, Isehara, Kanagawa (JP); Hitoshi KUNITAKE, Machida, Tokyo (JP); Hidekazu MIYAIRI, Hadano, Kanagawa (JP); Hiromi SAWAI, Kawasaki, Kanagawa (JP); Yuki OKAMOTO, Ebina, Kanagawa (JP); Shoki MIYATA, Atsugi, Kanagawa (JP)

(73) Assignee: Semiconductor Energy Laboratory Co., Ltd., Kanagawa-ken (JP)

(21) Appl. No.: 19/164,989

(22) PCT Filed: Mar. 11, 2024
(86) PCT No.: PCT/IB2024/052309

§ 371 Date: Sep. 12, 2025

(30) Foreign Application Priority Data
Mar. 17, 2023 (JP) 2023-042776
Mar. 17, 2023 (JP) 2023-042779

(51) Int. Cl. H10B 12/00; H10B 53/10; H10B 53/20; H10B 53/30; H10D 1/68; H10D 30/67

(52) U.S. Cl. CPC H10B 12/00; H10B 12/01; H10D 1/682; H10D 30/6728; H10D 30/6731; H10B 53/10; H10B 53/20; H10B 53/30

(57) ABSTRACT

A semiconductor device that can be miniaturized or highly integrated is provided, which includes a memory device, a sense amplifier, and a processing portion. The sense amplifier and the processing portion are placed on a first layer, and the memory device is placed on a second layer stacked over the first layer. The memory device includes first and second transistors and a capacitor, the second transistor and the capacitor are each provided over the first transistor to overlap therewith, and the second transistor is positioned diagonally above the first transistor. A source electrode and a drain electrode of each of the first and second transistors are provided at different levels with respect to a substrate surface to overlap with each other. A gate electrode of the first transistor has both a function of one of the source electrode and the drain electrode of the second transistor and a function of one electrode of the capacitor. A dielectric layer of the capacitor is provided over the gate electrode of the first transistor. Over the dielectric layer of the capacitor, the other electrode of the capacitor is provided apart from a gate electrode of the second transistor.

### TECHNICAL FIELD

One embodiment of the present invention relates to a semiconductor device. Another embodiment of the present invention relates to a memory device and a method for manufacturing a memory device. Another embodiment of the present invention relates to a transistor and a method for manufacturing a transistor. Another embodiment of the present invention relates to a capacitor and a method for manufacturing a capacitor. Another embodiment of the present invention relates to an electronic appliance.

Note that one embodiment of the present invention is not limited to the above technical field. Examples of the technical field of one embodiment of the present invention include a semiconductor device, a display device, a light-emitting device, a power storage device, a memory device, a lighting device, an input device (e.g., a touch sensor), an input/output device (e.g., a touch panel), an electronic appliance including any of them, a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also refers to all devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic appliance themselves are semiconductor devices and also include a semiconductor device.

### BACKGROUND ART

In recent years, development of semiconductor devices has been proceeding, and large scale integration circuits (LSI), for example, are used in the semiconductor devices. For example, central processing units (CPUs), memories, and the like are used in the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. As another example, Patent Document 2 discloses a memory device that can retain stored contents for a long time by utilizing the feature of the low leakage current of the transistor using an oxide semiconductor.

In recent years, demand for an integrated circuit with higher density has risen with reductions in size and weight of electronic appliances. In addition, the productivity of a semiconductor device including an integrated circuit is desired to be improved. For example, Patent Document 3 and Non-Patent Document 1 disclose a technique to obtain an integrated circuit with higher density by making a plurality of memory cells overlap with each other by stacking a first transistor using an oxide semiconductor film and a second transistor using an oxide semiconductor film.

Furthermore, by employing vertical transistors, an integrated circuit with higher density can be obtained. For example, Patent Document 4 discloses a vertical transistor in which a side surface of an oxide semiconductor is covered with a gate electrode with a gate insulating layer therebetween.

### Reference

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device, a memory device, or a transistor that can be miniaturized or highly integrated. Another object of one embodiment of the present invention is to provide a semiconductor device, a memory device, or a transistor with high reliability. Another object of one embodiment of the present invention is to provide a transistor with a high on-state current. Another object of one embodiment of the present invention is to provide a transistor, a memory device, or a semiconductor device with favorable electrical characteristics. Another object of one embodiment of the present invention is to provide an inexpensive semiconductor device or an inexpensive memory device. Another object of one embodiment of the present invention is to provide a semiconductor device or a memory device with low power consumption. Another object of one embodiment of the present invention is to provide a semiconductor device or a memory device with a high operation speed. Another object of one embodiment of the present invention is to provide a novel semiconductor device, a novel memory device, or a novel transistor.

Another object of one embodiment of the present invention is to provide a method for manufacturing a semiconductor device, a memory device, or a transistor that can be miniaturized or highly integrated. Another object of one embodiment of the present invention is to provide a method for manufacturing a semiconductor device, a memory device, or a transistor with high reliability. Another object of one embodiment of the present invention is to provide a method for manufacturing a transistor with a high on-state current. Another object of one embodiment of the present invention is to provide a method for manufacturing a transistor, a memory device, or a semiconductor device with favorable electrical characteristics. Another object of one embodiment of the present invention is to provide a method for manufacturing a semiconductor device or a memory device with high yield. Another object of one embodiment of the present invention is to provide a method for manufacturing a semiconductor device or a memory device with low power consumption. Another object of one embodiment of the present invention is to provide a method for manufacturing a semiconductor device or a memory device with a high operation speed. Another object of one embodiment of the present invention is to provide a method for manufacturing a novel semiconductor device, a novel memory device, or a novel transistor.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a semiconductor device including a first transistor, a second transistor, a capacitor, a first insulating layer, and a second insulating layer; the second transistor and the capacitor are each provided over the first transistor to overlap therewith; a source electrode and a drain electrode of each of the first transistor and the second transistor are positioned at different levels with respect to a substrate surface; the first insulating layer is provided between the source electrode and the drain electrode of the first transistor and includes a first opening reaching one of the source electrode and the drain electrode of the first transistor; the other of the source electrode and the drain electrode of the first transistor is provided over the first insulating layer; a semiconductor layer of the first transistor includes a region in contact with a top surface of the one of the source electrode and the drain electrode of the first transistor in the first opening, a side surface of the first insulating layer in the first opening, and a top surface of the other of the source electrode and the drain electrode of the first transistor; a gate insulating layer of the first transistor is provided over and in contact with the semiconductor layer of the first transistor; a gate electrode of the first transistor is provided over the gate insulating layer of the first transistor to include a region overlapping with the semiconductor layer of the first transistor and has a function of one of the source electrode and the drain electrode of the second transistor and a function of one electrode of the capacitor; the second insulating layer is provided between the source electrode and the drain electrode of the second transistor and includes a second opening reaching the gate electrode of the first transistor; the second opening is positioned diagonally above the first opening; the other of the source electrode and the drain electrode of the second transistor is provided over the second insulating layer; a semiconductor layer of the second transistor includes a region in contact with a top surface of the gate electrode of the first transistor in the second opening, a side surface of the second insulating layer in the second opening, and a top surface of the other of the source electrode and the drain electrode of the second transistor; a gate insulating layer of the second transistor is provided over and in contact with the semiconductor layer of the second transistor; a gate electrode of the second transistor is provided over the gate insulating layer of the second transistor to include a region overlapping with the semiconductor layer of the second transistor; a dielectric layer of the capacitor is provided over the gate electrode of the first transistor; and the other electrode of the capacitor includes a region overlapping with the gate electrode of the first transistor and is provided over the dielectric layer of the capacitor and apart from the second opening in a plan view.

In the above, at least one of the semiconductor layer of the first transistor and the semiconductor layer of the second transistor preferably contains a metal oxide.

In the above, it is preferable to include a region in which a side surface of the semiconductor layer of the first transistor is substantially aligned with a side surface of the other of the source electrode and the drain electrode of the first transistor, and a region in which a side surface of the semiconductor layer of the second transistor is substantially aligned with a side surface of the other of the source electrode and the drain electrode of the second transistor.

In the above, an end portion of the other electrode of the capacitor on a side not facing the first opening is preferably positioned outward from an end portion of the gate electrode of the first transistor.

In the above, the other electrode of the capacitor preferably includes a region overlapping with the top surface of the gate electrode of the first transistor to surround the second opening.

In the above, it is preferable that an end portion of the gate electrode of the first transistor be positioned inward from an end portion of the other of the source electrode and the drain electrode of the first transistor in a first direction, and include a region that includes a substantially flat top surface and is positioned outward from an end portion of the other of the source electrode and the drain electrode of the first transistor in a second direction that is a direction opposite to the first direction, and the second opening be provided to overlap with the region in a plan view.

In the above, the dielectric layer of the capacitor preferably contains any of an oxide containing any of aluminum, gallium, hafnium, tantalum, and zirconium, an oxide containing hafnium and zirconium, an oxide containing aluminum and hafnium, an oxynitride containing aluminum and hafnium, an oxide containing silicon and hafnium, an oxynitride containing silicon and hafnium, and a nitride containing silicon and hafnium.

In the above, the dielectric layer of the capacitor preferably contains any of hafnium oxide, zirconium oxide, lead titanate, barium strontium titanate, strontium titanate, lead zirconate titanate, strontium bismuth tantalate, bismuth ferrite, barium titanate, and any of these materials to which lanthanum or yttrium is added.

In the above, the first insulating layer and the second insulating layer each preferably contain any of silicon oxide, silicon oxynitride, silicon nitride oxide, polyester, polyolefin, polyamide, polyimide, polycarbonate, and acrylic.

Another embodiment of the present invention is a method for manufacturing a semiconductor device, including: forming a first conductive layer; forming a first insulating layer and a first conductive film over the first conductive layer; processing the first insulating layer and the first conductive film to form a second conductive layer from the first conductive film and to form a first opening reaching the first conductive layer in the first conductive film and the first insulating layer; processing the second conductive layer to form a third conductive layer; forming a first metal oxide film in contact with a top surface of the first conductive layer in the first opening, a side surface of the first insulating layer in the first opening, a side surface of the third conductive layer in the first opening, and a top surface of the third conductive layer; processing the first metal oxide film to form a first semiconductor layer including a region overlapping with the first opening; forming a second insulating layer in contact with a top surface of the first semiconductor layer; forming a second conductive film over the second insulating layer; processing the second conductive film to form a fourth conductive layer including a region overlapping with the first semiconductor layer; forming a third insulating layer over the fourth conductive layer and the second insulating layer; forming a third conductive film over the third insulating layer; processing the third conductive film to form a fifth conductive layer including a region overlapping with the fourth conductive layer; forming a fourth insulating layer and a fourth conductive film over the fifth conductive layer and the third insulating layer; processing the fourth insulating layer and the fourth conductive film to form a sixth conductive layer from the fourth conductive film and to form, in the fourth conductive film and the fourth insulating layer, a second opening overlapping with a substantially flat top surface of the fourth conductive layer so as to be apart from the fifth conductive layer in a plan view; processing the sixth conductive layer to form a seventh conductive layer; forming a second metal oxide film in contact with a top surface of the fourth conductive layer in the second opening, a side surface of the third insulating layer in the second opening, a side surface of the seventh conductive layer in the second opening, and a top surface of the seventh conductive layer; processing the second metal oxide film to form a second semiconductor layer including a region overlapping with the second opening; forming a fifth insulating layer in contact with a top surface of the second semiconductor layer; forming a fifth conductive film over the fifth insulating layer; and processing the fifth conductive film to form an eighth conductive layer including a region overlapping with the second semiconductor layer.

Another embodiment of the present invention is a method for manufacturing a semiconductor device, including: forming a first conductive layer; forming a first insulating layer and a first conductive film over the first conductive layer; processing the first insulating layer and the first conductive film to form a second conductive layer from the first conductive film and to form a first opening reaching the first conductive layer in the first conductive film and the first insulating layer; forming a first metal oxide film in contact with a top surface of the first conductive layer in the first opening, a side surface of the first insulating layer in the first opening, a side surface of the second conductive layer in the first opening, and a top surface of the second conductive layer; processing the first metal oxide film to form a first semiconductor layer including a region overlapping with the first opening; processing the second conductive layer to form a third conductive layer including a region overlapping with the first semiconductor layer; forming a second insulating layer in contact with a top surface of the first semiconductor layer; forming a second conductive film over the second insulating layer; processing the second conductive film to form a fourth conductive layer including a region overlapping with the first semiconductor layer; forming a third insulating layer over the fourth conductive layer and the second insulating layer; forming a third conductive film over the third insulating layer; processing the third conductive film to form a fifth conductive layer including a region overlapping with the fourth conductive layer; forming a fourth insulating layer and a fourth conductive film over the fifth conductive layer and the third insulating layer; processing the fourth insulating layer and the fourth conductive film to form a sixth conductive layer from the fourth conductive film and to form, in the fourth conductive film and the fourth insulating layer, a second opening overlapping with a substantially flat top surface of the fourth conductive layer so as to be apart from the fifth conductive layer in a plan view; forming a second metal oxide film in contact with a top surface of the fourth conductive layer in the second opening, a side surface of the third insulating layer in the second opening, a side surface of the fourth insulating layer in the second opening, a side surface of the sixth conductive layer in the second opening, and a top surface of the sixth conductive layer; processing the second metal oxide film to form a second semiconductor layer including a region overlapping with the second opening; processing the sixth conductive layer to form a seventh conductive layer including a region overlapping with the second semiconductor layer; forming a fifth insulating layer in contact with a top surface of the second semiconductor layer; forming a fifth conductive film over the fifth insulating layer; and processing the fifth conductive film to form an eighth conductive layer including a region overlapping with the second semiconductor layer.

Another embodiment of the present invention is a semiconductor device including a memory portion and a processing portion; the memory portion includes a memory device and a sense amplifier; the processing portion includes a CPU, an MPU, or a GPU; the sense amplifier and the processing portion are placed on a first layer; the memory device is placed on a second layer and includes a first transistor, a second transistor, a capacitor, a first insulating layer, and a second insulating layer; the second layer is stacked over the first layer; the second transistor and the capacitor are each provided over the first transistor to overlap therewith; a source electrode and a drain electrode of each of the first transistor and the second transistor are positioned at different levels with respect to a substrate surface; the first insulating layer is provided between the source electrode and the drain electrode of the first transistor and includes a first opening reaching one of the source electrode and the drain electrode of the first transistor; the other of the source electrode and the drain electrode of the first transistor is provided over the first insulating layer; a semiconductor layer of the first transistor includes a region in contact with a top surface of the one of the source electrode and the drain electrode of the first transistor in the first opening, a side surface of the first insulating layer in the first opening, and a top surface of the other of the source electrode and the drain electrode of the first transistor; a gate insulating layer of the first transistor is provided over and in contact with the semiconductor layer of the first transistor; a gate electrode of the first transistor is provided over the gate insulating layer of the first transistor to include a region overlapping with the semiconductor layer of the first transistor and has a function of one of the source electrode and the drain electrode of the second transistor and a function of one electrode of the capacitor; the second insulating layer is provided between the source electrode and the drain electrode of the second transistor and includes a second opening reaching the gate electrode of the first transistor; the second opening is positioned diagonally above the first opening; the other of the source electrode and the drain electrode of the second transistor is provided over the second insulating layer; a semiconductor layer of the second transistor includes a region in contact with a top surface of the gate electrode of the first transistor in the second opening, a side surface of the second insulating layer in the second opening, and a top surface of the other of the source electrode and the drain electrode of the second transistor; a gate insulating layer of the second transistor is provided over and in contact with the semiconductor layer of the second transistor; a gate electrode of the second transistor is provided over the gate insulating layer of the second transistor so as to include a region overlapping with the semiconductor layer of the second transistor; a dielectric layer of the capacitor is provided over the gate electrode of the first transistor; and the other electrode of the capacitor includes a region overlapping with the gate electrode of the first transistor and is provided over the dielectric layer of the capacitor and apart from the second opening in a plan view.

In the above, at least one of the semiconductor layer of the first transistor and the semiconductor layer of the second transistor preferably contains a metal oxide.

In the above, it is preferable to include a region in which a side surface of the semiconductor layer of the first transistor is substantially aligned with a side surface of the other of the source electrode and the drain electrode of the first transistor, and a region in which a side surface of the semiconductor layer of the second transistor is substantially aligned with a side surface of the other of the source electrode and the drain electrode of the second transistor.

In the above, an end portion of the other electrode of the capacitor on a side not facing the first opening is preferably positioned outward from an end portion of the gate electrode of the first transistor.

In the above, the other electrode of the capacitor preferably includes a region overlapping with the top surface of the gate electrode of the first transistor to surround the second opening.

In the above, it is preferable that an end portion of the gate electrode of the first transistor be positioned inward from an end portion of the other of the source electrode and the drain electrode of the first transistor in a first direction, and include a region that includes a substantially flat top surface and is positioned outward from an end portion of the other of the source electrode and the drain electrode of the first transistor in a second direction that is a direction opposite to the first direction, and the second opening be provided to overlap with the region in a plan view.

In the above, the dielectric layer of the capacitor preferably contains any of an oxide containing any of aluminum, gallium, hafnium, tantalum, and zirconium, an oxide containing hafnium and zirconium, an oxide containing aluminum and hafnium, an oxynitride containing aluminum and hafnium, an oxide containing silicon and hafnium, an oxynitride containing silicon and hafnium, and a nitride containing silicon and hafnium.

In the above, the dielectric layer of the capacitor preferably contains any of hafnium oxide, zirconium oxide, lead titanate, barium strontium titanate, strontium titanate, lead zirconate titanate, strontium bismuth tantalate, bismuth ferrite, barium titanate, and any of these materials to which lanthanum or yttrium is added.

In the above, the first insulating layer and the second insulating layer each preferably contain any of silicon oxide, silicon oxynitride, silicon nitride oxide, polyester, polyolefin, polyamide, polyimide, polycarbonate, and acrylic.

### Effect of the Invention

One embodiment of the present invention can provide a semiconductor device, a memory device, or a transistor that can be miniaturized or highly integrated. Another embodiment of the present invention can provide a semiconductor device, a memory device, or a transistor with high reliability. Another embodiment of the present invention can provide a transistor with a high on-state current. Another embodiment of the present invention can provide a transistor, a memory device, or a semiconductor device with favorable electrical characteristics. Another embodiment of the present invention can provide an inexpensive semiconductor device or an inexpensive memory device. Another embodiment of the present invention can provide a semiconductor device or a memory device with low power consumption. Another embodiment of the present invention can provide a semiconductor device or a memory device with a high operation speed. Another embodiment of the present invention can provide a novel semiconductor device, a novel memory device, or a novel transistor.

Another embodiment of the present invention can provide a method for manufacturing a semiconductor device, a memory device, or a transistor that can be miniaturized or highly integrated. Another embodiment of the present invention can provide a method for manufacturing a semiconductor device, a memory device, or a transistor with high reliability. Another embodiment of the present invention can provide a method for manufacturing a transistor with a high on-state current. Another embodiment of the present invention can provide a method for manufacturing a transistor, a memory device, or a semiconductor device with favorable electrical characteristics. Another embodiment of the present invention can provide a method for manufacturing a semiconductor device or a memory device with high yield. Another embodiment of the present invention can provide a method for manufacturing a semiconductor device or a memory device with low power consumption. Another embodiment of the present invention can provide a method for manufacturing a semiconductor device or a memory device with a high operation speed. Another embodiment of the present invention can provide a method for manufacturing a novel semiconductor device, a novel memory device, or a novel transistor.

Note that the description of these effects does not preclude the existence of other effects. One embodiment of the present invention does not necessarily need to have all of these effects. Other effects can be derived from the description of the specification, the drawings, and the claims.

### BRIEF DESCRIPTION OF THE DRAWINGS

FIG. 1A is a block diagram illustrating a structure example of an electronic computer. FIG. 1B and FIG. 1C are schematic diagrams illustrating structure examples of the electronic computer.

FIG. 2 is a schematic diagram illustrating a structure example of an electronic computer.

FIG. 3 is a circuit diagram illustrating a structure example of a semiconductor device.

FIG. 4A to FIG. 4D are circuit diagrams illustrating structure examples of a semiconductor device.

FIG. 5A is a plan view illustrating a structure example of a memory device. FIG. 5B is a cross-sectional view illustrating the structure example of the memory device.

FIG. 6A and FIG. 6B are cross-sectional views illustrating the structure example of the memory device.

FIG. 7A is a cross-sectional view illustrating a structure example of a transistor. FIG. 7B is a plan view illustrating the structure example of the transistor.

FIG. 8A is a plan view illustrating a structure example of a memory device. FIG. 8B is a cross-sectional view illustrating the structure example of the memory device.

FIG. 9A is a plan view illustrating a structure example of a memory device. FIG. 9B is a cross-sectional view illustrating the structure example of the memory device.

FIG. 10 is a cross-sectional view illustrating the structure example of the memory device.

FIG. 11A is a plan view illustrating a structure example of a memory device. FIG. 11B is a cross-sectional view illustrating the structure example of the memory device.

FIG. 12A and FIG. 12B are cross-sectional views illustrating the structure example of the memory device.

FIG. 13A to FIG. 13C are schematic plan views illustrating structure examples of semiconductor devices.

FIG. 14A and FIG. 14B are schematic plan views illustrating structure examples of semiconductor devices.

FIG. 15A to FIG. 15H are plan views illustrating the positional relationship between wirings.

FIG. 16A to FIG. 16H are plan views illustrating the positional relationship between wirings.

FIG. 17 is a circuit diagram illustrating a structure example of a semiconductor device.

FIG. 18 is a timing chart illustrating an operation example of the semiconductor device.

FIG. 19 is a block diagram illustrating a structure example of a memory device.

FIG. 20A and FIG. 20B are circuit diagrams illustrating structure examples of memory devices.

FIG. 21 is a schematic diagram illustrating a structure example of a memory device.

FIG. 22 is a circuit diagram illustrating a structure example of a semiconductor device.

FIG. 23 is a timing chart illustrating an operation example of the semiconductor device.

FIG. 24A to FIG. 24D are schematic diagrams illustrating the operation example of the semiconductor device.

FIG. 25 is a timing chart illustrating an operation example of the semiconductor device.

FIG. 26A to FIG. 26G are schematic diagrams illustrating the operation example of the semiconductor device.

FIG. 27 is a block diagram illustrating a CPU.

FIG. 28A and FIG. 28B are perspective views of a semiconductor device.

FIG. 29A and FIG. 29B are perspective views of semiconductor devices.

FIG. 30A and FIG. 30B are diagrams each illustrating a hierarchy of a variety of memory devices.

FIG. 31A is a plan view illustrating an example of a method for manufacturing a memory device.

FIG. 31B is a cross-sectional view illustrating the example of the method for manufacturing the memory device.

FIG. 32A and FIG. 32B are cross-sectional views illustrating the example of the method for manufacturing the memory device.

FIG. 33A is a plan view illustrating the example of the method for manufacturing the memory device. FIG. 33B is a cross-sectional view illustrating the example of the method for manufacturing the memory device.

FIG. 34A and FIG. 34B are cross-sectional views illustrating the example of the method for manufacturing the memory device.

FIG. 35A is a plan view illustrating the example of the method for manufacturing the memory device. FIG. 35B is a cross-sectional view illustrating the example of the method for manufacturing the memory device.

FIG. 36A and FIG. 36B are cross-sectional views illustrating the example of the method for manufacturing the memory device.

FIG. 37A is a plan view illustrating the example of the method for manufacturing the memory device. FIG. 37B is a cross-sectional view illustrating the example of the method for manufacturing the memory device.

FIG. 38A and FIG. 38B are cross-sectional views illustrating the example of the method for manufacturing the memory device.

FIG. 39A is a plan view illustrating the example of the method for manufacturing the memory device. FIG. 39B is a cross-sectional view illustrating the example of the method for manufacturing the memory device.

FIG. 40A and FIG. 40B are cross-sectional views illustrating the example of the method for manufacturing the memory device.

FIG. 41A is a plan view illustrating the example of the method for manufacturing the memory device. FIG. 41B is a cross-sectional view illustrating the example of the method for manufacturing the memory device.

FIG. 42A and FIG. 42B are cross-sectional views illustrating the example of the method for manufacturing the memory device.

FIG. 43A is a plan view illustrating the example of the method for manufacturing the memory device. FIG. 43B is a cross-sectional view illustrating the example of the method for manufacturing the memory device.

FIG. 44A and FIG. 44B are cross-sectional views illustrating the example of the method for manufacturing the memory device.

FIG. 45A is a plan view illustrating the example of the method for manufacturing the memory device. FIG. 45B is a cross-sectional view illustrating the example of the method for manufacturing the memory device.

FIG. 46A and FIG. 46B are cross-sectional views illustrating the example of the method for manufacturing the memory device.

FIG. 47A is a plan view illustrating the example of the method for manufacturing the memory device. FIG. 47B is a cross-sectional view illustrating the example of the method for manufacturing the memory device.

FIG. 48A and FIG. 48B are cross-sectional views illustrating the example of the method for manufacturing the memory device.

FIG. 49A is a plan view illustrating the example of the method for manufacturing the memory device. FIG. 49B is a cross-sectional view illustrating the example of the method for manufacturing the memory device.

FIG. 50A and FIG. 50B are cross-sectional views illustrating the example of the method for manufacturing the memory device.

FIG. 51A is a plan view illustrating the example of the method for manufacturing the memory device. FIG. 51B is a cross-sectional view illustrating the example of the method for manufacturing the memory device.

FIG. 52A and FIG. 52B are cross-sectional views illustrating the example of the method for manufacturing the memory device.

FIG. 53A is a plan view illustrating the example of the method for manufacturing the memory device. FIG. 53B is a cross-sectional view illustrating the example of the method for manufacturing the memory device.

FIG. 54A and FIG. 54B are cross-sectional views illustrating the example of the method for manufacturing the memory device.

FIG. 55A is a plan view illustrating the example of the method for manufacturing the memory device. FIG. 55B is a cross-sectional view illustrating the example of the method for manufacturing the memory device.

FIG. 56A and FIG. 56B are cross-sectional views illustrating the example of the method for manufacturing the memory device.

FIG. 57 is a cross-sectional view illustrating a structure example of a memory device.

FIG. 58A and FIG. 58B are diagrams illustrating examples of electronic components.

FIG. 59A and FIG. 59B are diagrams illustrating examples of electronic appliances. FIG. 59C to FIG. 59E are diagrams illustrating an example of a large computer.

FIG. 60 is a diagram illustrating an example of a device for space.

FIG. 61 is a diagram illustrating an example of a storage system that can be used in a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in the structures of the invention described below, the same reference numeral is used in common for the same portions or portions having similar functions in different drawings, and repeated description thereof is omitted. The same hatching pattern is applied to portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings. For example, in the actual manufacturing process, a layer, a resist mask, or the like might be unintentionally reduced in size by treatment such as etching, which might not be reflected in the drawings for easy understanding.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

A transistor is a kind of semiconductor element and can achieve a function of amplifying a current or a voltage, switching operation for controlling conduction or non-conduction, or the like. An IGFET (Insulated Gate Field Effect Transistor) and a thin film transistor (TFT) are in the category of a transistor in this specification.

In this specification and the like, a transistor is an element having at least three terminals including a gate, a drain, and a source. In addition, the transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which a current mainly flows.

Furthermore, functions of a “source” and a “drain” are sometimes interchanged with each other when a transistor of different polarity is used or when the direction of a current is changed in a circuit operation, for example. Thus, the terms “source” and “drain” can be used interchangeably in this specification.

Note that impurities in a semiconductor refer to, for example, elements other than the main components of a semiconductor. For example, an element with a concentration lower than 0.1 atomic % can be regarded as an impurity. When an impurity is contained, for example, the density of defect states in a semiconductor increases or the crystallinity decreases in some cases. In the case where the semiconductor is an oxide semiconductor, examples of impurities that change the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. In addition, oxygen vacancies (also referred to as Vₒ) are formed in an oxide semiconductor in some cases by entry of impurities, for example.

Note that in this specification and the like, an oxynitride refers to a material that contains more oxygen than nitrogen in its composition. A nitride oxide refers to a material that contains more nitrogen than oxygen in its composition.

The contents of elements such as hydrogen, oxygen, carbon, and nitrogen in a film can be analyzed by secondary ion mass spectrometry (SIMS) or X-ray photoelectron spectroscopy (XPS), for example. When the content percentage of a target element is high (e.g., higher than or equal to 0.5 atomic %, or higher than or equal to 1 atomic %), XPS is suitable. By contrast, when the content percentage of a target element is low (e.g., lower than or equal to 0.5 atomic %, or lower than or equal to 1 atomic %), SIMS is suitable. To compare the contents of elements, a combined analysis using both SIMS and XPS is further preferably performed.

In this specification and the like, the terms “film” and “layer” can be interchanged with each other depending on the situation. For example, the term “conductive layer” can be changed to the term “conductive film” in some cases, and the term “conductive film” can be changed to the term “conductive layer” in some cases. For example, the term “insulating film” can be changed to the term “insulating layer” in some cases, and the term “insulating layer” can be changed to the term “insulating film” in some cases. For example, the term “semiconductor film” can be changed to the term “semiconductor layer” in some cases, and the term “semiconductor layer” can be changed to the term “semiconductor film” in some cases.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, the term “connection” includes “electrical connection”.

The expression “A and B are electrically connected” means that, in the case where A and B are connected not through an insulator (or in the case where A and B are connected through a conductor or a semiconductor, or in the case where A and B are in contact with each other), transmission and reception of an electric signal or interaction of a potential occurs between A and B in a certain period in operation of a circuit including A and B. In other words, even when the circuit operation includes a timing at which neither transmission and reception of an electric signal nor interaction of a potential occurs between A and B, the expression “A and B are electrically connected” can be used as long as transmission and reception of an electric signal or interaction of a potential occurs between A and B at another timing.

The term “electrical connection” includes direct connection that is connection not through a circuit element (e.g., a transistor, with the exception of a wiring) and indirect connection that is connection through at least one circuit element.

Examples of the expression “A and B are electrically connected” include the case where A and B are connected not through a circuit element, and the case where A and B are connected through a source and a drain of at least one transistor, assuming that transmission and reception of an electric signal or interaction of a potential occurs between A and B at a certain timing.

Examples of the case where the expression “A and B are electrically connected” cannot be used because A and B are connected through an insulator include the case where a dielectric of a capacitor element, a gate insulating film of a transistor, or the like is positioned between A and B.

Examples of the case where the expression “A and B are electrically connected” cannot be used because neither transmission and reception of an electric signal nor interaction of a potential occurs between A and B at any timing although A and B are connected not through an insulator include the case where a potential V is supplied from a power source, a signal source, or the like to the path between A and B (except for the case where the potential V is supplied through a circuit element), and the case where A and C are connected through a source and a drain of a transistor TrP and B and C are connected through a source and a drain of a transistor TrQ, but both the transistor TrP and the transistor TrQ are not in the on state at the same time at any timing.

In this specification and the like, a “resistor element” can be, for example, a circuit element having a resistance value higher than 0 Ω or a wiring having a resistance value higher than 0 Ω. Therefore, in this specification and the like, a “resistor element” includes a wiring having a resistance value, a transistor in which a current flows between a source and a drain, a diode, and a coil. Thus, the term “resistor element” can sometimes be replaced with the term “resistor”, “load”, or “region having a resistance value”. Conversely, the term “resistor”, “load”, or “region having a resistance value” can sometimes be replaced with the term “resistor element”. The resistance value can be, for example, preferably higher than or equal to 1 mΩ and lower than or equal to 10 Ω, further preferably higher than or equal to 5 mΩ and lower than or equal to 5 Ω, still further preferably higher than or equal to 10 mΩ and lower than or equal to 1 Ω. For another example, the resistance value may be higher than or equal to 1 Ω and lower than or equal to 1×10⁹ Ω.

In this specification and the like, a “capacitor element” can be, for example, a circuit element having an electrostatic capacitance value higher than 0 F, a region of a wiring having an electrostatic capacitance value higher than 0 F, parasitic capacitance, or gate capacitance of a transistor. The term “capacitor element”, “parasitic capacitance”, or “gate capacitance” can be replaced with the term “capacitor” in some cases. Conversely, the term “capacitor” can be replaced with the term “capacitor element”, “parasitic capacitance”, or “gate capacitance” in some cases. In addition, a “capacitor” (including a “capacitor” with three or more terminals) includes an insulator and a pair of conductors between which the insulator is sandwiched. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gates can be used as the transistor. With the multi-gate structure, channel formation regions are connected to each other in series; accordingly, a plurality of transistors are connected to each other in series. Thus, with the multi-gate structure, the amount of an off-state current can be reduced, and the breakdown voltage of the transistor can be increased (the reliability can be improved). Alternatively, with the multi-gate structure, the current between the drain and the source does not change much even if the voltage between the drain and the source changes at the time of operation in a saturation region, so that a flat slope of voltage-current characteristics can be obtained. By utilizing the flat slope of the voltage current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and gates of the transistors are electrically connected to each other. Similarly, for another example, the case where a single switch is illustrated in a circuit diagram may include a case where the switch includes two or more transistors, the two or more transistors are electrically connected to each other in series or in parallel, and gates of the transistors are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean particular potentials. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means an electric charge transfer phenomenon (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to an electric charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive electric charge moves, and the amount of the current is expressed as a positive value. In other words, the direction in which a carrier with negative electric charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Unless otherwise specified, an off-state current in this specification and the like refers to a leakage current between a source and a drain of a transistor in an off state (also referred to as a non-conduction state or a cut-off state). Unless otherwise specified, an off state of an n-channel transistor refers to a state where a voltage V_{gs} between its gate and source is lower than a threshold voltage Vₜₕ (in the case of a p-channel transistor, higher than Vₜₕ).

Note that in this specification and the like, a tapered shape refers to a shape such that at least part of a side surface of a component is inclined to a substrate surface or a formation surface. For example, the tapered shape refers to including a region where the angle formed between the inclined side surface and the substrate surface or the formation surface (the angle is also referred to as a taper angle) is less than 90°. Note that the side surface of the component, the substrate surface, and the formation surface are not necessarily completely flat and may be substantially flat with a slight curvature or substantially flat with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, terms for describing placement, such as “over”, “under”, “left”, and “right”, are used for convenience to describe the positional relationship between components with reference to drawings. The positional relationship between components is changed as appropriate in accordance with the direction in which the components are described. Thus, without limitation to terms described in this specification, the description can be changed appropriately depending on the situation.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor. Note that metal oxides containing nitrogen are also collectively referred to as metal oxides in some cases. Furthermore, a metal oxide containing nitrogen may be referred to as a metal oxynitride.

### Embodiment 1

A semiconductor device of one embodiment of the present invention can function as an electronic computer (also referred to as a computer in some cases). At least part of the electronic computer of one embodiment of the present invention can be used in a microcomputer, a personal computer, a workstation, a mainframe, or a supercomputer, for example.

Among components of the semiconductor device of one embodiment of the present invention, a processing portion such as a CPU and part of a memory portion (e.g., a sense amplifier) can be formed on the same layer (on a first layer). Thus, the semiconductor device can be manufactured through a smaller number of steps than in the case where the processing portion and the memory portion are formed on different layers. Since the processing portion and part of the memory portion are formed on the same layer (on the first layer), the physical distance between the two components can be decreased to reduce the influence of signal delay through a wiring between the two, for example. Thus, the operation speed of the semiconductor device can be increased, and the power consumption thereof can be reduced.

In the semiconductor device of one embodiment of the present invention, a memory cell (also referred to as a memory device in some cases) included in the memory portion is provided on a layer (a second layer) different from the above-described first layer. Here, the second layer is a layer stacked over the first layer. In the semiconductor device of one embodiment of the present invention, the memory cell can be formed with a minute transistor and a capacitor. The transistor and the capacitor which are included in the memory cell are provided to overlap with each other, and part of their components are formed to be shared by the two. Accordingly, a minute semiconductor device having a high degree of integration can be obtained. In addition, an inexpensive semiconductor device with a smaller number of steps can be obtained. An electronic computer that can be used as the semiconductor device of one embodiment of the present invention will be described below with reference to drawings.

### Structure Example of Electronic Computer

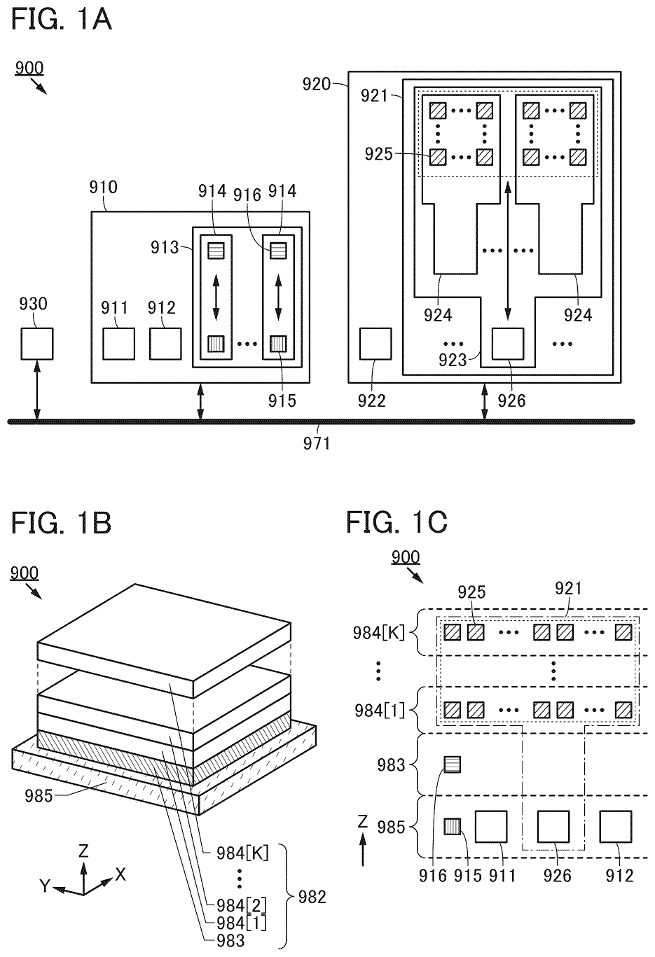

FIG. 1A is a block diagram illustrating a structure example of an electronic computer 900 that can be used as the semiconductor device of one embodiment of the present invention.

As illustrated in FIG. 1A, the electronic computer 900 includes a processing portion 910 (also referred to as a processor in some cases), a memory portion 920 (also referred to as a memory in some cases), and a control portion 930. The processing portion 910, the memory portion 920, and the control portion 930 are electrically connected to each other through a bus line 971.

Although not illustrated, the electronic computer 900 may include an input/output portion (also referred to as an interface in some cases), for example. The input/output portion has a function of, for example, exchanging data or the like with a functional device (e.g., an input device, an output device, or a memory device) provided outside the electronic computer 900.

The processing portion 910 has a function of executing a series of processes (tasks) by sequentially executing processes according to a program, for example. In addition, the processing portion 910 has a function of executing a plurality of tasks, for example. At least part of the processing portion 910 can be used for a CPU, an MPU (Micro Processing Unit), a GPU (Graphics Processing Unit), and the like, for example.

The processing portion 910 includes an arithmetic portion 911 (also referred to as a core in some cases), a control portion 912, and a register portion 913. The register portion 913 includes one or more register units 914.

The register unit 914 includes a scan flip-flop 915 and a backup memory 916. At least part of the register unit 914 can be used for a general-purpose register and a dedicated register (e.g., a program counter (PC), an instruction register (IR), or a status register (SR)), for example.

The arithmetic portion 911 can include, for example, an arithmetic logic unit (ALU), a floating point unit (FPU), and the like.

The control portion 912 has a function of controlling the operation of the processing portion 910. For example, the control portion 912 has a function of controlling processing which is performed with switching between a plurality of tasks. The control portion 912 can include an instruction decoder (ID), for example.

A specific structure example of the register unit 914 will be described later.

The memory portion 920 has a function of storing a program and data, for example. At least part of the memory portion 920 can be used for a main memory, a cache memory, and the like, for example.

The memory portion 920 includes a memory array portion 921 and a control portion 922.

The memory array portion 921 includes one or more memory blocks 923. The memory block 923 includes one or more memory units 924 and a sense amplifier 926. The memory unit 924 includes one or more memory cells 925.

Here, a group of a plurality of memory cells 925 enclosed by the dotted line in FIG. 1A is referred to as a memory cell array in some cases.

The control portion 922 has a function of controlling the operation of the memory portion 920. For example, the control portion 922 has a function of controlling data writing and reading to and from the memory array portion 921.

A specific structure example of the memory block 923 and a specific structure example of the memory portion 920 will be described later.

The control portion 930 has a function of controlling the operation of the electronic computer 900. The control portion 930 can include a power management unit (PMU), for example. The PMU has a function of controlling a power gating operation, for example. For example, the PMU has a function of controlling power supply to each component included in the electronic computer 900 by bringing a power switch (not illustrated) into a conduction state or a non-conduction state.

FIG. 1B is a schematic diagram illustrating a layer structure example of the electronic computer 900.

As illustrated in FIG. 1B, the electronic computer 900 includes a layer 985 and a layer 982. The layer 982 includes a layer 983 and a plurality of layers 984 (a layer 984[1] to 984[K] (K is an integer greater than or equal to 2)). Note that a structure including one layer 984 may be employed.

The layer 983 is stacked over the layer 985. The layer 984[1] to the layer 984[K] are stacked over the layer 983.

In the following description, the X direction, the Y direction, and the Z direction are defined for easy understanding of the positional relationship between components. The X direction, the Y direction, and the Z direction are perpendicular or substantially perpendicular to each other. Note that “substantially perpendicular” indicates a state where the angle formed by two targeted elements is greater than or equal to 85° and less than or equal to 95°. The Z direction corresponds to a direction in which the layer 983 and the layer 984[1] to the layer 984[K] are stacked over the layer 985. Thus, the X direction and the Y direction correspond to directions along the surfaces of the layer 985, the layer 983, and the layer 984[1] to the layer 984[K].

The layer 985 can be provided in an insulating substrate or a semiconductor substrate containing any of a variety of materials.

In one embodiment of the present invention, a structure can be employed in which the layer 985 is provided in a substrate containing silicon, for example. That is, a structure can be employed in which a Si transistor (a transistor containing silicon in a channel formation region) is provided in the layer 985. Thus, in one embodiment of the present invention, a structure can be employed in which a gate of an n-channel Si transistor and a gate of a p-channel Si transistor are electrically connected to each other in the layer 985, for example, to form a CMOS circuit (e.g., a circuit that operates complementarily, a CMOS logic gate, a CMOS logic circuit, or the like).

Each of the layer 983 and the layer 984[1] to the layer 984[K] can contain any of a variety of materials such as a conductor, a semiconductor, and an insulator, for example. Any of a variety of elements such as a capacitor and a transistor can be provided in each of the layer 983 and the layer 984[1] to the layer 984[K], for example.

Note that a semiconductor layer including a channel formation region of a transistor provided in the layer 983 and semiconductor layers including channel formation regions of transistors provided in the layer 984[1] to the layer 984[K] may contain the same material or different materials. The transistor provided in the layer 983 and the transistors provided in the layer 984[1] to the layer 984[K] may have the same structure or different structures.

In one embodiment of the present invention, a structure can be employed in which OS transistors (transistors each containing an oxide semiconductor in a channel formation region) are provided in the layer 983 and the layer 984[1] to the layer 984[K].

OS transistors have a characteristic of extremely low off-state current. In addition, OS transistors have a characteristic of off-state current that hardly increases and on-state current that is unlikely to decrease even in a high-temperature environment. Thus, for example, in the case where a wiring electrically connected to one of a source and a drain of an OS transistor is in a floating state (also referred to as being floating in some cases), charge accumulated in the wiring can be retained for a long period. Thus, when a memory cell is formed using an OS transistor in one embodiment of the present invention, data written to the memory cell can be retained for a long period, for example.

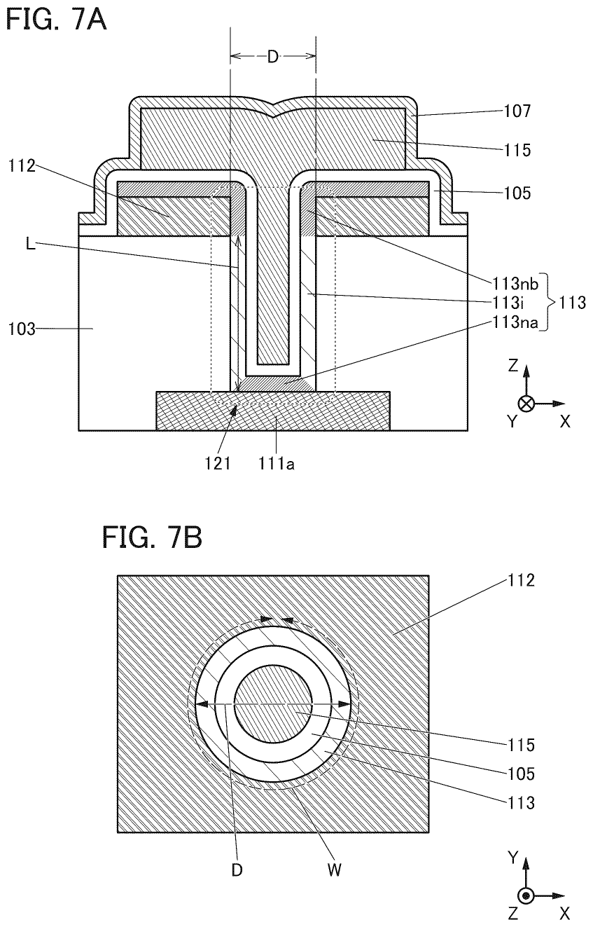

In one embodiment of the present invention, a structure can be employed in which, as the structures of the OS transistors, a planar transistor is provided in the layer 983 and vertical transistors (transistors in each of which at least part of a semiconductor layer including a channel formation region is provided in an opening formed in an insulating layer) are provided in the layer 984[1] to the layer 984[K], for example. Note that the detailed structure of the vertical transistors will be described later with reference to FIG. 7A, FIG. 7B, and the like.

A vertical transistor has a structure that can easily reduce the area to be occupied (the footprint) as compared with a planar transistor. Since the structure can easily decrease the channel length and increase the channel width, the structure can easily decrease the on-state resistance (and increase the on-state current). Thus, when the memory cell in one embodiment of the present invention is formed using, for example, a vertical transistor, the cell area (cell size) of the memory cell can be reduced.

Since a planar transistor has a structure that can easily increase the channel length as compared with a vertical transistor, the structure can easily reduce a short-channel effect such as drain-induced barrier lowering (DIBL), for example. That is, the structure can easily enable a transistor to have high saturability (a small change in drain current with respect to drain voltage in a saturation region of the transistor). Thus, when the sense amplifier in one embodiment of the present invention is formed using, for example, a planar transistor, the characteristics of the sense amplifier can be improved.

Note that a structure may be employed in which a vertical transistor is provided in the layer 983, for example. As another example, a structure may be employed in which planar transistors are provided in the layer 984[1] to the layer 984[K].

Although not illustrated, the electronic computer 900 may have a structure in which a wiring layer is provided as appropriate between the layer 985, the layer 983, and the layer 984[1] to the layer 984[K] individually. The wiring layer can be provided with a wiring for electrically connecting various elements to each other, for example.

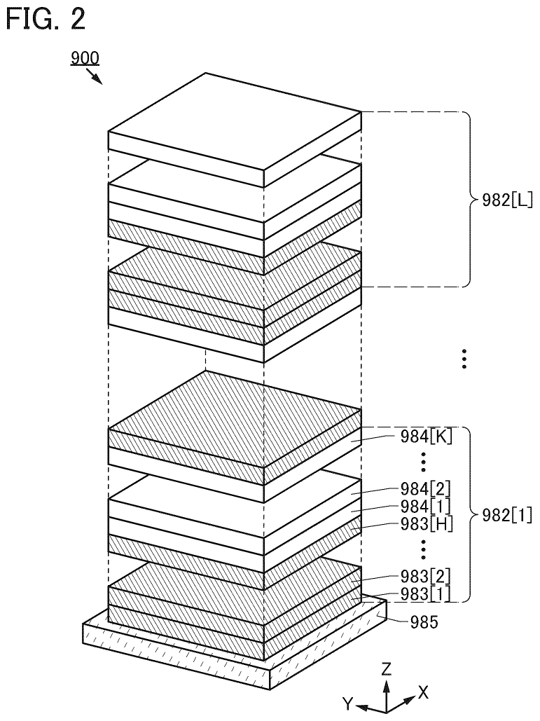

As illustrated in FIG. 2, the electronic computer 900 may have a structure which includes a plurality of layers 983 (a layer 983[1] to a layer 983[H] (H is an integer greater than or equal to 2)) and in which the layer 983[1] to the layer 983[H] are stacked. The electronic computer 900 may have a structure which includes a plurality of layers 982 (a layer 982[1] to a layer 982[L] (L is an integer greater than or equal to 2)) and in which the layer 982[1] to the layer 982[L] are stacked.

FIG. 1C is a schematic diagram for explaining an example of the placement of the components included in the electronic computer 900. In the electronic computer 900, the components illustrated in FIG. 1A can be placed as appropriate in the layers illustrated in FIG. 1B, for example. Note that FIG. 1C illustrates, as some of the components of the electronic computer 900, the arithmetic portion 911, the control portion 912, the scan flip-flop 915, and the backup memory 916, which are included in the processing portion 910. In addition, FIG. 1C illustrates the memory cells 925 and the sense amplifier 926, which are included in the memory portion 920.

The electronic computer 900 illustrated in FIG. 1C includes the layer 985, the layer 983, and the layer 984[1] to the layer 984[K]. As illustrated in FIG. 1C, the arithmetic portion 911, the control portion 912, the scan flip-flop 915, and the sense amplifier 926 are placed in the layer 985. Although not illustrated, the control portion 930 and the control portion 922, which is included in the memory portion 920, are also placed in the layer 985. Note that the sense amplifier 926 can be placed between the arithmetic portion 911 and the control portion 912, for example. The backup memory 916 is placed in the layer 983 to overlap with the scan flip-flop 915. The memory cells 925 are placed in the layer 984[1] to the layer 984[K] to overlap with the sense amplifier 926. Note that the memory cells 925 can be placed to overlap with the arithmetic portion 911 and the control portion 912, for example. The memory cells 925 can be placed to overlap with the backup memory 916, for example.

In other words, the electronic computer 900 illustrated in FIG. 1C has a structure in which the memory array portion 921 included in the memory portion 920 is placed inside the processing portion 910. Note that a structure may be employed in which the control portion 922 is also placed inside the processing portion 910.

Such placement can reduce the space unused in the layer 983 and the layer 984[1] to 984[K], for example, to improve the area efficiency. Accordingly, the surface density (memory density) of the memory array portion 921 can be increased. Thus, the memory capacity of the memory portion 920 included in the electronic computer 900 can be increased, and the size of the electronic computer 900 can be reduced. The bus line 971 between the processing portion 910 and the memory portion 920 can be shortened, for example. Accordingly, the access time (time needed for data writing and reading) and the access energy (energy consumed by data writing and reading) can be reduced. Thus, the operation speed of the electronic computer 900 can be increased, and the power consumption thereof can be reduced.

Specific structure examples of a semiconductor device that can be used for the register unit 914, a semiconductor device that can be used for the memory block 923, and a memory device that can be used for the memory portion 920 will be described below.

Note that in the following description, a potential corresponding to “1” of binary data is a potential VDD that is a high power supply potential, and a potential corresponding to “0” of binary data is a potential VSS that is a low power supply potential. The potential VDD is a potential higher than at least the threshold voltage of a transistor with respect to the potential VSS. Note that the potential VSS may be a ground potential, for example. The potential of a signal is a potential H or a potential L. The potential H is a potential which, when supplied to a gate of an n-channel transistor, makes the transistor in the conduction state and, when supplied to a gate of a p-channel transistor, makes the transistor in the non-conduction state. The potential L is a potential which, when supplied to a gate of an n-channel transistor, makes the transistor in the non-conduction state and, when supplied to a gate of a p-channel transistor, makes the transistor in the conduction state. The potential H can be, for example, a potential equal to or higher than the potential VDD. The potential L can be, for example, a potential equal to or lower than the potential VSS.

Note that the potential H or the potential L does not necessarily have the same potential among a plurality of signals. The plurality of signals may have different potentials H or L from one another in accordance with the threshold voltages of the transistors to which the signals are supplied. For example, the potential H or the potential L of a signal supplied to a gate of a Si transistor provided in the layer 985 and that of a signal supplied to gates of OS transistors provided in the layer 983 and the layer 984[1] to the layer 984[K] may be different from each other.

### Semiconductor Device That Can Be Used for Memory Portion 920

A semiconductor device 710 of one embodiment of the present invention will be described. At least part of the semiconductor device 710 can be used for the above-described electronic computer 900 illustrated in FIG. 1A and the like, for example. For example, at least part of the semiconductor device 710 can be used for the memory block 923 included in the memory portion 920.

### Structure Example

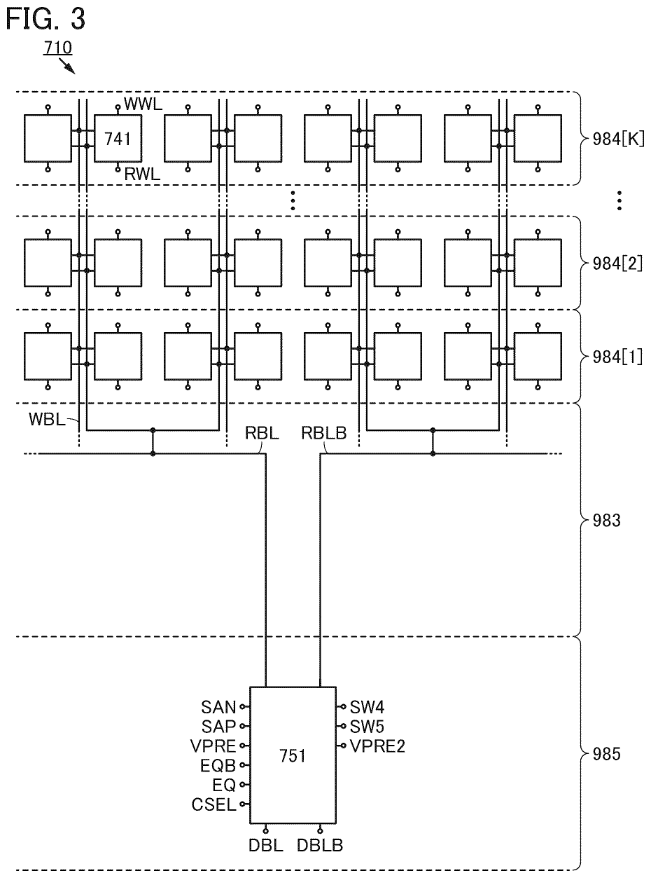

FIG. 3 is a circuit diagram illustrating a structure example of the semiconductor device 710.

The semiconductor device 710 illustrated in FIG. 3 includes a plurality of memory cells 741 and a sensing circuit 751.

In the case where the semiconductor device 710 is used for the memory block 923 included in the above-described electronic computer 900 in one embodiment of the present invention, the memory cells 741 correspond to the memory cells 925, and the sensing circuit 751 corresponds to the sense amplifier 926, for example. In other words the memory cells 741 are placed in the layer 984[1] to the layer 984[K], and the sensing circuit 751 is placed in the layer 985, for example. Thus, vertical OS transistors can be used in the memory cells 741, and a Si transistor can be used in the sensing circuit 751, for example.

Note that FIG. 3 selectively illustrates eight memory cells 741 placed in the layer 984[1], eight memory cells 741 placed in the layer 984[2], and eight memory cells 741 placed in the layer 984[K].

Some of the plurality of memory cells 741 are electrically connected to the sensing circuit 751 through a wiring RBL functioning as a read bit line. The others are electrically connected to the sensing circuit 751 through a wiring RBLB functioning as a read bit line.

In the case of writing data, the sensing circuit 751 has a function of supplying a potential corresponding to the data to each of the wiring RBL and the wiring RBLB. In the case of reading data, the sensing circuit 751 has a function of outputting a potential corresponding to the data in accordance with a potential difference between the wiring RBL and the wiring RBLB.

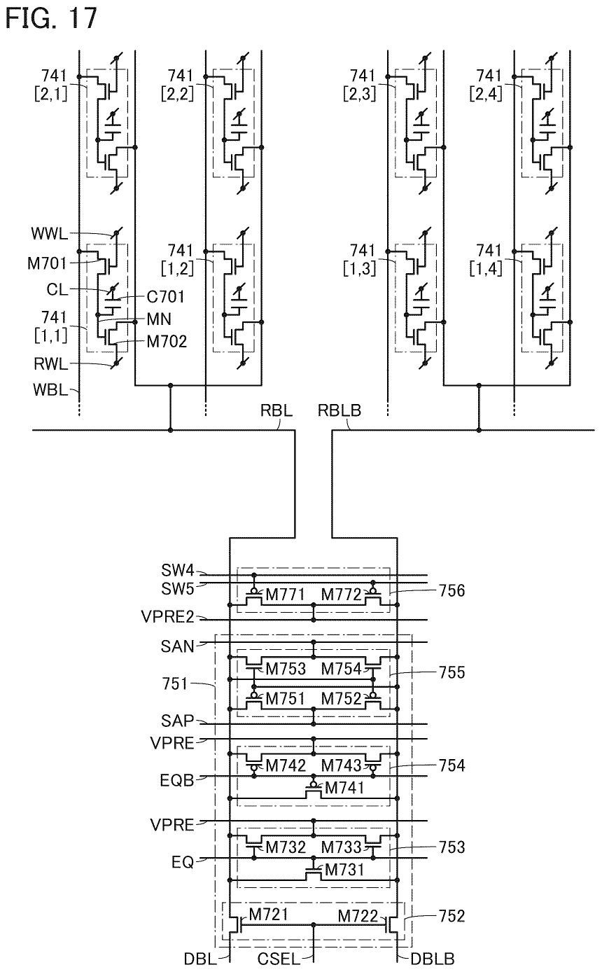

FIG. 17 is a circuit diagram illustrating a specific structure example of the semiconductor device 710 illustrated in FIG. 3. Note that FIG. 17 selectively illustrates two memory cells (a memory cell 741[1,1] and a memory cell 741[1,2]) electrically connected to the wiring RBL and two memory cells (a memory cell 741[1,3] and a memory cell 741[1,4]) electrically connected to the wiring RBLB, which are placed in the layer 984[1]. In addition, FIG. 17 illustrates two memory cells (a memory cell 741[2,1] and a memory cell 741[2,2]) electrically connected to the wiring RBL and two memory cells (a memory cell 741[2,3] and a memory cell 741[2,4]) electrically connected to the wiring RBLB, which are placed in the layer 984[2].

The sensing circuit 751 includes a switch circuit 752, a precharge circuit 753, a precharge circuit 754, an amplifier circuit 755, and a precharge circuit 756. The switch circuit 752, the precharge circuit 753, the precharge circuit 754, the amplifier circuit 755, and the precharge circuit 756 are each electrically connected to the wiring RBL and the wiring RBLB. The switch circuit 752 is electrically connected to a wiring DBL and a wiring DBLB. The sensing circuit 751 has a function of controlling data writing and reading to and from the memory cells 741.

The switch circuit 752 has a function of establishing or interrupting electrical continuity between the wiring pair of the wiring RBL and the wiring RBLB and the wiring pair of the wiring DBL and the wiring DBLB in accordance with a signal supplied to a wiring CSEL. Specifically, the switch circuit 752 includes a transistor M721 and a transistor M722. One of a source and a drain of the transistor M721 is electrically connected to the wiring RBL. The other of the source and the drain of the transistor M721 is electrically connected to the wiring DBL. One of a source and a drain of the transistor M722 is electrically connected to the wiring RBLB. The other of the source and the drain of the transistor M722 is electrically connected to the wiring DBLB. A gate of the transistor M721 and a gate of the transistor M722 are electrically connected to the wiring CSEL. The transistor M721 and the transistor M722 are n-channel transistors.

The precharge circuit 753 has a function of precharging the wiring RBL and the wiring RBLB with a potential supplied to a wiring VPRE, in accordance with a signal supplied to a wiring EQ. Specifically, the precharge circuit 753 includes a transistor M731, a transistor M732, and a transistor M733. One of a source and a drain of the transistor M731 is electrically connected to the wiring RBL. The other of the source and the drain of the transistor M731 is electrically connected to the wiring RBLB. One of a source and a drain of the transistor M732 is electrically connected to the wiring RBL. One of a source and a drain of the transistor M733 is electrically connected to the wiring RBLB. The other of the source and the drain of the transistor M732 and the other of the source and the drain of the transistor M733 are electrically connected to the wiring VPRE. A gate of the transistor M731, a gate of the transistor M732, and a gate of the transistor M733 are electrically connected to the wiring EQ. The transistor M731, the transistor M732, and the transistor M733 are n-channel transistors.

The precharge circuit 754 has a function of precharging the wiring RBL and the wiring RBLB with the potential supplied to the wiring VPRE, in accordance with a signal supplied to a wiring EQB. Specifically, the precharge circuit 754 includes a transistor M741, a transistor M742, and a transistor M743. One of a source and a drain of the transistor M741 is electrically connected to the wiring RBL. The other of the source and the drain of the transistor M741 is electrically connected to the wiring RBLB. One of a source and a drain of the transistor M742 is electrically connected to the wiring RBL. One of a source and a drain of the transistor M743 is electrically connected to the wiring RBLB. The other of the source and the drain of the transistor M742 and the other of the source and the drain of the transistor M743 are electrically connected to the wiring VPRE. A gate of the transistor M741, a gate of the transistor M742, and a gate of the transistor M743 are electrically connected to the wiring EQB. The transistor M741, the transistor M742, and the transistor M743 are p-channel transistors.

The amplifier circuit 755 has a function of outputting a potential corresponding to one of binary data to the wiring RBL and outputting a potential corresponding to the other of the binary data to the wiring RBLB when a predetermined potential is supplied to a wiring SAP and a wiring SAN. Specifically, the amplifier circuit 755 includes a transistor M751, a transistor M752, a transistor M753, and a transistor M754. One of a source and a drain of the transistor M751 is electrically connected to the wiring RBL. One of a source and a drain of the transistor M752 is electrically connected to the wiring RBLB. One of a source and a drain of the transistor M753 is electrically connected to the wiring RBL. One of a source and a drain of the transistor M754 is electrically connected to the wiring RBLB. The other of the source and the drain of the transistor M751 and the other of the source and the drain of the transistor M752 are electrically connected to the wiring SAP. The other of the source and the drain of the transistor M753 and the other of the source and the drain of the transistor M754 are electrically connected to the wiring SAN. A gate of the transistor M751 and a gate of the transistor M753 are electrically connected to the wiring RBLB. A gate of the transistor M752 and a gate of the transistor M754 are electrically connected to the wiring RBL. The transistor M751 and the transistor M752 are p-channel transistors. The transistor M753 and the transistor M754 are n-channel transistors.

The precharge circuit 756 is electrically connected to the wiring RBL and the wiring RBLB. The precharge circuit 756 has a function of precharging the wiring RBL with a potential supplied to a wiring VPRE2, in accordance with a signal supplied to a wiring SW4. In addition, the precharge circuit 756 has a function of precharging the wiring RBLB with the potential supplied to the wiring VPRE2, in accordance with a signal supplied to a wiring SW5. Specifically, the precharge circuit 756 includes a transistor M771 and a transistor M772. One of a source and a drain of the transistor M771 is electrically connected to the wiring RBL. One of a source and a drain of the transistor M772 is electrically connected to the wiring RBLB. The other of the source and the drain of the transistor M771 and the other of the source and the drain of the transistor M772 are electrically connected to the wiring VPRE2. A gate of the transistor M771 is electrically connected to the wiring SW4. A gate of the transistor M772 is electrically connected to the wiring SW5. The transistor M771 and the transistor M772 are p-channel transistors.

Here, in the case where any one of the plurality of memory cells 741 in the semiconductor device 710 is selected and data is written to the memory cell 741, a signal is supplied to a wiring WWL electrically connected to the memory cell 741. For example, in the case where data is written to the memory cell 741[1,1] placed in the layer 984[1] in FIG. 17, the potential H is supplied to the wiring WWL electrically connected to the memory cell 741[1,1] and the potential L is supplied to the wirings WWL electrically connected to the other memory cells 741.

In the case where any one of the plurality of memory cells 741 in the semiconductor device 710 is selected and data is read from the memory cell 741, a signal is supplied to a wiring RWL electrically connected to the memory cell 741. For example, in the case where data is read from the memory cell 741[1,1] placed in the layer 984[1] in FIG. 17, the potential H is supplied to the wiring RWL electrically connected to the memory cell 741[1,1] and the potential L is supplied to the wirings RWL electrically connected to the other memory cells 741.

### Memory Cell That Can Be Used for Memory Portion 920

A memory cell of one embodiment of the present invention will be described. The memory cell can be used for the above-described electronic computer 900 illustrated in FIG. 1A and the like, for example. For example, the memory cell can be used as the memory cell 925 included in the memory portion 920.

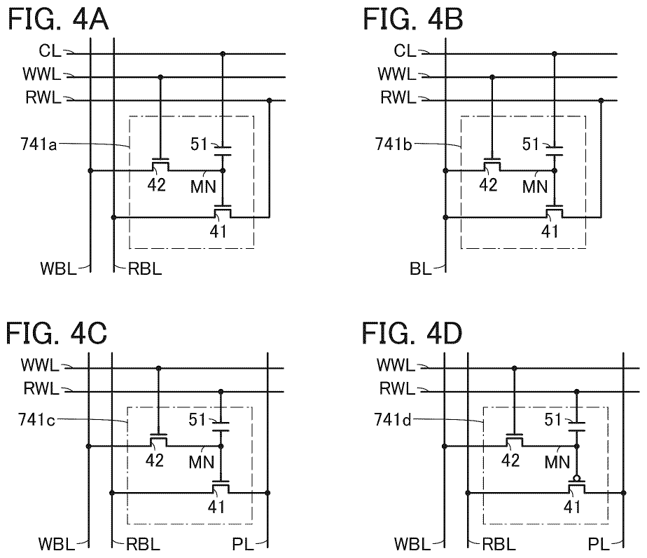

Each of FIG. 4A to FIG. 4D is a circuit diagram illustrating a structure example of the memory cell of one embodiment of the present invention.

A memory cell 741a illustrated in FIG. 4A includes a transistor 42, a transistor 41, and a capacitor 51. One of a source and a drain of the transistor 42 is electrically connected to a gate of the transistor 41 and one terminal of the capacitor 51. The other of the source and the drain of the transistor 42 is electrically connected to a wiring WBL functioning as a write bit line. A gate of the transistor 42 is electrically connected to the wiring WWL functioning as a write word line. One of a source and a drain of the transistor 41 is electrically connected to the wiring RBL functioning as a read bit line. The other of the source and the drain of the transistor 41 is electrically connected to the wiring RWL functioning as a read word line. The other terminal of the capacitor 51 is electrically connected to a wiring CL. Note that a wiring to which the one of the source and the drain of the transistor 42, the gate of the transistor 41, and the one terminal of the capacitor 51 are each electrically connected is referred to as a wiring MN in the description in some cases.

The memory cell 741a can store binary data when the potential corresponding to the amount of charge retained in the wiring MN is made to correspond to “1” or “0”. In the case where data is written to the memory cell 741a, the transistor 42 is brought into a conduction state so that a potential corresponding to data can be supplied from the wiring WBL to the wiring MN. In the case where data is read from the memory cell 741a, the transistor 41 is brought into the conduction state or the non-conduction state in accordance with the potential of the wiring MN so that the potential corresponding to the data can be extracted to the wiring RBL.

In one embodiment of the present invention, an n-channel OS transistor can be used as the transistor 42, for example. An n-channel transistor can also be used as the transistor 41, for example.

Note that a structure in which an OS transistor is used as the transistor 42 in the memory cell 741a illustrated in FIG. 4A is referred to as a NOSRAM (registered trademark) in some cases. The NOSRAM is an abbreviation for a Nonvolatile Oxide Semiconductor RAM. Since an OS transistor having an extremely low off-state current is used in the NOSRAM, data can be stored for a long time. Since the transistor for writing (the transistor 42) and the transistor for reading (the transistor 41) are different from each other, non-destructive reading is performed in data reading. Thus, the memory cell can be used as a nonvolatile memory, for example.

A memory cell 741b illustrated in FIG. 4B is a modification example of the memory cell 741a illustrated in FIG. 4A and is different in that the other of the source and the drain of the transistor 42 is electrically connected to a wiring BL and the one of the source and the drain of the transistor 41 is electrically connected to the wiring BL.

A memory cell 741c illustrated in FIG. 4C is a modification example of the memory cell 741a illustrated in FIG. 4A and is different in that the other of the source and the drain of the transistor 41 is electrically connected to a wiring PL and the other terminal of the capacitor 51 is electrically connected to the wiring RWL.

A memory cell 741d illustrated in FIG. 4D is a modification example of the memory cell 741c illustrated in FIG. 4C and is different in that a p-channel transistor is used as the transistor 41.

### Memory Device That Can Be Used for Memory Cell 741

A specific structure example of a memory device that can be used for the memory cell 741 included in the semiconductor device of one embodiment of the present invention will be described below with reference to drawings.

A memory device of one embodiment of the present invention includes a first transistor, a second transistor, a capacitor, a first insulating layer, and a second insulating layer.

The memory device of one embodiment of the present invention has a structure in which the first transistor, the capacitor, and the second transistor are placed to overlap with each other. Accordingly, the area occupied by the memory device in a plan view can be reduced. For example, in the case where the memory device of one embodiment of the present invention is used for the memory cell 741, the area occupied by the memory cell in a plan view can be reduced. Thus, the memory cell can be miniaturized and a semiconductor device that can be highly integrated can be provided.

In the memory device of one embodiment of the present invention, the second transistor is stacked over the first transistor. Each of the first transistor and the second transistor has a structure in which a source electrode and a drain electrode are provided at different heights from a substrate surface to overlap with each other and a drain current flows in the height direction (vertical direction) (the above-described “vertical transistor”). Thus, these transistors can be miniaturized as compared with a transistor having a structure in which a source electrode and a drain electrode are provided on the same plane (a planar transistor). When the memory device of one embodiment of the present invention includes a transistor having the above-described structure, a semiconductor device that can be further miniaturized and highly integrated can be obtained.

In the memory device of one embodiment of the present invention, the first insulating layer is positioned between the source electrode and the drain electrode of the first transistor, and the second insulating layer is positioned between the source electrode and the drain electrode of the second transistor.

In the memory device of one embodiment of the present invention, part of a component (gate electrode) of the first transistor functions also as part of a component (one of the source electrode and the drain electrode) of the second transistor.

In other words, in the memory device of one embodiment of the present invention, part of a component of the first transistor serves also as part of a component of the second transistor.

In the memory device of one embodiment of the present invention, the second transistor is not stacked to completely overlap with the first transistor in a plan view but is stacked to partly overlap therewith in a plan view. In other words, the second transistor is stacked to be positioned diagonally above the first transistor.

As described above, each of the first transistor and the second transistor in the memory device of one embodiment of the present invention has a structure in which the source electrode and the drain electrode are provided at different heights from a substrate surface to overlap with each other and a drain current flows in the height direction (vertical direction). In other words, the first transistor and the second transistor are each the above-described “vertical transistor”, as opposed to a planar transistor (also referred to as a “lateral transistor”) in which a drain current flows in a plane parallel to a substrate surface.

The vertical transistor is structurally likely to have a depressed portion formed at part of the top surface of the gate electrode provided in the uppermost portion of the transistor; the structures of the first transistor and the second transistor will be described in detail later. Thus, in the case of the structure in which the second transistor is stacked over the first transistor as in the memory device of one embodiment of the present invention, simply stacking the second transistor over the first transistor in a position overlapping with the above-described depressed portion is likely to cause defective contact between the first transistor and the second transistor due to poor coverage over the depressed portion.

In this regard, in the memory device of one embodiment of the present invention, the second transistor is placed such that the semiconductor layer of the second transistor is in contact with a region not overlapping with the depressed portion (a substantially flat region) over the gate electrode of the first transistor. In other words, the second transistor is stacked to be positioned diagonally above the first transistor, as described above. This can inhibit defective contact between the first transistor and the second transistor from being caused by the depressed portion at the top of the first transistor; thus, a memory device with favorable electrical characteristics can be provided. In addition, a method for manufacturing a memory device with a high yield can be provided. Furthermore, the step of planarizing the top surface of the gate electrode of the first transistor is unnecessary, and thus the total number of steps can be reduced. Accordingly, an inexpensive memory device can be obtained.

In the memory device of one embodiment of the present invention, an insulating layer (a third insulating layer) and a conductive layer which are included in part of the capacitor are stacked in this order over the first transistor so as to include a region overlapping with the gate electrode of the first transistor. In the capacitor included in the memory device of one embodiment of the present invention, the gate electrode of the first transistor functions as one electrode, the above-described insulating layer (the third insulating layer) functions as a dielectric layer, and the above-described conductive layer functions as the other electrode. In other words, the memory device of one embodiment of the present invention has a structure in which the insulating layer (the third insulating layer) and the conductive layer which are included in part of the capacitor are provided to include a region overlapping with the first transistor, and the gate electrode of the first transistor has a function of one electrode of the capacitor as well.

In the memory device of one embodiment of the present invention, the side surface of the above-described conductive layer (the conductive layer included in part of the capacitor) and the side surface of part of the gate electrode of the second transistor (a portion embedded in the second insulating layer) are provided to face each other with part of the second insulating layer, part of the semiconductor layer of the second transistor, and part of the gate insulating layer of the second transistor therebetween. Thus, in the memory device of one embodiment of the present invention, a region between the above-described conductive layer and the part of the gate electrode of the second transistor (the portion embedded in the second insulating layer) can also function as the capacitor. In other words, in the memory device of one embodiment of the present invention, the gate electrode of the second transistor can have a function of an electrode of the capacitor as well. It can also be said that the second insulating layer, the semiconductor layer of the second transistor, and the gate insulating layer of the second transistor in a region sandwiched between the above-described conductive layer and the part of the gate electrode of the second transistor (the portion embedded in the second insulating layer) can have a function of a dielectric layer of the capacitor as well.

In other words, in the memory device of one embodiment of the present invention, part of a component of the first transistor serves also as part of a component of the capacitor. Furthermore, part of a component of the second transistor serves also as part of a component of the capacitor.

Accordingly, in the case of the memory device of one embodiment of the present invention, the number of steps can be significantly reduced as compared with the case of manufacturing the first transistor and the second transistor independently. In addition, the number of steps can be significantly reduced as compared with the case of manufacturing the capacitor and the first transistor independently. Furthermore, the number of steps can be significantly reduced as compared with the case of manufacturing the capacitor and the second transistor independently. Accordingly, an inexpensive memory device can be obtained. Furthermore, a method for manufacturing a memory device with a high yield can be provided.

Specific structure examples of the memory device of one embodiment of the present invention will be described below.

### Structure Example 1 of Memory Device

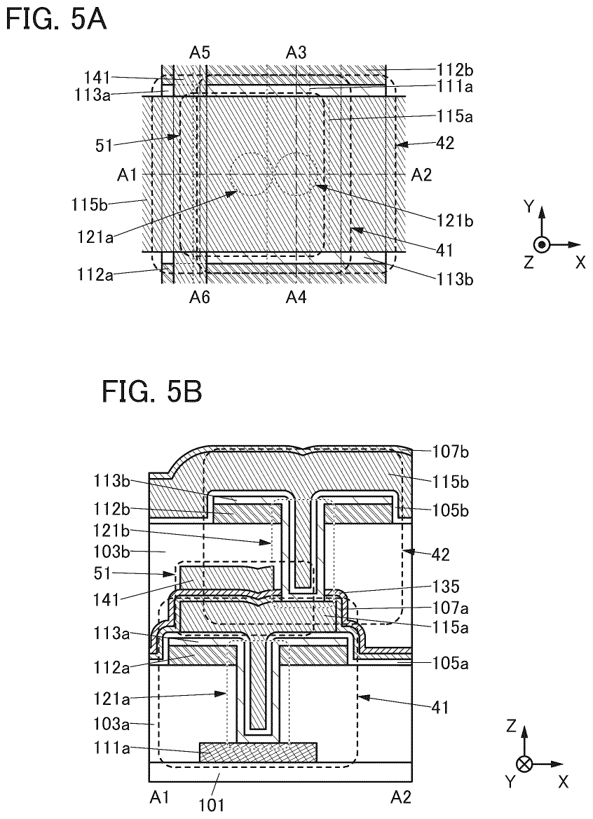

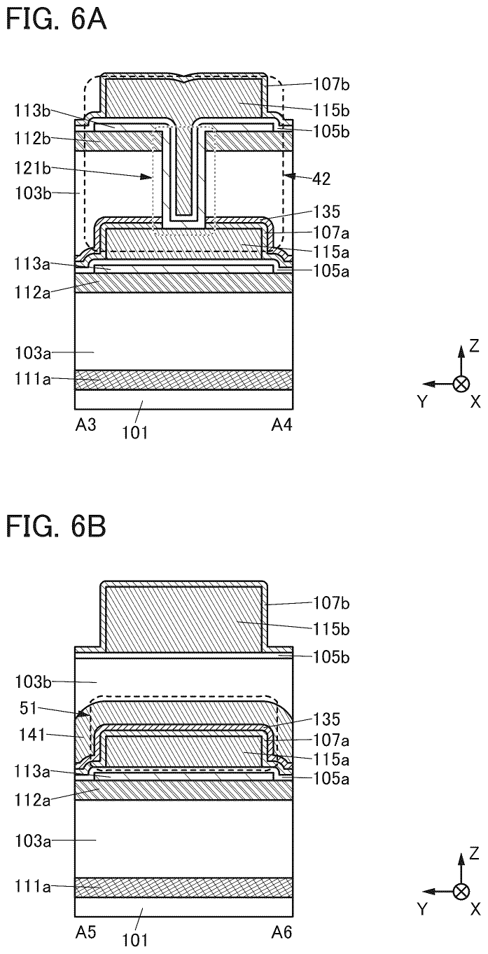

FIG. 5A is a plan view illustrating a structure example of the memory device of one embodiment of the present invention. For clarity of the drawing, some components such as insulating layers are omitted in FIG. 5A. Some components are omitted also in the following plan views. FIG. 5B is a cross-sectional view along the dashed-dotted line A1-A2 in FIG. 5A. FIG. 6A is a cross-sectional view along the dashed-dotted line A3-A4 in FIG. 5A. FIG. 6B is a cross-sectional view along the dashed-dotted line A5-A6 in FIG. 5A.

The memory device of one embodiment of the present invention includes the transistor 41, the transistor 42, the capacitor 51, an insulating layer 103a, and an insulating layer 103b.

The insulating layer 103a is provided over an insulating layer 101. The transistor 41 is provided over the insulating layer 101 to be partly embedded in the insulating layer 103a. Part of the components of the capacitor 51 are provided over the transistor 41 to include a region overlapping with the transistor 41. The insulating layer 103b is provided to cover the transistor 41 and the capacitor 51. The transistor 42 is provided to overlap with the transistor 41 and the capacitor 51 so as to be partly embedded in the insulating layer 103b.

Here, the insulating layer 101, the insulating layer 103a, and the insulating layer 103b function as interlayer insulating layers and are preferably planarized. Note that the insulating layers functioning as the interlayer insulating layers are not necessarily planarized.

The transistor 41 includes a conductive layer 111a, a conductive layer 112a, a semiconductor layer 113a, an insulating layer 105a, and a conductive layer 115a.

The conductive layer 111a functions as one of a source electrode and a drain electrode of the transistor 41. The conductive layer 112a functions as the other of the source electrode and the drain electrode of the transistor 41. The insulating layer 105a functions as a gate insulating layer of the transistor 41. The conductive layer 115a functions as a gate electrode of the transistor 41.

The conductive layer 111a is provided over the insulating layer 101, the insulating layer 103a is provided over the insulating layer 101 and the conductive layer 111a, and the conductive layer 112a is provided over the insulating layer 103a. The conductive layer 111a and the conductive layer 112a have an overlapping region with the insulating layer 103a therebetween. In the example illustrated in FIG. 5A and FIG. 5B, in the X direction, a side end portion of the conductive layer 111a is positioned inward from a side end portion that is of the conductive layer 112a and does not face an opening 121a, i.e., the side end portion of the conductive layer 112a that does not face the opening 121a does not overlap with the conductive layer 111a and the side end portion of the conductive layer 111a overlaps with the conductive layer 112a; however, one embodiment of the present invention is not limited thereto. For example, the side end portion of the conductive layer 111a may be positioned outward from the side end portion of the conductive layer 112a that does not face the opening 121a.

The insulating layer 103a and the conductive layer 112a have the opening 121a reaching the conductive layer 111a. FIG. 5A illustrates an example in which the opening 121a has a circular shape in a plan view. When the top-view shape (the outline shape in a plan view) of the opening 121a is a circle, the processing accuracy at the time of forming the opening 121a can be increased and the opening 121a having a minute size can be formed. Note that the top-view shape of the opening 121a may be an ellipse, a polygon such as a quadrangle, or a polygon with rounded corners, for example.

The semiconductor layer 113a is provided to cover the opening 121a and to include a region positioned in the opening 121a. The semiconductor layer 113a includes a region in contact with the top surface of the conductive layer 112a, a region in contact with the side surface of the conductive layer 112a in the opening 121a, a region in contact with the side surface of the insulating layer 103a in the opening 121a, and a region in contact with the top surface of the conductive layer 111a in the opening 121a. The semiconductor layer 113a has a shape along the top surface of the conductive layer 112a, the side surface of the conductive layer 112a in the opening 121a, the side surface of the insulating layer 103a in the opening 121a, and the top surface of the conductive layer 111a in the opening 121a. Accordingly, the semiconductor layer 113a has a depressed portion in a position overlapping with the opening 121a.

Although FIG. 5B illustrates that, in the X direction, the side surface of the semiconductor layer 113a is substantially aligned with the side surface of the conductive layer 112a on the side not facing the opening 121a, one embodiment of the present invention is not limited thereto. For example, in the X direction, the side surface of the semiconductor layer 113a may be positioned outward or inward from the side surface of the conductive layer 112a on the side not facing the opening 121a.

Note that the semiconductor layer 113a preferably covers a side end portion of the conductive layer 112a on the opening 121a side. For example, FIG. 5A and FIG. 5B illustrate a structure in which, in the X direction, the side end portion of the semiconductor layer 113a extends to the outside of the opening 121a and is substantially aligned with the side end portion of the conductive layer 112a on the side not facing the opening 121a. In other words, in the X direction, the lower end portion of the semiconductor layer 113a is substantially aligned with the upper end portion of the conductive layer 112a. That is, in the illustrated example, the entire semiconductor layer 113a overlaps with the conductive layer 112a or the opening 121a. FIG. 5A and FIG. 5B illustrate a structure in which, in the X direction, the side end portion of the semiconductor layer 113a is positioned outward from the side end portion of the conductive layer 111a. That is, in the illustrated example, part of the semiconductor layer 113a overlaps with the conductive layer 111a.

In this specification and the like, an upper end portion refers to the uppermost portion of a side end portion, and a lower end portion refers to the lowermost portion of a side end portion. That is, the upper end portion and the lower end portion are each part of the side end portion.

Although the semiconductor layer 113a has a single-layer structure in FIG. 5B, FIG. 6A, and FIG. 6B, one embodiment of the present invention is not limited thereto. The semiconductor layer 113a may have a stacked-layer structure of two or more layers.

The insulating layer 105a functioning as the gate insulating layer of the transistor 41 is provided to cover the opening 121a and to include a region positioned in the opening 121a. The insulating layer 105a is provided over the semiconductor layer 113a, the conductive layer 112a, and the insulating layer 103a. The insulating layer 105a includes a region in contact with the top surface of the semiconductor layer 113a, a region in contact with the side surface of the semiconductor layer 113a, a region in contact with the top surface of the conductive layer 112a, a region in contact with the side surface of the conductive layer 112a, and a region in contact with the top surface of the insulating layer 103a. The insulating layer 105a has a shape along the top surface of the semiconductor layer 113a, the side surface of the semiconductor layer 113a, the top surface of the conductive layer 112a, the side surface of the conductive layer 112a, and the top surface of the insulating layer 103a. Accordingly, the insulating layer 105a has a depressed portion in a position overlapping with the opening 121a.

The conductive layer 115a functioning as the gate electrode of the transistor 41 is provided over the insulating layer 105a and includes a region in contact with the top surface of the insulating layer 105a. The conductive layer 115a includes a region overlapping with the semiconductor layer 113a with the insulating layer 105a therebetween. Here, the semiconductor layer 113a can cover the side surface and the bottom surface of the conductive layer 115a with the insulating layer 105a therebetween in the opening 121a. For example, in the opening 121a, the insulating layer 105a includes a region in contact with the side surface of the semiconductor layer 113a, a region in contact with the top surface of the depressed portion of the semiconductor layer 113a, a region in contact with the side surface of the conductive layer 115a, and a region in contact with the bottom surface of the conductive layer 115a.

As described above, the conductive layer 115a is provided to fill the opening 121a with the semiconductor layer 113a and the insulating layer 105a therebetween. Thus, a depressed portion is sometimes formed at part of the top surface of the conductive layer 115a (specifically, at the top of a region of the conductive layer 115a that overlaps with the opening 121a) depending on various conditions such as the depth of the opening 121a, the opening diameter, the thickness of the semiconductor layer 113a, the thickness of the insulating layer 105a, and the thickness of the conductive layer 115a. FIG. 1B and the like illustrate an example in which the conductive layer 115a has a depressed portion at the top surface in a region overlapping with the opening 121a. Note that the top surface of the conductive layer 115a does not necessarily have the depressed portion.

As described above, in the transistor 41 illustrated in FIG. 5B, the semiconductor layer (the semiconductor layer 113a), the gate insulating layer (the insulating layer 105a), and the gate electrode (the conductive layer 115a) are provided in the opening (the opening 121a) formed in the interlayer insulating layer (the insulating layer 103a). In other words, in the transistor 41, the semiconductor layer is provided to surround the gate electrode with the gate insulating layer therebetween in a plan view. Accordingly, the channel length direction of the transistor 41 can be a direction along the side surface of the insulating layer 103a in the opening 121a in a cross-sectional view. Thus, the channel length is not influenced by the performance of a light exposure apparatus used for manufacturing the transistor 41; hence, the channel length can be smaller than the resolution limit of the light exposure apparatus. Consequently, the transistor 41 can be miniaturized. For example, the opening 121a entirely includes a region overlapping with the conductive layer 111a, the semiconductor layer 113a, and the conductive layer 115a in the example illustrated in FIG. 5A; part of the opening 121a is not necessarily overlap with at least one of the conductive layer 111a, the semiconductor layer 113a, and the conductive layer 115a.

The transistor 41 is what is called a top-gate transistor including the gate electrode above the semiconductor layer 113a. Furthermore, since the bottom surface of the semiconductor layer 113a (the surface on the insulating layer 101 side) is in contact with each of the source electrode and the drain electrode, the transistor 41 can be referred to as a TGBC (Top Gate Bottom Contact) transistor.

As illustrated in FIG. 5B and the like, part of the insulating layer 105a is positioned outside the opening 121a, that is, over the conductive layer 112a and the insulating layer 103a. Here, the insulating layer 105a preferably covers the side end portion of the semiconductor layer 113a. This can prevent a short circuit between the conductive layer 115a and the semiconductor layer 113a. Moreover, the insulating layer 105a preferably covers the side end portion of the conductive layer 112a. This can prevent a short circuit between the conductive layer 115a and the conductive layer 112a.

Furthermore, as illustrated in FIG. 5B and the like, part of the conductive layer 115a is positioned outside the opening 121a, that is, over the conductive layer 112a and the insulating layer 103a. Although FIG. 5B and the like illustrate an example in which the side end portion of the conductive layer 115a is positioned inward from the side end portion of the semiconductor layer 113a, one embodiment of the present invention is not limited thereto. The side end portion of the conductive layer 115a may be positioned outward from the side end portion of the semiconductor layer 113a.

An insulating layer 107a is provided in contact with the top surface of the insulating layer 105a, the side surface of the conductive layer 115a, and the top surface of the conductive layer 115a. An insulating layer 135 is provided over the insulating layer 107a. Over the insulating layer 135, a conductive layer 141 is provided to include a region overlapping with the conductive layer 115a. Note that the conductive layer 141 is provided apart from the opening 121b provided in the insulating layer 103b and the conductive layer 112b in a plan view.

The capacitor 51 includes the conductive layer 115a, the conductive layer 141, part of the insulating layer 107a (a portion sandwiched between the conductive layer 115a and the conductive layer 141), and part of the insulating layer 135 (a portion sandwiched between the conductive layer 115a and the conductive layer 141). In addition to the above, the capacitor 51 includes part of a conductive layer 115b (a portion positioned in an opening 121b) that functions as a gate electrode of the transistor 42, and the insulating layer 103b over the transistor 41, a semiconductor layer 113b functioning as a semiconductor layer of the transistor 42, and an insulating layer 105b functioning as a gate insulating layer of the transistor 42 in a region sandwiched between the part of the conductive layer 115b and the conductive layer 141.

The conductive layer 115a functions as one electrode of the capacitor 51. The conductive layer 141 functions as the other electrode of the capacitor 51. Part of the insulating layer 107a (the portion sandwiched between the conductive layer 115a and the conductive layer 141) and part of the insulating layer 135 (the portion sandwiched between the conductive layer 115a and the conductive layer 141) function as a dielectric layer of the capacitor 51.

In addition to the above, part of the conductive layer 115b (the portion positioned in the opening 121b) can function also as the electrode of the capacitor 51. The insulating layer 103b, the semiconductor layer 113b, and the insulating layer 105b in the region sandwiched between the conductive layer 141 and the part of the conductive layer 115b can function also as the dielectric layer of the capacitor 51. As the thickness of the conductive layer 141 increases, the region sandwiched between the conductive layer 141 and the part of the conductive layer 115b increases, and thus the capacitance value of the capacitor 51 can be increased.

In other words, the memory device of one embodiment of the present invention includes regions that can function as capacitors in two portions which are between the conductive layer 141 and the conductive layer 115a and between the conductive layer 141 and part of the conductive layer 115b (the portion positioned in the opening 121b), and the two portions can be collectively referred to as the capacitor 51. With the capacitor 51 having such a structure, a capacitance value required for the operation of the memory device of one embodiment of the present invention can be obtained by adjusting the thickness of the conductive layer 141 even in the case where the conductive layer 141 has a minute top-surface shape.

The insulating layer 103b is provided over the transistor 41 and the capacitor 51.

The insulating layer 107a functions as the dielectric layer of the capacitor 51 and has also a function of inhibiting diffusion of impurities into the transistor 41. For example, the insulating layer 107a has a function of inhibiting diffusion of impurities into the semiconductor layer 113a.

As described above, the insulating layer 135 has a function of the dielectric layer of the capacitor 51. For the insulating layer 135, a high-dielectric-constant material, that is, a high-k material, described in the section [Insulator] below is preferably used. When a high-dielectric-constant material is used for the insulating layer 135, the capacitance value of the capacitor 51 can be increased. Therefore, the memory device can have a long data retention time. Furthermore, an increase in data retention time can decrease the frequency of regular data rewriting (refresh operation), and thus the memory device can have low power consumption.

For the insulating layer 135, a material that can have ferroelectricity, which is described below, may be used, for example. When a material that can have ferroelectricity is used for the insulating layer 135, the memory device can be nonvolatile. Thus, the aforementioned refresh operation is not necessary, and the memory device can have further low power consumption.

Note that part of the insulating layer 103b can also function as the dielectric layer of the capacitor 51, and the insulating layer 103b has also a function of an interlayer insulating layer as described above. Accordingly, for the insulating layer 103b, a low-dielectric-constant material described in the section [Insulator] is preferably used. When a low-dielectric-constant material is used for the insulating layer 103b, the parasitic capacitance between wirings in the memory device can be reduced. For a similar reason, a low-dielectric-constant material is preferably used also for the insulating layer 103a.

The transistor 42 includes the conductive layer 115a, a conductive layer 112b, the semiconductor layer 113b, the insulating layer 105b, and the conductive layer 115b.

The conductive layer 115a functions as one of a source electrode and a drain electrode of the transistor 42. The conductive layer 112b functions as the other of the source electrode and the drain electrode of the transistor 42. The insulating layer 105b functions as a gate insulating layer of the transistor 42. The conductive layer 115b functions as the gate electrode of the transistor 42.

Note that the conductive layer 115a functions also as the gate electrode of the transistor 41 as described above. Thus, in the memory device illustrated in FIG. 5A to FIG. 6B, the conductive layer 115a has both a function of the gate electrode of the transistor 41 and a function of the one of the source electrode and the drain electrode of the transistor 42.

The insulating layer 103b is provided over the conductive layer 115a. The conductive layer 112b is provided over the insulating layer 103b. The conductive layer 115a and the conductive layer 112b have an overlapping region with the insulating layer 103b therebetween.

The conductive layer 112b, the insulating layer 103b, the insulating layer 135, and the insulating layer 107a have the opening 121b reaching the conductive layer 115a. FIG. 5A illustrates an example in which the opening 121b has a circular shape in a plan view. Note that the shape of the opening 121b can be similar to the shape that the opening 121a can have.

The transistor 42 can have a structure similar to that of the above-described transistor 41 except for the structure of the one of the source electrode and the drain electrode described above. The description of the structure of the transistor 41 can be referred to for the description of the structure of the transistor 42 by replacing the transistor 41, the insulating layer 103a, the insulating layer 105a, the conductive layer 112a, the semiconductor layer 113a, and the conductive layer 115a with the transistor 42, the insulating layer 103b, the insulating layer 105b, the conductive layer 112b, the semiconductor layer 113b, and the conductive layer 115b, respectively, and appropriately replacing words or sentences as necessary, except for the structure of the one of the source electrode and the drain electrode described above.

In this specification and the like, the insulating layer 103a and the insulating layer 103b may be collectively referred to as an insulating layer 103. The insulating layer 105a and the insulating layer 105b may be collectively referred to as an insulating layer 105. The insulating layer 107a and an insulating layer 107b may be collectively referred to as an insulating layer 107. The conductive layer 112a and the conductive layer 112b may be collectively referred to as a conductive layer 112. The semiconductor layer 113a and the semiconductor layer 113b may be collectively referred to as a semiconductor layer 113. The conductive layer 115a and the conductive layer 115b may be collectively referred to as a conductive layer 115. The opening 121a and the opening 121b may be collectively referred to as an opening 121.

The insulating layer 107b is provided over the conductive layer 115b and the insulating layer 105b. The insulating layer 107b can be provided to cover the top surface and the side surface of the conductive layer 115b. The insulating layer 107b has a function of inhibiting diffusion of impurities into the transistor 42. For example, the insulating layer 107b has a function of inhibiting diffusion of impurities into the semiconductor layer 113b.

As described above, in the memory device of one embodiment of the present invention, the transistor 41, the capacitor 51, and the transistor 42 are stacked. In each of the transistor 41 and the transistor 42, the semiconductor layer, the gate insulating layer, and the gate electrode are provided in the opening formed in the interlayer insulating layer, one of the source electrode and the drain electrode is provided under the opening, and the other of the source electrode and the drain electrode is provided over the interlayer insulating layer. Accordingly, the area occupied by the memory device in a plan view can be reduced. Thus, the memory device can be miniaturized. Therefore, one embodiment of the present invention can provide a memory device that can be highly integrated.

In the memory device of one embodiment of the present invention, the transistor 42 is not stacked to completely overlap with the transistor 41 in a plan view (which may be said that the transistor 42 is not provided such that the opening 121b completely overlaps with the opening 121a in a plan view) but is stacked to partly overlap therewith in a plan view. In other words, the transistor 42 is stacked to be positioned diagonally above the transistor 41 (which may be said that the transistor 42 is provided such that the opening 121b is positioned diagonally above the opening 121a) as illustrated in FIG. 5B and the like. In this case, as illustrated in FIG. 5A, the transistor 42 is preferably stacked over the transistor 41 such that the opening 121a and the opening 121b do not overlap with each other (i.e., the opening 121a and the opening 121b are at least slightly apart from each other) in a plan view. This enables the bottom surface of the semiconductor layer 113b in the opening 121b to be in contact with the substantially flat top surface of the conductive layer 115a; thus, there is no concern that defective contact between the semiconductor layer 113b and the conductive layer 115a is caused by the depressed portion at the top of the conductive layer 115a. Thus, a memory device with favorable electrical characteristics can be provided. In addition, a method for manufacturing a memory device with a high yield can be provided.

When the transistor 41 and the transistor 42 are in the above-described relationship of placement, the step of planarizing the top surface of the conductive layer 115a is not necessary. Thus, the total number of steps can be reduced, and an inexpensive memory device can be obtained.

In the memory device of one embodiment of the present invention, part of a component of the transistor 41 serves also as part of a component of the transistor 42. In addition, part of a component of the transistor 41 serves also as part of a component of the capacitor 51. Furthermore, part of a component of the transistor 42 serves also as part of a component of the capacitor 51.

Therefore, in the case of the memory device of one embodiment of the present invention, the number of steps can be significantly reduced as compared with the case of manufacturing the transistor 41 and the transistor 42 independently. In addition, the number of steps can be significantly reduced as compared with the case of manufacturing the capacitor 51 and the transistor 41 independently. Furthermore, the number of steps can be significantly reduced as compared with the case of manufacturing the capacitor 51 and the transistor 42 independently. Thus, an inexpensive memory device can be obtained. Furthermore, a method for manufacturing a memory device with a high yield can be provided.

In the cross-sectional views illustrated in FIG. 5B to FIG. 6B, boundaries of the layers cannot be clearly recognized in some cases. For example, a boundary between two insulating layers that are in contact with each other cannot be clearly recognized in some cases. In addition, a boundary between two conductive layers that are in contact with each other cannot be clearly recognized in some cases. Furthermore, a boundary between two semiconductor layers that are in contact with each other cannot be clearly recognized in some cases.

FIG. 7A is an enlarged view of the transistor 41 illustrated in FIG. 5B and the vicinity thereof. FIG. 7B illustrates a plan view of an XY plane of the transistor illustrated in FIG. 7A. Note that the conductive layer 111a is not illustrated in FIG. 7B. The structure illustrated in FIG. 7A can be applied to the transistor 42 by replacing the conductive layer 111a with the conductive layer 115a. The structure illustrated in FIG. 7B can be applied to both the transistor 41 and the transistor 42.

As illustrated in FIG. 7A, the semiconductor layer 113 includes a region 113i, and a region 113na and a region 113nb provided such that the region 113i is sandwiched therebetween.

The region 113na is a region of the semiconductor layer 113 that is in contact with the conductive layer 111a. At least part of the region 113na functions as one of a source region and a drain region of the transistor. The region 113nb is a region of the semiconductor layer 113 that is in contact with the conductive layer 112. At least part of the region 113nb functions as the other of the source region and the drain region of the transistor. As illustrated in FIG. 7B, the conductive layer 112 is in contact with the entire outer perimeter of the semiconductor layer 113. Thus, the other of the source region and the drain region of the transistor can be formed in the entire outer perimeter of a portion of the semiconductor layer 113 that is formed at the same level as the conductive layer 112.

The region 113i is a region of the semiconductor layer 113 that is between the region 113na and the region 113nb. At least part of the region 113i functions as the channel formation region of the transistor. That is, the channel formation region of the transistor is positioned in a region of the semiconductor layer 113 that is between the conductive layer 111a and the conductive layer 112. It can be said that the channel formation region of the transistor is positioned in a region in contact with the insulating layer 103 or a region in the vicinity thereof in the semiconductor layer 113.

The channel length of the transistor is a distance between the source region and the drain region. In other words, the channel length of the transistor is determined by the thickness of the insulating layer 103 over the conductive layer 111a. In FIG. 7A, a channel length L of the transistor is indicated by a solid double-headed arrow. In a cross-sectional view, the channel length L is a distance between an end portion of the region where the semiconductor layer 113 is in contact with the conductive layer 111a and an end portion of the region where the semiconductor layer 113 is in contact with the conductive layer 112. That is, the channel length L corresponds to the length of the side surface of the insulating layer 103 on the opening 121 side in a cross-sectional view.

In a planar transistor, the channel length is determined by the light exposure limit of photolithography, for example. Meanwhile, in the present invention, the channel length can be determined by the thickness of the insulating layer 103. Thus, the transistor can have an extremely small channel length less than or equal to the light exposure limit of photolithography (e.g., greater than or equal to 1 nm and less than or equal to 60 nm, greater than or equal to 5 nm and less than or equal to 50 nm, greater than or equal to 5 nm and less than or equal to 40 nm, greater than or equal to 5 nm and less than or equal to 30 nm, greater than or equal to 5 nm and less than or equal to 20 nm, or greater than or equal to 5 nm and less than or equal to 10 nm). Accordingly, the transistor can have a higher on-state current and improved frequency characteristics. Thus, a memory device with high operation speed can be provided. For example, the reading speed and the writing speed of the memory device can be increased.

Here, although the details will be described later, a transistor using a metal oxide for a semiconductor layer has higher resistance against a short-channel effect than a transistor using silicon for a semiconductor layer. Furthermore, as described above, the transistor having the structure illustrated in FIG. 7A and FIG. 7B, for example, can have a shorter channel length than a planar transistor. Thus, in the case where the transistor has the structure illustrated in FIG. 7A and FIG. 7B, for example, a metal oxide is preferably used for the semiconductor layer 113. Note that a material other than a metal oxide, such as silicon, may be used for the semiconductor layer 113.

As described above, the channel formation region, the source region, and the drain region can be formed in the opening 121. Thus, the area occupied by the transistor can be reduced as compared with a planar transistor in which a channel formation region, a source region, and a drain region are provided separately on the XY plane. This allows high integration of the memory device, thereby increasing the memory capacity per unit area.

As illustrated in FIG. 7B, the semiconductor layer 113, the insulating layer 105, and the conductive layer 115 are provided concentrically on the XY plane including the channel formation region of the semiconductor layer 113. Thus, the side surface of the conductive layer 115 that is provided at the center faces the side surface of the semiconductor layer 113 with the insulating layer 105 therebetween. That is, in a plan view, the entire inner perimeter of the semiconductor layer 113 serves as the channel formation region. In this case, the channel width of the transistor depends on the length of the outer perimeter of the semiconductor layer 113, for example. In other words, the channel width of the transistor depends on the maximum width of the opening 121 (the diameter in the case where the opening 121 is circular in a plan view). In FIG. 7A and FIG. 7B, a maximum width D of the opening 121 is indicated by a dashed double-dotted double-headed arrow. In FIG. 7B, a channel width W of the transistor is indicated by a dashed-dotted double-headed arrow. By increasing the maximum width D of the opening 121, the channel width can be increased and the on-state current can be increased.

The maximum width D of the opening 121 is preferably, for example, greater than or equal to 5 nm and less than or equal to 100 nm, greater than or equal to 10 nm and less than or equal to 60 nm, greater than or equal to 20 nm and less than or equal to 50 nm, greater than or equal to 20 nm and less than or equal to 40 nm, or greater than or equal to 20 nm and less than or equal to 30 nm. Thus, a miniaturized memory device can be obtained as compared with the case of using a planar transistor. A memory device having a high degree of integration can be obtained. In the case where the opening 121 is circular in a plan view as described above, the maximum width D of the opening 121 corresponds to the diameter of the opening 121, and the channel width W can be calculated to be “D×π”.

In the memory device of one embodiment of the present invention, the channel length L of the transistor is preferably shorter than at least the channel width W of the transistor. The channel length L of the transistor in one embodiment of the present invention is greater than or equal to 0.1 times and less than or equal to 0.99 times, preferably greater than or equal to 0.5 times and less than or equal to 0.8 times the channel width W of the transistor. Such a structure enables the transistor to have favorable electrical characteristics and high reliability.

By providing the semiconductor layer 113, the insulating layer 105, and the conductive layer 115 concentrically, the distance between the conductive layer 115 and the semiconductor layer 113 becomes substantially uniform. Thus, a gate electric field can be substantially uniformly applied to the semiconductor layer 113 from the conductive layer 115.

The sidewall of the opening 121 is preferably perpendicular to the top surface of the conductive layer 111a, for example. With the structure, the memory device can be miniaturized or highly integrated. Note that the sidewall of the opening 121 may be tapered.

### Structure Example 2 of Memory Device

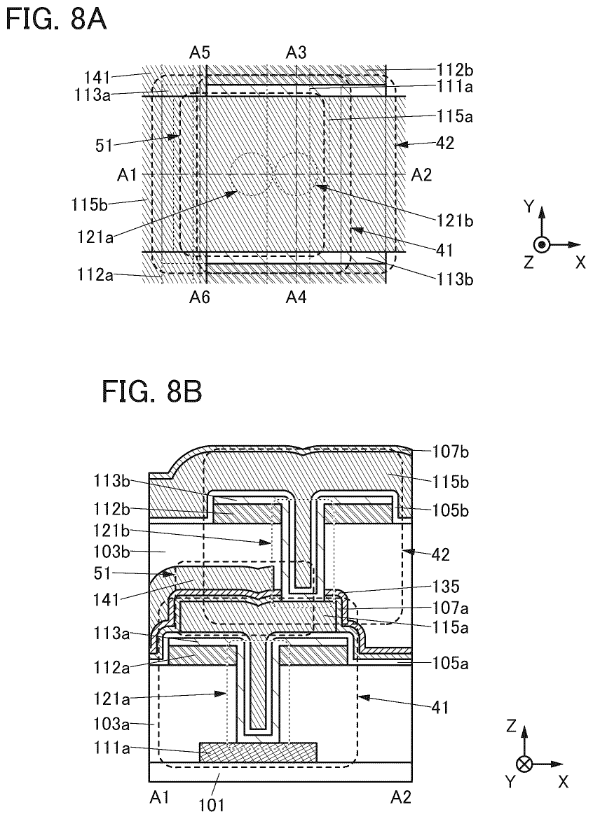

FIG. 8A and FIG. 8B illustrate another structure example of the memory device of one embodiment of the present invention, which is different from that illustrated in FIG. 5A and FIG. 5B. FIG. 8A is a plan view illustrating a structure example of part of the memory device. FIG. 8B is a cross-sectional view along the dashed-dotted line A1-A2 in FIG. 8A. Note that FIG. 6A can be referred to for a cross-sectional view along the dashed-dotted line A3-A4 in FIG. 8A. Note that FIG. 6B can be referred to for a cross-sectional view along the dashed-dotted line A5-A6 in FIG. 8A.

The memory device illustrated in FIG. 8A and FIG. 8B is different from the memory device illustrated in FIG. 5A and FIG. 5B in the structure of the capacitor 51.

Specifically, in the memory device illustrated in FIG. 8A and FIG. 8B, the end portion of the capacitor 51 on the side not facing the opening 121b is positioned outward from that in the memory device illustrated in FIG. 5A and FIG. 5B.

In the capacitor 51 included in the memory device illustrated in FIG. 8A and FIG. 8B, the end portion of the conductive layer 141 on the side not facing the opening 121b extends beyond the end portion of the conductive layer 115a, and the conductive layer 141 includes a region overlapping with not only the conductive layer 115a but also the conductive layer 112a and the insulating layer 103a. Thus, the conductive layer 141 includes a region overlapping with the top surface of the conductive layer 115a, the side surface of the conductive layer 115a, the top surface of the conductive layer 112a, the side surface of the conductive layer 112a, and the top surface of the insulating layer 103a with the insulating layer 107a and the insulating layer 135 therebetween.

In that case, in addition to the structure of the capacitor 51 illustrated in FIG. 5A and FIG. 5B, a region sandwiched between the conductive layer 141 and the side surface of the conductive layer 115a can also function as part of the capacitor 51. A region sandwiched between the conductive layer 141 and the top surface of the conductive layer 112a positioned outward from the conductive layer 115a can also function as part of the capacitor 51. A region sandwiched between the conductive layer 141 and the side surface of the conductive layer 112a can also function as part of the capacitor 51.

Thus, the capacitor 51 illustrated in FIG. 8A and FIG. 8B can have a larger capacitance value than the capacitor 51 illustrated in FIG. 5A and FIG. 5B. Thus, in the case where the memory device illustrated in FIG. 8A and FIG. 8B is used, the memory device can have a longer data retention time and a lower power consumption than in the case where the memory device illustrated in FIG. 5A and FIG. 5B is used.

The capacitor 51 illustrated in FIG. 8A and FIG. 8B has a larger area in a plan view than the capacitor 51 illustrated in FIG. 5A and FIG. 5B, and thus the processing accuracy for the conductive layer 141 is not required to be as high as that in the capacitor 51 illustrated in FIG. 5A and FIG. 5B. Accordingly, the yield of the memory device can be increased.

The description of the memory device illustrated in FIG. 5A and FIG. 5B can be referred to for the memory device illustrated in FIG. 8A and FIG. 8B other than the above-described difference.

### Structure Example 3 of Memory Device

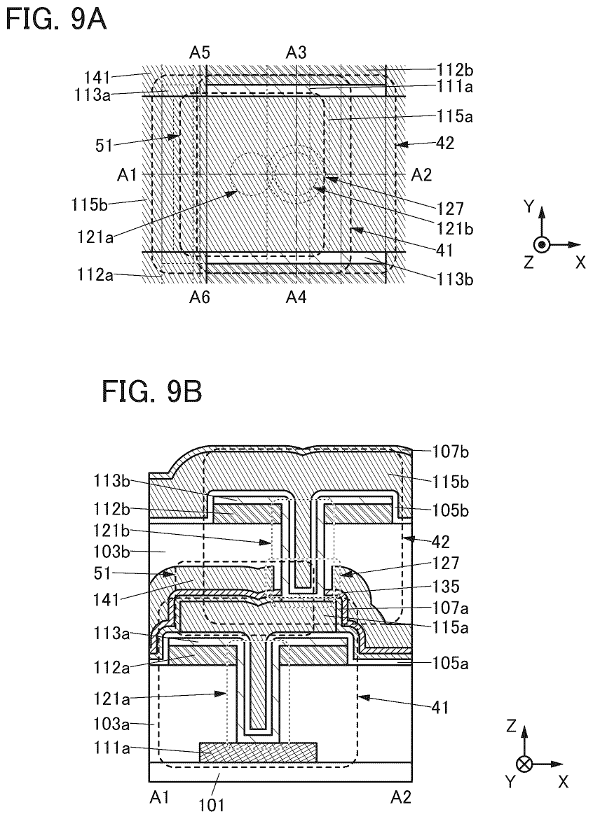

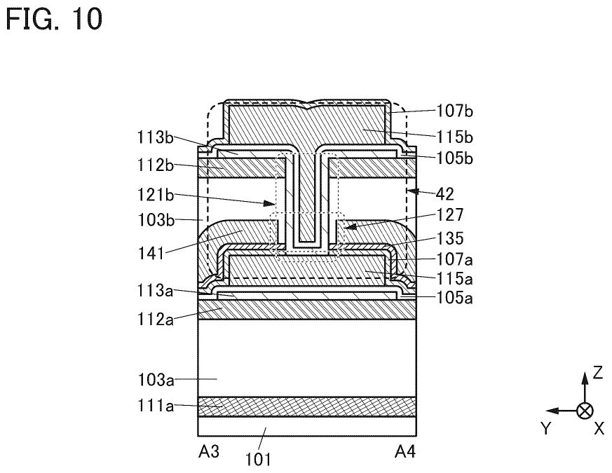

FIG. 9A to FIG. 10 illustrate another structure example of the memory device of one embodiment of the present invention, which is different from the above-described structures. FIG. 9A is a plan view illustrating a structure example of part of the memory device. FIG. 9B is a cross-sectional view along the dashed-dotted line A1-A2 in FIG. 9A, and FIG. 10 is a cross-sectional view along the dashed-dotted line A3-A4 in FIG. 9A. Note that FIG. 8B can be referred to for a cross-sectional view along the dashed-dotted line A5-A6 in FIG. 9A.

The memory device illustrated in FIG. 9A to FIG. 10 is different from the above-described memory devices in the structure of the capacitor 51.

Specifically, the above-described memory device has a structure in which the conductive layer 141 overlaps with part of the conductive layer 115a in a plan view, while the memory device illustrated in FIG. 9A to FIG. 10 has a structure in which the conductive layer 141 overlaps with the entire top surface of the conductive layer 115a to surround the opening 121b in a plan view.

In the memory device illustrated in FIG. 9A to FIG. 10, the conductive layer 141 includes an opening 127 in a region overlapping with the opening 121b in a plan view. The opening 127 is provided to enclose the opening 121b. That is, in the memory device illustrated in FIG. 9A to FIG. 10, the conductive layer 141 includes a region overlapping with the entire top surface of the conductive layer 115a except a region overlapping with the opening 127 in a plan view.

Although FIG. 9A illustrates an example in which the opening 127 has a circular shape in a plan view, one embodiment of the present invention is not limited thereto. For example, the top-view shape of the opening 127 may be an ellipse, a polygon such as a quadrangle, or a polygon with rounded corners. Although FIG. 9A illustrates an example in which the top-view shape of the opening 127 and the top-view shapes of the opening 121a and the opening 121b are the same circular shape, one embodiment of the present invention is not limited thereto. The top-view shape of the opening 127 may be different from the top-view shapes of the opening 121a and the opening 121b.

With this structure, the capacitor 51 illustrated in FIG. 9A to FIG. 10 can have a larger capacitance value than the capacitors 51 included in the above-described memory devices. Thus, the memory device illustrated in FIG. 9A to FIG. 10 can have a longer data retention time and a lower power consumption than the above-described memory devices.

The description of the memory device illustrated in FIG. 5A to FIG. 6B can be referred to for the memory device illustrated in FIG. 9A to FIG. 10 other than the above-described differences.

### Structure Example 4 of Memory Device

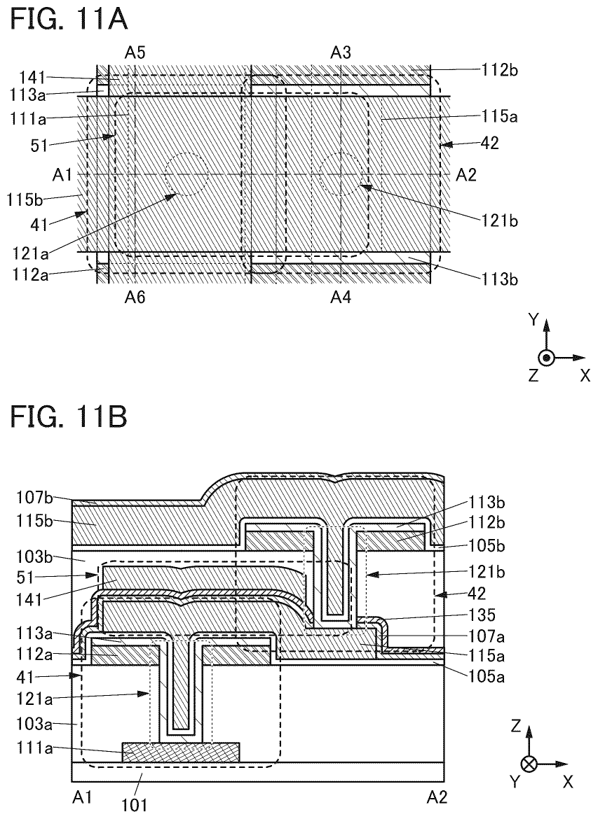

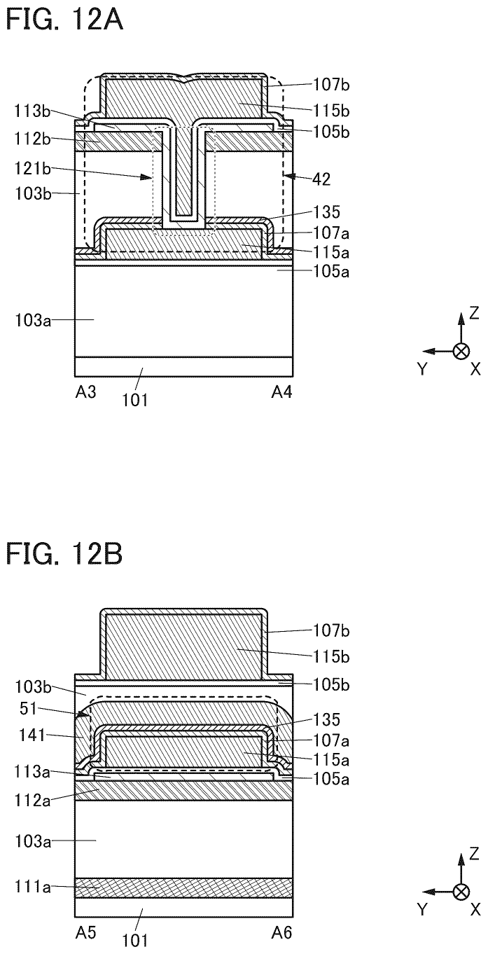

FIG. 11A to FIG. 12B illustrate another structure example of the memory device of one embodiment of the present invention, which is different from the above-described structures. FIG. 11A is a plan view illustrating a structure example of part of the memory device. FIG. 11B is a cross-sectional view along the dashed-dotted line A1-A2 in FIG. 11A. FIG. 12A is a cross-sectional view along the dashed-dotted line A3-A4 in FIG. 11A. FIG. 12B is a cross-sectional view along the dashed-dotted line A5-A6 in FIG. 11A.

The memory device illustrated in FIG. 11A to FIG. 12B is different from the above-described memory device in the shape of the conductive layer 115a functioning as the gate electrode of the transistor 41, the size of the capacitor 51 in a plan view, and the position where the opening 121b is formed.

Specifically, in the above-described memory device, the conductive layer 115a is positioned inward from the conductive layer 112a in a plan view. Meanwhile, in the memory device illustrated in FIG. 11A to FIG. 12B, in the X direction, the end portion of the conductive layer 115a on the A1 side is positioned inward from the end portion of the conductive layer 112a on the A1 side, whereas the end portion of the conductive layer 115a on the A2 side is provided to extend beyond the end portion of the conductive layer 112a on the A2 side.

In the memory device illustrated in FIG. 11A to FIG. 12B, in the X direction, the end portion of the conductive layer 141 on the A2 side is positioned outward from the end portion of the conductive layer 112a on the A2 side, and the size of the capacitor 51 in a plan view (the area of the region where the conductive layer 141 overlaps with the conductive layer 115a with the insulating layer 107a and the insulating layer 135 therebetween) is larger than that in the memory device illustrated in FIG. 5A to FIG. 6B.

In the above-described memory device, the opening 121b is formed to include a region overlapping with both the conductive layer 112a and the conductive layer 115a in a plan view. Meanwhile, in the memory device illustrated in FIG. 11A to FIG. 12B, in the X direction, the opening 121b is formed to be positioned outward from the end portion of the conductive layer 112a on the A2 side and to include a region overlapping with the portion of the conductive layer 115a that extends beyond the conductive layer 112a on the A2 side.

The memory device that is illustrated in FIG. 11A to FIG. 12B and has the above-described structure can include the capacitor 51 whose capacitance value is larger than that in the memory device illustrated in FIG. 5A to FIG. 6B. Thus, in the case where the memory device illustrated in FIG. 11A to FIG. 12B is used, the memory device can have a longer data retention time and a lower power consumption than in the case where the above-described memory devices are used.

As described above, in the memory device illustrated in FIG. 11A to FIG. 12B, in the X direction, the opening 121b is provided to overlap with the region of the conductive layer 115a that extends beyond the conductive layer 112a on the A2 side. The region has a substantially flat top surface as illustrated in FIG. 11B. Thus, the bottom surface of the semiconductor layer 113b can be surely in contact with the top surface of the conductive layer 115a, so that defective contact can be inhibited from being caused therebetween.

Note that the above-described memory device also has a structure in which the semiconductor layer 113b is in contact with the substantially flat top surface of the conductive layer 115a in a region overlapping with the conductive layer 112a; the area of the top surface is preferably as small as possible in view of miniaturization of the transistor 41. Therefore, forming the opening 121b to surely overlap with the top surface requires high processing accuracy. Meanwhile, in the memory device illustrated in FIG. 11A to FIG. 12B, since the conductive layer 115a extends to the A2 side, the portion where the top surface of the conductive layer 115a is substantially flat can be sufficiently obtained in the region outward from the conductive layer 112a. Thus, even when processing accuracy is lower than that in manufacturing the above-described memory device, the bottom surface of the semiconductor layer 113b can be surely in contact with the top surface of the conductive layer 115a. Accordingly, a method for manufacturing a memory device with a higher yield than that of the above-described memory device can be provided.

The description of the memory device illustrated in FIG. 5A to FIG. 6B can be referred to for the memory device illustrated in FIG. 11A to FIG. 12B other than the above-described differences.

### Structure Example 5 of Memory Device

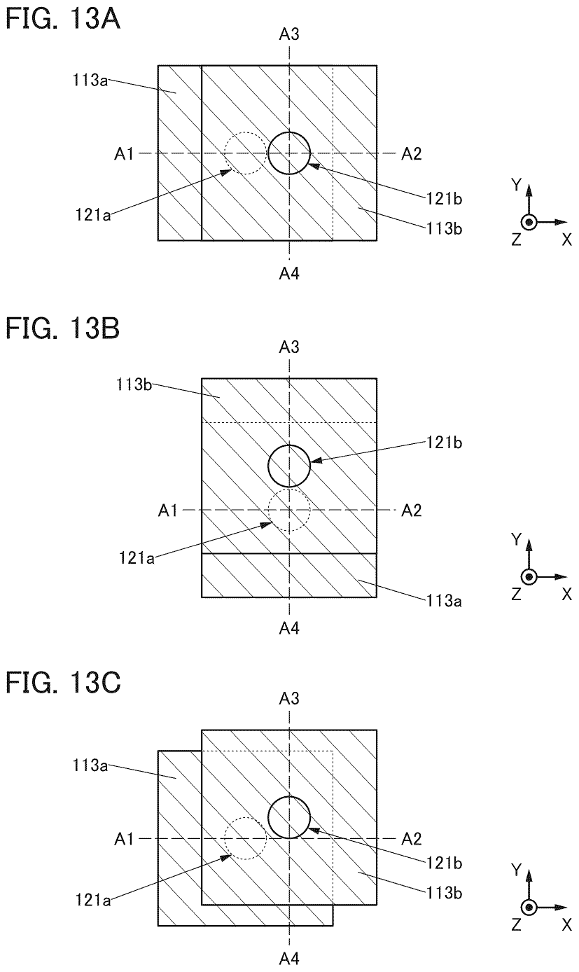

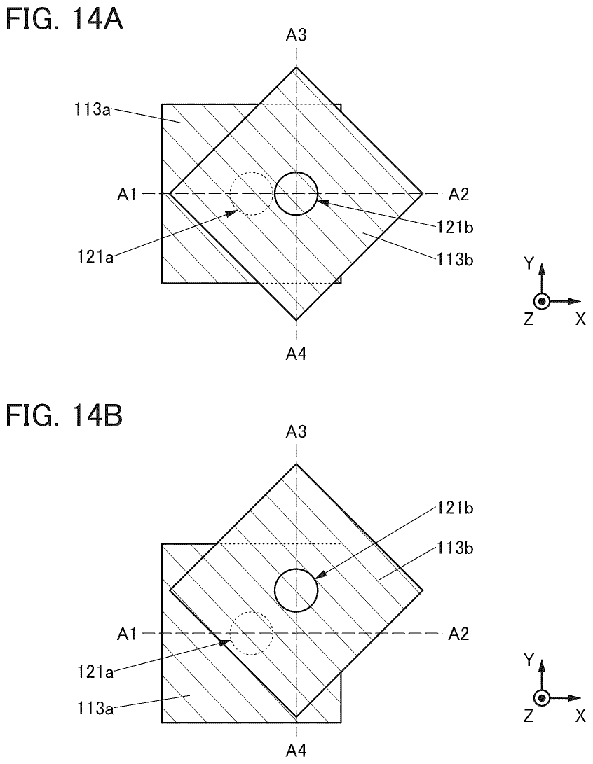

FIG. 13A to FIG. 14B illustrate other structure examples of the memory device of one embodiment of the present invention, which are different from the above-described memory devices. Note that the description below will be made with a focus on the positional relationship between the semiconductor layer 113a and the semiconductor layer 113b in a plan view and the positional relationship between the opening 121a and the opening 121b in a plan view, among the components of the memory device of one embodiment of the present invention.

FIG. 13A to FIG. 14B are schematic plan views each illustrating the positional relationship between the semiconductor layer 113a and the semiconductor layer 113b and the positional relationship between the opening 121a and the opening 121b in the memory device of one embodiment of the present invention. For easy viewing, the components other than the semiconductor layer 113 and the opening 121 in the memory device are not illustrated in each drawing.

FIG. 13A illustrates a structure example in which the semiconductor layer 113b of the transistor 42 is stacked to overlap with the semiconductor layer 113a of the transistor 41 in the state of being slightly shifted in the X direction (to the A2 side) and the opening 121a included in the transistor 41 and the opening 121b included in the transistor 42 are provided not to overlap with each other (i.e., the opening 121a and the opening 121b are slightly apart from each other) in a plan view. This corresponds to the structures of the memory devices illustrated in FIG. 5A to FIG. 10. For the effect of using this structure, the above description of the effect that each of the memory devices illustrated in FIG. 5A to FIG. 10 can have can be referred to.

FIG. 13B illustrates a structure example in which the semiconductor layer 113b of the transistor 42 is stacked to overlap with the semiconductor layer 113a of the transistor 41 in the state of being slightly shifted in the Y direction (to the A4 side) and the opening 121a included in the transistor 41 and the opening 121b included in the transistor 42 are provided not to overlap with each other (i.e., the opening 121a and the opening 121b are slightly apart from each other) in a plan view. Also for the effect of using this structure, the above description of the effect that each of the memory devices illustrated in FIG. 5A to FIG. 10 can have can be referred to.

FIG. 13C illustrates a structure example in which the semiconductor layer 113b of the transistor 42 is stacked to overlap with the semiconductor layer 113a of the transistor 41 in the state of being slightly shifted both in the X direction (to the A2 side) and in the Y direction (to the A4 side) and the opening 121a included in the transistor 41 and the opening 121b included in the transistor 42 are provided not to overlap with each other (i.e., the opening 121a and the opening 121b are slightly apart from each other) in a plan view. This structure example can be regarded as a combination of the structure example illustrated in FIG. 13A and the structure example illustrated in FIG. 13B. Also for the effect of using this structure, the above description of the effect that each of the memory devices illustrated in FIG. 5A to FIG. 10 can have can be referred to. In addition, the alignment accuracy for the semiconductor layer 113b with respect to the semiconductor layer 113a is not required to be as high as that in the structure examples illustrated in FIG. 13A and FIG. 13B. Accordingly, a method for manufacturing a memory device with a higher yield than in the structure examples illustrated in FIG. 13A and FIG. 13B can be provided.

FIG. 14A can be regarded as illustrating a structure in which the semiconductor layer 113b of the transistor 42 in the structure example illustrated in FIG. 13A is rotated 45° around the opening 121b. Also for the effect of using this structure, the above description of the effect that each of the memory devices illustrated in FIG. 5A to FIG. 10 can have can be referred to. In addition, the alignment accuracy for the semiconductor layer 113b with respect to the semiconductor layer 113a is not required to be as high as that in the structure examples illustrated in FIG. 13A and FIG. 13B. Accordingly, a method for manufacturing a memory device with a higher yield than in the structure examples illustrated in FIG. 13A and FIG. 13B can be provided. Although FIG. 14A illustrates the structure example in which the semiconductor layer 113b of the transistor 42 in the structure example illustrated in FIG. 13A is rotated 45° around the opening 121b, the rotation angle is not necessarily limited to 45°.

FIG. 14B illustrates a structure example in which the semiconductor layer 113b of the transistor 42 in the structure example illustrated in FIG. 14A is slightly shifted in the Y direction (to the A4 side). Also for the effect of using this structure, the above description of the effect that each of the memory devices illustrated in FIG. 5A to FIG. 10 can have can be referred to. In addition, the alignment accuracy for the semiconductor layer 113b with respect to the semiconductor layer 113a is not required to be as high as that in the structure examples illustrated in FIG. 13A and FIG. 13B. Accordingly, a method for manufacturing a memory device with a higher yield than in the structure examples illustrated in FIG. 13A and FIG. 13B can be provided.

Although the top-surface shapes of the semiconductor layer 113a and the semiconductor layer 113b are illustrated as quadrangles in FIG. 13A to FIG. 14B, one embodiment of the present invention is not limited thereto. The top-surface shapes of the semiconductor layer 113a and the semiconductor layer 113b may be any of a circle, an ellipse, a polygon other than a quadrangle, and a polygon with rounded corners. The semiconductor layer 113a and the semiconductor layer 113b may have the same or different top-surface shapes.

Although FIG. 13A to FIG. 14B illustrate examples in which the opening 121a and the opening 121b do not overlap with each other (the opening 121a and the opening 121b are apart from each other) in a plan view, the opening 121a and the opening 121b may include an overlapping region when the opening 121b is formed to overlap with the substantially flat top surface of the conductive layer 115a.

### Structure Example 6 of Memory Device

In the memory device of one embodiment of the present invention, each of the conductive layer 111a, the conductive layer 112a, the conductive layer 112b, and the conductive layer 115b functions as an electrode (a source electrode, a drain electrode, or a gate electrode) of a transistor included in the semiconductor device and can extend to function also as a wiring. Although the conductive layer 111a, the conductive layer 112a, and the conductive layer 112b extend in the Y direction and the conductive layer 115b extends in the X direction in the examples of the memory devices illustrated in FIG. 5A to FIG. 12B, one embodiment of the present invention is not limited thereto. A region sandwiched between conductive layers extending in the same direction with an insulating layer therebetween can function as parasitic capacitance. Large parasitic capacitance might induce an adverse effect such as impairing the operation of the memory device. Therefore, the memory device preferably has a structure in which parasitic capacitance is reduced as much as possible. Thus, the memory device of one embodiment of the present invention can have structures with a variety of combinations of the extending dictions of the above-described conductive layers that can function also as wirings. In this manner, parasitic capacitance generated between wirings can be reduced.

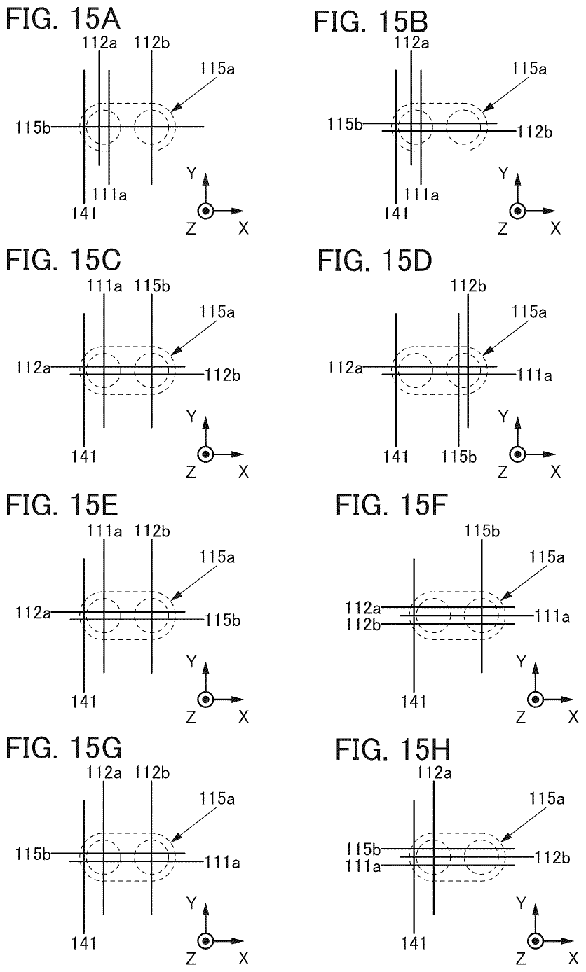

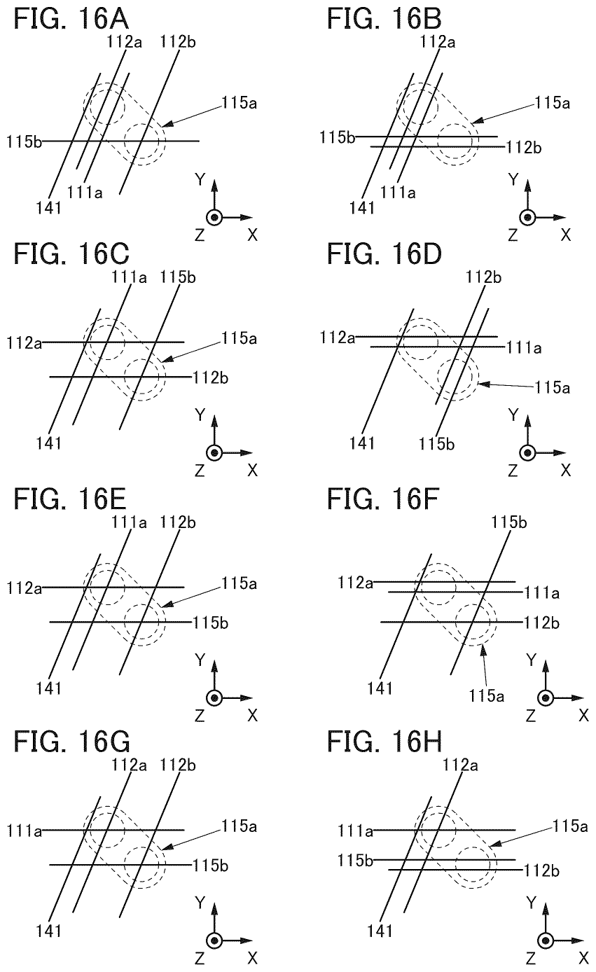

FIG. 15A to FIG. 16H illustrate other structure examples of the memory device of one embodiment of the present invention, which are different from the above-described memory devices. Note that the description below will be made with a focus on the positional relationship between the extending directions of the wirings (the conductive layer 111a, the conductive layer 112a, the conductive layer 112b, and the conductive layer 115b) in a plan view, among the components of the memory device of one embodiment of the present invention. In addition to the above wirings, the conductive layer 141 and the conductive layer 115a are also illustrated in each drawing.

FIG. 15A illustrates a structure example in which the conductive layer 141, the conductive layer 111a, the conductive layer 112a, and the conductive layer 112b extend in the Y direction and the conductive layer 115b extends in the X direction. This corresponds to the structures of the memory devices illustrated in FIG. 5A to FIG. 12B. With this structure, parasitic capacitance between the conductive layer 115b and the other conductive layers (the conductive layer 141, the conductive layer 111a, the conductive layer 112a, and the conductive layer 112b) can be reduced.

FIG. 15B illustrates a structure example in which the conductive layer 141, the conductive layer 111a, and the conductive layer 112a extend in the Y direction and the conductive layer 112b and the conductive layer 115b extend in the X direction. With this structure, parasitic capacitance between each of the conductive layer 112b and the conductive layer 115b and each of the conductive layer 141, the conductive layer 111a, and the conductive layer 112a can be reduced.

FIG. 15C illustrates a structure example in which the conductive layer 141, the conductive layer 111a, and the conductive layer 115b extend in the Y direction and the conductive layer 112a and the conductive layer 112b extend in the X direction. With this structure, parasitic capacitance between each of the conductive layer 112a and the conductive layer 112b and each of the conductive layer 141, the conductive layer 111a, and the conductive layer 115b can be reduced.

FIG. 15D illustrates a structure example in which the conductive layer 141, the conductive layer 112b, and the conductive layer 115b extend in the Y direction and the conductive layer 111a and the conductive layer 112a extend in the X direction. With this structure, parasitic capacitance between each of the conductive layer 111a and the conductive layer 112a and each of the conductive layer 141, the conductive layer 112b, and the conductive layer 115b can be reduced.

FIG. 15E illustrates a structure example in which the conductive layer 141, the conductive layer 111a, and the conductive layer 112b extend in the Y direction and the conductive layer 112a and the conductive layer 115b extend in the X direction. With this structure, parasitic capacitance between each of the conductive layer 112a and the conductive layer 115b and each of the conductive layer 141, the conductive layer 111a, and the conductive layer 112b can be reduced.

FIG. 15F illustrates a structure example in which the conductive layer 141 and the conductive layer 115b extend in the Y direction and the conductive layer 111a, the conductive layer 112a, and the conductive layer 112b extend in the X direction. With this structure, parasitic capacitance between each of the conductive layer 111a, the conductive layer 112a, and the conductive layer 112b and each of the conductive layer 141 and the conductive layer 115b can be reduced.

FIG. 15G illustrates a structure example in which the conductive layer 141, the conductive layer 112a, and the conductive layer 112b extend in the Y direction and the conductive layer 111a and the conductive layer 115b extend in the X direction. With this structure, parasitic capacitance between each of the conductive layer 111a and the conductive layer 115b and each of the conductive layer 141, the conductive layer 112a, and the conductive layer 112b can be reduced.

FIG. 15H illustrates a structure example in which the conductive layer 141 and the conductive layer 112a extend in the Y direction and the conductive layer 111a, the conductive layer 112b, and the conductive layer 115b extend in the X direction. With this structure, parasitic capacitance between each of the conductive layer 111a, the conductive layer 112b, and the conductive layer 115b and each of the conductive layer 141 and the conductive layer 112a can be reduced.

Although each conductive layer that can function as a wiring extends in either the X direction or the Y direction and the conductive layers extending in different directions are orthogonal to each other in a plan view in the examples illustrated in FIG. 15A to FIG. 15H, one embodiment of the present invention is not limited thereto. The angle formed by the conductive layers extending in different directions may be other than 90°. FIG. 16A to FIG. 16H illustrate examples of the case where the angle formed by the conductive layers extending in different directions is an acute angle.

FIG. 16A illustrates an example in which the angle formed by the conductive layers extending in different directions is an acute angle in the positional relationship between the conductive layers illustrated in FIG. 15A. With this structure, an effect similar to that of the structure illustrated in FIG. 15A can be obtained. In addition, the alignment accuracy for each conductive layer is not required to be as high as that in the structure illustrated in FIG. 15A, and the degree of freedom in manufacturing the memory device can be increased.

FIG. 16B illustrates an example in which the angle formed by the conductive layers extending in different directions is an acute angle in the positional relationship between the conductive layers illustrated in FIG. 15B. With this structure, an effect similar to that of the structure illustrated in FIG. 15B can be obtained. In addition, the alignment accuracy for each conductive layer is not required to be as high as that in the structure illustrated in FIG. 15B, and the degree of freedom in manufacturing the memory device can be increased.

FIG. 16C illustrates an example in which the angle formed by the conductive layers extending in different directions is an acute angle in the positional relationship between the conductive layers illustrated in FIG. 15C. With this structure, an effect similar to that of the structure illustrated in FIG. 15C can be obtained. In addition, the alignment accuracy for each conductive layer is not required to be as high as that in the structure illustrated in FIG. 15C, and the degree of freedom in manufacturing the memory device can be increased.

FIG. 16D illustrates an example in which the angle formed by the conductive layers extending in different directions is an acute angle in the positional relationship between the conductive layers illustrated in FIG. 15D. With this structure, an effect similar to that of the structure illustrated in FIG. 15D can be obtained. In addition, the alignment accuracy for each conductive layer is not required to be as high as that in the structure illustrated in FIG. 15D, and the degree of freedom in manufacturing the memory device can be increased.

FIG. 16E illustrates an example in which the angle formed by the conductive layers extending in different directions is an acute angle in the positional relationship between the conductive layers illustrated in FIG. 15E. With this structure, an effect similar to that of the structure illustrated in FIG. 15E can be obtained. In addition, the alignment accuracy for each conductive layer is not required to be as high as that in the structure illustrated in FIG. 15E, and the degree of freedom in manufacturing the memory device can be increased.

FIG. 16F illustrates an example in which the angle formed by the conductive layers extending in different directions is an acute angle in the positional relationship between the conductive layers illustrated in FIG. 15F. With this structure, an effect similar to that of the structure illustrated in FIG. 15F can be obtained. In addition, the alignment accuracy for each conductive layer is not required to be as high as that in the structure illustrated in FIG. 15F, and the degree of freedom in manufacturing the memory device can be increased.

FIG. 16G illustrates an example in which the angle formed by the conductive layers extending in different directions is an acute angle in the positional relationship between the conductive layers illustrated in FIG. 15G. With this structure, an effect similar to that of the structure illustrated in FIG. 15G can be obtained. In addition, the alignment accuracy for each conductive layer is not required to be as high as that in the structure illustrated in FIG. 15G, and the degree of freedom in manufacturing the memory device can be increased.

FIG. 16H illustrates an example in which the angle formed by the conductive layers extending in different directions is an acute angle in the positional relationship between the conductive layers illustrated in FIG. 15H. With this structure, an effect similar to that of the structure illustrated in FIG. 15H can be obtained. In addition, the alignment accuracy for each conductive layer is not required to be as high as that in the structure illustrated in FIG. 15H, and the degree of freedom in manufacturing the memory device can be increased.

Components of the transistors (the transistor 41 and the transistor 42) included in the memory device of one embodiment of the present invention will be described below.

### Components of Transistor

As the semiconductor layer 113 (the semiconductor layer 113a and the semiconductor layer 113b), a single layer or stacked layers of any of the metal oxides described in the section [Metal oxide] below can be used. As the semiconductor layer 113, a single layer or stacked layers of any of the materials, such as silicon, described in the section [Other semiconductor materials] below can be used.

In the case of using a metal oxide for the semiconductor layer 113, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:0.5 [atomic ratio] or in the neighborhood thereof, a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be specifically used for the semiconductor layer 113. Note that a composition in the neighborhood includes the range of ±30 % of an intended atomic ratio. It is preferable to use gallium as the element M.

When the metal oxide is deposited by a sputtering method, the above atomic ratio is not limited to the atomic ratio of the metal oxide deposited and may be the atomic ratio of a sputtering target used for depositing the metal oxide.

For analysis of the composition of the metal oxide used for the semiconductor layer 113, for example, energy dispersive X-ray spectroscopy (EDX: Energy Dispersive X-ray Spectrometry), X-ray photoelectron spectroscopy (XPS: X-ray Photoelectron Spectrometry), inductively coupled plasma-mass spectrometry (ICP-MS), or inductively coupled plasma-atomic emission spectroscopy (ICP-AES: Inductively Coupled Plasma-Atomic Emission Spectrometry) can be used. Alternatively, such kinds of analysis methods may be performed in combination. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage.

An atomic layer deposition (ALD) method can be suitably used to form the metal oxide.

Alternatively, a sputtering method or a chemical vapor deposition (CVD) method may be used to form the metal oxide.

Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

It is preferable that the metal oxide used for the semiconductor layer 113 have crystallinity. Examples of oxide semiconductors having crystallinity include a CAAC-OS (C-Axis Aligned Crystalline Oxide Semiconductor), an nc-OS (nanocrystalline Oxide Semiconductor), a polycrystalline oxide semiconductor, and a single-crystal oxide semiconductor. For the semiconductor layer 113, the CAAC-OS or the nc-OS is preferably used, and the CAAC-OS is particularly preferably used.

The CAAC-OS preferably includes a plurality of layered crystal regions and a c-axis is preferably aligned in a normal direction of a surface where the CAAC-OS is formed. For example, the semiconductor layer 113 preferably includes a layered crystal that is substantially parallel to the sidewall of the opening 121 (the opening 121a and the opening 121b), particularly the side surface of the insulating layer 103 (the insulating layer 103a and the insulating layer 103b). With this structure, the layered crystals of the semiconductor layer 113 are formed substantially parallel to the channel length direction of the transistor, so that the on-state current of the transistor can be increased.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used for the semiconductor layer 113, oxygen extraction from the semiconductor layer 113 by the source electrode or the drain electrode can be inhibited. This can inhibit oxygen extraction from the semiconductor layer 113 even when heat treatment is performed; thus, the transistor is stable with respect to high temperatures in a manufacturing process (what is called thermal budget).

The crystallinity of the semiconductor layer 113 can be analyzed with X-ray diffraction (XRD), a transmission electron microscope (TEM), or electron diffraction (ED), for example. Alternatively, such kinds of analysis methods may be performed in combination.

The thickness of the semiconductor layer 113 is preferably greater than or equal to 1 nm and less than or equal to 20 nm, greater than or equal to 3 nm and less than or equal to 15 nm, greater than or equal to 5 nm and less than or equal to 12 nm, or greater than or equal to 5 nm and less than or equal to 10 nm, for example. Accordingly, also in the opening 121 with a minute diameter, the semiconductor layer 113 can be formed along the sidewall of the opening 121 with high coverage, whereby the manufacturing yield of the transistor can be increased.

Although FIG. 5B, FIG. 6A, FIG. 6B, FIG. 7A, and the like illustrate the semiconductor layer 113 having a single-layer structure, the present invention is not limited thereto. The semiconductor layer 113 may have a stacked-layer structure of a plurality of oxide layers with different chemical compositions. For example, a structure in which a plurality of kinds of metal oxides selected from the above-described metal oxides are stacked as appropriate may be used.

As the insulating layer 105 (the insulating layer 105a and the insulating layer 105b) functioning as the gate insulating layer, a single layer or stacked layers of any of the insulators described in the section [Insulator] below can be used. For the insulating layer 105, silicon oxide or silicon oxynitride can be used, for example. Silicon oxide and silicon oxynitride are preferable because they are thermally stable.

For the insulating layer 105, any of the high-dielectric-constant materials, that is, high-k materials, described in the section [Insulator] below may be used. For example, hafnium oxide, aluminum oxide, or the like may be used.

The thickness of the insulating layer 105 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. At least part of the insulating layer 105 preferably includes a region having the above-described thickness. Accordingly, the insulating layer 105 can be formed along the sidewall of the opening 121 with high coverage also in the opening 121 with a minute diameter, whereby the manufacturing yield of the transistor can be increased.

The concentration of impurities such as water and hydrogen in the insulating layer 105 is preferably reduced. This can inhibit entry of impurities such as water and hydrogen into the channel formation region of the semiconductor layer 113.

Although FIG. 5B, FIG. 6A, FIG. 6B, FIG. 7A, and the like illustrate the insulating layer 105 having a single-layer structure, the present invention is not limited thereto. The insulating layer 105 may have a stacked-layer structure.

As the conductive layer 115 (the conductive layer 115a and the conductive layer 115b) functioning as the gate electrode, a single layer or stacked layers of any of the conductors described in the section [Conductor] below can be used. For example, a conductive material with high conductivity, such as tungsten, aluminum, or copper, can be used for the conductive layer 115.

A conductive material that is less likely to be oxidized, a conductive material having a function of inhibiting diffusion of oxygen, or the like is preferably used for the conductive layer 115. Examples of the conductive material include a conductive material containing nitrogen (e.g., titanium nitride or tantalum nitride) and a conductive material containing oxygen (e.g., ruthenium oxide). This can inhibit a decrease in the conductivity of the conductive layer 115. A semiconductor having high electrical conductivity, typified by polycrystalline silicon containing an impurity element such as phosphorus, or silicide such as nickel silicide may be used for the conductive layer 115.

Although FIG. 5B, FIG. 6A, FIG. 6B, FIG. 7A, and the like illustrate the conductive layer 115 having a single-layer structure, the present invention is not limited thereto. The conductive layer 115 may have a stacked-layer structure.

For the conductive layer 111a, a single layer or stacked layers of any of the conductors described in the section [Conductor] below can be used. A conductive material that is less likely to be oxidized, a conductive material having a function of inhibiting diffusion of oxygen, or the like is preferably used for the conductive layer 111a. For example, titanium nitride, tantalum nitride, or the like can be used. For example, a structure in which tantalum nitride is stacked over titanium nitride may be used. In that case, titanium nitride is in contact with the insulating layer 101 and the insulating layer 103a, and tantalum nitride is in contact with the semiconductor layer 113a. Such a structure can inhibit excessive oxidation of the conductive layer 111a due to the semiconductor layer 113a. In the case of using an oxide insulator for the insulating layer 101 and the insulating layer 103a, the conductive layer 111a can be inhibited from being excessively oxidized by these insulating layers. Alternatively, the conductive layer 111a may have a structure in which tungsten is stacked over titanium nitride, for example.

The conductive layer 111a includes a region in contact with the semiconductor layer 113a and thus is preferably formed using a conductive material containing oxygen, which is described in the section [Conductor] below. When a conductive material containing oxygen is used for the conductive layer 111a, the conductive layer 111a can maintain its conductivity even when absorbing oxygen. As the conductive layer 111a, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

Although FIG. 5B, FIG. 6A, FIG. 6B, FIG. 7A, and the like illustrate a structure in which the top surface of the conductive layer 111a is flat, the present invention is not limited to the structure. For example, the top surface of the conductive layer 111a may have a depressed portion overlapping with the opening 121a. When at least parts of the semiconductor layer 113a, the insulating layer 105a, and the conductive layer 115a are formed to fill the depressed portion, a gate electric field of the conductive layer 115a can be easily applied to a portion of the semiconductor layer 113a near the conductive layer 111a.

Similarly, the top surface of the conductive layer 115a does not necessarily need to be flat; for example, the top surface of the conductive layer 115a may have a depressed portion overlapping with the opening 121b. When at least parts of the semiconductor layer 113b, the insulating layer 105b, and the conductive layer 115b are formed to fill the depressed portion, a gate electric field of the conductive layer 115b can be easily applied to a portion of the semiconductor layer 113b near the conductive layer 115a.

As the conductive layer 112 (the conductive layer 112a and the conductive layer 112b), a single layer or stacked layers of any of the conductors described in the section [Conductor] below can be used. For example, a conductive material with high conductivity, such as tungsten, aluminum, or copper, can be used for the conductive layer 112.

A conductive material that is less likely to be oxidized, a conductive material having a function of inhibiting diffusion of oxygen, or the like is preferably used for the conductive layer 112, as in the case of the conductive layer 111a and the conductive layer 115. For example, titanium nitride, tantalum nitride, or the like can be used. Such a structure can inhibit excessive oxidation of the conductive layer 112 due to the semiconductor layer 113. A semiconductor with high electrical conductivity, typified by polycrystalline silicon containing an impurity element such as phosphorus, or silicide such as nickel silicide may be used for the conductive layer 112, as in the case of the conductive layer 115.

A structure in which tungsten is stacked over titanium nitride may be used, for example. When tungsten is stacked in this manner, the conductivity of the conductive layer 112 can be improved.

In the case where the conductive layer 112 has a structure where a first conductive layer and a second conductive layer are stacked, the first conductive layer may be formed using a conductive material with high conductivity and the second conductive layer may be formed using a conductive material containing oxygen, for example. By using the conductive material containing oxygen for the second conductive layer whose region in contact with the insulating layer 105 is larger in area than that of the first conductive layer, oxygen in the insulating layer 105 can be inhibited from diffusing into the first conductive layer of the conductive layer 112. For example, tungsten is preferably used for the first conductive layer of the conductive layer 112, and indium tin oxide to which silicon is added is preferably used for the second conductive layer of the conductive layer 112.

When the semiconductor layer 113a is in contact with the conductive layer 111a (or the semiconductor layer 113b is in contact with the conductive layer 115a), a metal compound or oxygen vacancies are formed in the semiconductor layer 113 (the semiconductor layer 113a and the semiconductor layer 113b), and the resistance of the region 113na in the semiconductor layer 113 is decreased. The decrease in the resistance of the semiconductor layer 113a in contact with the conductive layer 111a (or the semiconductor layer 113b in contact with the conductive layer 115a) can decrease the contact resistance between the semiconductor layer 113a and the conductive layer 111a (or the contact resistance between the semiconductor layer 113b and the conductive layer 115a). Similarly, when the semiconductor layer 113 is in contact with the conductive layer 112, the resistance of the region 113nb in the semiconductor layer 113 is decreased. Thus, the contact resistance between the semiconductor layer 113 and the conductive layer 112 can be reduced.

The insulating layer 101 and the insulating layer 103 (the insulating layer 103a and the insulating layer 103b) functioning as interlayer insulating layers preferably have a low dielectric constant. When a low-dielectric-constant material is used for the interlayer insulating layers, parasitic capacitance generated between wirings can be reduced. For the insulating layer 101 and the insulating layer 103, a single layer or stacked layers of any of the insulators each including a low-dielectric-constant material described in the section [Insulator] below can be used. In particular, silicon oxide and silicon oxynitride are preferable because they are thermally stable.

The concentration of impurities such as water and hydrogen in the insulating layer 101 and the insulating layer 103 is preferably reduced. This can inhibit entry of impurities such as water and hydrogen into the channel formation region of the semiconductor layer 113.

The insulating layer 103 placed in the vicinity of the channel formation region of the semiconductor layer 113 preferably contains oxygen that is released by heating (hereinafter sometimes referred to as excess oxygen). When heat treatment is performed on the insulating layer 103 containing excess oxygen, oxygen is supplied from the insulating layer 103 to the channel formation region of the semiconductor layer 113, so that oxygen vacancies and defects that are oxygen vacancies into which hydrogen has entered (hereinafter sometimes referred to as VoH) can be reduced in the semiconductor layer 113. Accordingly, the transistor can have stable electrical characteristics and increased reliability.

For the insulating layer 103, an insulator having a function of capturing or fixing hydrogen, which is described in the section [Insulator] below, may be used. With such a structure, hydrogen in the semiconductor layer 113 can be captured or fixed, so that the hydrogen concentration of the semiconductor layer 113 can be reduced. For the insulating layer 103, magnesium oxide, aluminum oxide, or the like can be used.

Although FIG. 5B, FIG. 6A, FIG. 6B, FIG. 7A, and the like illustrate the insulating layer 103 having a single-layer structure, the present invention is not limited thereto. The insulating layer 103 may have a stacked-layer structure.

For the insulating layer 107 (the insulating layer 107a and the insulating layer 107b), any of the insulators with a barrier property against hydrogen, which are described in the section [Insulator] below, is preferably used. In that case, hydrogen can be inhibited from diffusing from outside the transistor to the semiconductor layer 113 through the insulating layer 105. A silicon nitride film and a silicon nitride oxide film can be suitably used for the insulating layer 107 because they release fewer impurities (e.g., water and hydrogen) and are less likely to transmit oxygen and hydrogen.

For the insulating layer 107, any of the insulators having a function of capturing or fixing hydrogen, which are described in the section [Insulator] below, is preferably used. With such a structure, diffusion of hydrogen into the semiconductor layer 113 from above the insulating layer 107 can be inhibited, and hydrogen in the semiconductor layer 113 can be captured or fixed, whereby the hydrogen concentration of the semiconductor layer 113 can be reduced. For the insulating layer 107, magnesium oxide, aluminum oxide, hafnium oxide, or the like can be used. Alternatively, for example, a stacked-layer film of aluminum oxide and silicon nitride over the aluminum oxide may be used for the insulating layer 107.

Although the insulating layer 107 is formed over the top surface of the transistor in the structure illustrated in FIG. 5B, FIG. 6A, FIG. 6B, FIG. 7A, and the like, one embodiment of the present invention is not limited thereto. For example, the insulating layer 107 or an insulating layer that has a similar function and contains a similar material to the insulating layer 107 may be formed on the side surface and the bottom surface of the transistor so that the transistor is surrounded by the insulating layer 107. Alternatively, the insulating layer 107 may be formed on the top surfaces, side surfaces, and bottom surfaces of the transistor 41 and the transistor 42 so that the transistor 41 and the transistor 42 are surrounded by the insulating layer 107. Such a structure can inhibit entry of impurities (e.g., water and hydrogen) into the transistor 41 and the transistor 42.

Components of the capacitor (the capacitor 51) included in the memory device of one embodiment of the present invention will be described below.

### Components of Capacitor

As each of the conductive layer 115a and the conductive layer 141, a single layer or stacked layers of any of the conductors described in the section [Conductor] below can be used. For example, a conductive material with high conductivity, such as tungsten, aluminum, or copper, can be used for the conductive layer 115a and the conductive layer 141. With the use of a conductive material with high conductivity, the conductivity of the conductive layer 115a and the conductive layer 141 can be improved.

As each of the conductive layer 115a and the conductive layer 141, a single layer or stacked layers of a conductive material that is less likely to be oxidized, a conductive material having a function of inhibiting diffusion of oxygen, or the like are preferably used. For example, titanium nitride, indium tin oxide to which silicon is added, or the like may be used. Alternatively, for example, a structure in which titanium nitride is stacked over tungsten may be used. Alternatively, for example, a structure in which tungsten is stacked over a first titanium nitride and a second titanium nitride is stacked over the tungsten may be used. With such a structure, the conductive layer 115a can be inhibited from being oxidized by the insulating layer 135 in the case of using an oxide insulator for the insulating layer 135. Furthermore, the conductive layer 141 can be inhibited from being oxidized by the insulating layer 103b in the case of using an oxide insulator for the insulating layer 103b. A semiconductor having high electrical conductivity, typified by polycrystalline silicon containing an impurity element such as phosphorus, or silicide such as nickel silicide may be used for the conductive layer 115a and the conductive layer 141.

For the insulating layer 107a, any of the above-described insulators having a barrier property against hydrogen is preferably used. Any of the above-described insulators having a function of capturing or fixing hydrogen is preferably used.

For the insulating layer 135, any of the high-dielectric-constant materials, that is, high-k materials, described in the section [Insulator] below is preferably used. Using a high-k material for the insulating layer 135 allows the insulating layer 135 to be thick enough to inhibit a leakage current and the capacitor 51 to have a sufficiently high electrostatic capacitance.

It is preferable to use stacked insulators formed of high-k materials for the insulating layer 135, and it is preferable to use a stacked-layer structure of a high-dielectric-constant (high-k) material and a material having a higher dielectric strength than the high-k material. For the insulating layer 135, an insulating film in which zirconium oxide, aluminum oxide, and zirconium oxide are stacked in this order can be used, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. Using such stacked insulators with relatively high dielectric strength, such as aluminum oxide, can increase the dielectric strength and inhibit electrostatic breakdown of the capacitor 51.

Alternatively, a material that can have ferroelectricity may be used for the insulating layer 135. Examples of the material that can have ferroelectricity include metal oxides such as hafnium oxide, zirconium oxide, and HfZrO_{X} (X is a real number greater than 0). Another example of the material that can have ferroelectricity is a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or in the neighborhood thereof. Another example of the material that can have ferroelectricity is a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Another example of the material that can have ferroelectricity is a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Another example of the material that can have ferroelectricity is a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Other examples of the material that can have ferroelectricity include a perovskite-type oxynitride such as SrTaO₂N and BaTaO₂N, and GaFeO₃ with a κ-alumina-type structure.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulating layer 135 can have a stacked-layer structure of a plurality of materials selected from the above-listed materials. Note that the crystal structures (properties) of the above-listed materials can be changed depending on the processes as well as the deposition conditions. Thus, a material that exhibits ferroelectricity is referred to not only as a ferroelectric but also as a material that can have ferroelectricity or a material that has ferroelectricity in this specification and the like.

A metal oxide containing one or both of hafnium and zirconium is preferable because the metal oxide can have ferroelectricity even when processed into a thin film of several nanometers. Here, the thickness of the insulating layer 135 can be, for example, less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. With the use of the ferroelectric layer that can have a small thickness, the capacitor 51 can be combined with a miniatured semiconductor element such as a transistor to form a memory device. Note that in this specification and the like, the material that can have ferroelectricity processed into a layered shape may be referred to as a ferroelectric layer, a metal oxide film, or a metal nitride film. Furthermore, a device including such a ferroelectric layer, metal oxide film, or metal nitride film may be referred to as a ferroelectric device in this specification and the like.

Alternatively, a metal oxide containing one or both of hafnium and zirconium is preferable because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even a ferroelectric layer with an area less than or equal to 10000 nm² or less than or equal to 1000 nm² has ferroelectricity in some cases. With a small-area ferroelectric layer, the area occupied by the capacitor 51 can be reduced.

Note that a higher concentration of oxygen vacancies (Vₒ) in a metal oxide containing one or both of hafnium and zirconium is more likely to induce generation of a crystal having an orthorhombic crystal structure. Thus, an element that increases the concentration of oxygen vacancies in a metal oxide is preferably added to the metal oxide containing one or both of hafnium and zirconium. Examples of the element include Group 3 elements (also referred to as Group IIIa elements) in the periodic table. A Group 3 element in the periodic table, which is added to the above metal oxide, is preferably one or more selected from scandium, lanthanum, and yttrium, further preferably one or both of lanthanum and yttrium. In this specification and the like, a Group 3 element in the periodic table is sometimes simply referred to as a Group 3 element.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory has a structure which includes a transistor and a ferroelectric capacitor and in which one of a source and a drain of the transistor is electrically connected to one terminal of the ferroelectric capacitor. Thus, in the case of using a ferroelectric capacitor as the capacitor 51, the memory device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer 135 can exhibit ferroelectricity, the insulating layer 135 needs to include a crystal. It is particularly preferable that the insulating layer 135 include a crystal having an orthorhombic crystal structure to exhibit ferroelectricity. Note that a crystal included in the insulating layer 135 may have one or more selected from cubic, tetragonal, orthorhombic, monoclinic, and hexagonal crystal structures. Alternatively, the insulating layer 135 may have an amorphous structure. In that case, the insulating layer 135 may have a composite structure including an amorphous structure and a crystal structure.

The insulating layer 103b preferably has a low dielectric constant as described above. In that case, parasitic capacitance generated between wirings can be reduced. As the insulating layer 103b, a single layer or stacked layers of any of the insulators each including a low-dielectric-constant material described in the section [Insulator] below can be used. In particular, silicon oxide and silicon oxynitride are preferable because they are thermally stable.

### Component Materials of Memory Device

Component materials that can be used for the memory device of one embodiment of the present invention will be described below.

### Substrate

As a substrate where the transistor 41, the transistor 42, and the capacitor 51 are formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used.

### Insulator

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulating layer. When a high-k material is used for the insulator functioning as a gate insulating layer, the voltage at the time of the operation of the transistor can be reduced while the physical thickness is maintained. In addition, the equivalent oxide thickness (EOT) of the insulator functioning as the gate insulating layer can be reduced. In contrast, when a low-dielectric-constant material is used for the insulator functioning as an interlayer insulating layer, parasitic capacitance generated between wirings can be reduced. Thus, a material is preferably selected depending on the function of the insulator. Note that the low-dielectric-constant material is a material with high dielectric strength.

Examples of the high-dielectric-constant (high-k) material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the low-dielectric-constant material include inorganic insulating materials such as silicon oxide, silicon oxynitride, and silicon nitride oxide and resins such as polyester, polyolefin, polyamide (e.g., nylon and aramid), polyimide, polycarbonate, and acrylic. Other examples of low-dielectric-constant inorganic insulating materials include silicon oxide to which fluorine is added, silicon oxide to which carbon is added, and silicon oxide to which carbon and nitrogen are added. Another example is porous silicon oxide. Note that these silicon oxides may contain nitrogen. Silicon oxide may be formed using, for example, organosilane such as tetraethoxysilane (TEOS).

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of the semiconductor layer, such as a gate insulating layer, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of the insulator having a barrier property against hydrogen include aluminum oxide, magnesium oxide, hafnium oxide, gallium oxide, indium gallium zinc oxide, silicon nitride, and silicon nitride oxide.

The insulator having a barrier property against oxygen and the insulator having a barrier property against hydrogen can each be regarded as an insulator having a barrier property against one or both of oxygen and hydrogen.

Examples of the insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond and sometimes has a property of capturing or fixing hydrogen with the dangling bond. Note that these metal oxides preferably have an amorphous structure, but a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability to a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule and OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, and NO₂), and a copper atom. Oxygen described as a target substance refers to, for example, at least one of an oxygen atom and an oxygen molecule. Specifically, a barrier property against oxygen refers to a property that does not easily allow diffusion of at least one of an oxygen atom, an oxygen molecule, and the like.

### Conductor

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is less likely to be oxidized, a conductive material having a function of inhibiting oxygen diffusion, or a material maintaining its conductivity even after absorbing oxygen. Note that examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive material containing oxygen may be referred to as an oxide conductor.

In addition, a conductive material containing tungsten, copper, or aluminum as its main component is preferable because it has high conductivity.

A stack of a plurality of conductors formed of the above-described materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. A stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### Metal Oxide

A metal oxide sometimes has a lattice defect. Examples of the lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor might lead to unstable electrical characteristics of the transistor. Thus, a metal oxide used in a semiconductor layer of a transistor preferably has a small number of lattice defects.

A transistor using a metal oxide is likely to change its electrical characteristics especially in the case where oxygen vacancies (Vₒ) and impurities exist in a channel formation region in the metal oxide, which might degrade the reliability. In some cases, hydrogen in the vicinity of the oxygen vacancy forms VₒH, which generates an electron serving as a carrier. Therefore, when the channel formation region in the metal oxide includes oxygen vacancies, the transistor is likely to have normally-on characteristics (characteristics with which, even when no voltage is applied to the gate electrode, the channel exists and current flows through the transistor). Therefore, oxygen vacancies and impurities are preferably reduced as much as possible in the channel formation region in the metal oxide. In other words, the channel formation region in the metal oxide is preferably an i-type (intrinsic) or substantially i-type region with a reduced carrier concentration.

The kind of lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure.

A metal oxide having an a-like structure and a metal oxide having an amorphous structure each include a void or a low-density region. That is, the metal oxide having the a-like structure and the metal oxide having the amorphous structure have low crystallinity as compared with a metal oxide having the nc structure and a metal oxide having the CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used in a semiconductor layer of a transistor. For example, it is preferable to use the metal oxide having the CAAC structure or the metal oxide having the single crystal structure. The use of such a metal oxide for a transistor enables the transistor to have favorable electrical characteristics. In addition, a transistor with high reliability can be obtained.

For the channel formation region of a transistor, a metal oxide that increases the on-state current of the transistor is preferably used. To increase the on-state current of the transistor, the mobility of the metal oxide used for the transistor is increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Thus, the on-state current of the transistor can be increased by providing a channel formation region through which carriers can easily flow in the channel length direction.

Here, it is preferable to use a metal oxide with high crystallinity for a metal oxide including a channel formation region. The crystal further preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS, and the like.

The c-axis of the above crystal is preferably aligned in the normal direction with respect to the formation surface or film surface of the metal oxide. This enables the plurality of layers to be placed parallel or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ type structure, a Yb₂Fe₃O₇ type structure, their deformed structures, and the like.

Preferably, each of the first layer to the third layer is composed of one metal element or a plurality of metal elements with the same valence and oxygen. The valence of the one or more metal elements included in the first layer is preferably equal to the valence of the one or more metal elements included in the second layer. The first layer and the second layer may include the same metal element. The valence of the one or more metal elements included in the first layer is preferably different from the valence of the one or more metal elements included in the third layer.

The above structure can increase the crystallinity of the metal oxide, which leads to an increase in the mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three kinds selected from indium, an element M, and zinc. Note that the element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be given as an example.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. By an ALD method, a metal oxide having the layered crystal structure is easily formed.

Examples of the ALD method include a thermal ALD method, in which a precursor and a reactant react with each other only by a thermal energy, and a plasma ALD (PEALD: Plasma Enhanced ALD) method, in which a reactant excited by plasma is used.

The ALD method enables atomic layers to be deposited one by one, and has advantages such as deposition of an extremely thin film, deposition on a component with a high aspect ratio, deposition of a film with few defects such as pinholes, deposition with excellent coverage, and low-temperature deposition. The use of plasma in a PEALD method is sometimes preferable because it enables deposition at a lower temperature. Note that a precursor used in the ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS.

When an ALD method is used as the deposition method of a metal oxide, one or both of a deposition condition with a high substrate temperature and impurity removal treatment can form a film with smaller amounts of carbon and chlorine than the case of using an ALD method without the condition and the treatment.

For example, impurity removal treatment is preferably intermittently performed in an atmosphere containing oxygen during deposition of the metal oxide. Furthermore, impurity removal treatment is preferably performed in an atmosphere containing oxygen after the deposition of the metal oxide. Impurities in the film can be removed by performing impurity removal treatment during and/or after the deposition of the metal oxide. This can inhibit impurities (e.g., hydrogen, carbon, and nitrogen) contained in a raw material such as a precursor from remaining in the metal oxide. Accordingly, the impurity concentration in the metal oxide can be reduced. Furthermore, the crystallinity of the metal oxide can be increased.

Examples of the impurity removal treatment include plasma treatment, microwave treatment, and heat treatment.

When plasma treatment or microwave treatment is performed, the substrate temperature is preferably higher than or equal to room temperature (e.g., 25° C.) and lower than or equal to 500° C., higher than or equal to 100° C. and lower than or equal to 450° C., higher than or equal to 200° C. and lower than or equal to 450° C., higher than or equal to 300° C. and lower than or equal to 450° C., or higher than or equal to 400° C. and lower than or equal to 450° C., for example. The temperature of heat treatment is preferably higher than or equal to 100° C. and lower than or equal to 500° C., higher than or equal to 200° C. and lower than or equal to 450° C., higher than or equal to 300° C. and lower than or equal to 450° C., or higher than or equal to 400° C. and lower than or equal to 450° C., for example.

The temperature at the time of the impurity removal treatment is particularly preferably set lower than or equal to the maximum temperature in the manufacturing process of the transistor or the memory device, in which case the impurity content in the metal oxide can be reduced without a decrease in productivity. For example, when the maximum temperature in manufacturing the memory device of one embodiment of the present invention is lower than or equal to 500° C., preferably lower than or equal to 450° C., the productivity of the memory device can be increased.

Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHz, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W, for example. The microwave treatment apparatus may be provided with a power source that applies RF to the substrate side. Application of RF to the substrate side allows oxygen ions generated by the high-density plasma to be introduced into the film efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa, for example. The treatment temperature is preferably higher than or equal to room temperature (25° C.) and lower than or equal to 750° C., further preferably higher than or equal to 300° C. and lower than or equal to 500° C., still further preferably higher than or equal to 400° C. and lower than or equal to 450° C.

The microwave treatment or the plasma treatment can be followed successively by heat treatment without exposure to air. The temperature of the heat treatment is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (O₂/(O₂+Ar)) is still further preferably higher than or equal to 10% and lower than or equal to 30%.

The heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere. The heat treatment may be performed under an atmosphere of ultra-dry air (air with a water content lower than or equal to 20 ppm, lower than or equal to 1 ppm, further preferably lower than or equal to 10 ppb).

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which can improve crystallinity. Thus, a metal oxide having a layered crystal structure with high crystallinity, specifically, a metal oxide having the above-described CAAC structure can be formed.

Unlike a deposition method in which particles ejected from a target are deposited, for example, an ALD method is a deposition method in which a film is formed by reaction at a surface of an object to be processed. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as a sputtering method or a CVD method, in some cases. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

In the ALD method, the composition of a film to be formed can be controlled with the amount of introduced source gases. For example, a film with a certain composition can be deposited by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is deposited while the source gas is changed, as compared to the case where the film is deposited using a plurality of deposition chambers, the time taken for the deposition can be shortened because the time taken for transfer and pressure adjustment is not required. Thus, the productivity of the memory device can be increased in some cases.

### Transistor Including Metal Oxide

Next, the case where a metal oxide (oxide semiconductor) is used for a transistor will be described. Hereinafter, a transistor with a semiconductor layer of an oxide semiconductor is sometimes referred to as an OS transistor, and a transistor with a semiconductor layer of silicon is sometimes referred to as a Si transistor.

The use of the metal oxide (oxide semiconductor) of one embodiment of the present invention for a transistor enables the transistor to have high field-effect mobility. In addition, a transistor with high reliability can be obtained. Furthermore, a miniaturized or highly integrated transistor can be obtained. For example, a transistor with a channel length of greater than or equal to 2 nm and less than or equal to 30 nm can be manufactured.

An oxide semiconductor having a low carrier concentration is preferably used for a channel formation region of a transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that impurities in an oxide semiconductor refer to, for example, elements other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, an OS transistor includes an oxide semiconductor that is a semiconductor material having a wide band gap, and thus can suppress the short-channel effect. In other words, the OS transistor is a transistor in which the short-channel effect does not appear or hardly appears.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value means the amount of change in gate voltage in the subthreshold region by which the drain current is changed by one order of magnitude at a constant drain voltage.

The characteristic length is widely used as an indicator of resistance to the short-channel effect. The characteristic length is an indicator of curving of potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, in the case where a transistor with a short channel length is to be manufactured, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure where the channel formation region is an n⁻-type region and the source region and the drain region are n⁺-type regions.

The OS transistor with the above structure can have favorable electrical characteristics even when a memory device is miniaturized or highly integrated. For example, the OS transistor can have favorable electrical characteristics even when the channel length or gate length of the OS transistor is greater than or equal to 1 nm and less than or equal to 20 nm, greater than or equal to 3 nm and less than or equal to 15 nm, greater than or equal to 5 nm and less than or equal to 10 nm, greater than or equal to 5 nm and less than or equal to 7 nm, or greater than or equal to 5 nm and less than or equal to 6 nm. By contrast, it is sometimes difficult for the Si transistor to have a gate length less than or equal to 20 nm or less than or equal to 15 nm because of the appearance of the short-channel effect. Therefore, the OS transistor can be suitably used as a transistor having a short channel length as compared with the Si transistor. Note that the gate length refers to the length of a gate electrode in a direction in which carriers move inside a channel formation region during operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### Impurity in Metal Oxide

Here, the influence of each impurity in the metal oxide (oxide semiconductor) will be described.

When silicon or carbon, which is one of Group 14 elements, is contained in the oxide semiconductor, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### Other Semiconductor Materials

The semiconductor layer 113 can be rephrased as a semiconductor layer including a channel formation region of the transistor. A semiconductor material that can be used for the semiconductor layer is not limited to the above metal oxides. A semiconductor material that has a band gap (a semiconductor material that is not a zero-gap semiconductor) may be used as the semiconductor. For example, a single-element semiconductor, a compound semiconductor, or a layered substance (also referred to as an atomic layer substance or a two-dimensional material) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon, nitrogen, and boron atoms arranged in a hexagonal lattice structure on a plane. Chalcogenide is a compound containing chalcogen. Chalcogen is a general term for elements belonging to Group 16, which includes oxygen, sulfur, selenium, tellurium, polonium, and livermorium. Examples of chalcogenide include transition metal chalcogenide and chalcogenide of Group 13 elements.

For the semiconductor layer, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a transistor with a high on-state current to be provided.

### Operation Example of Semiconductor Device 710

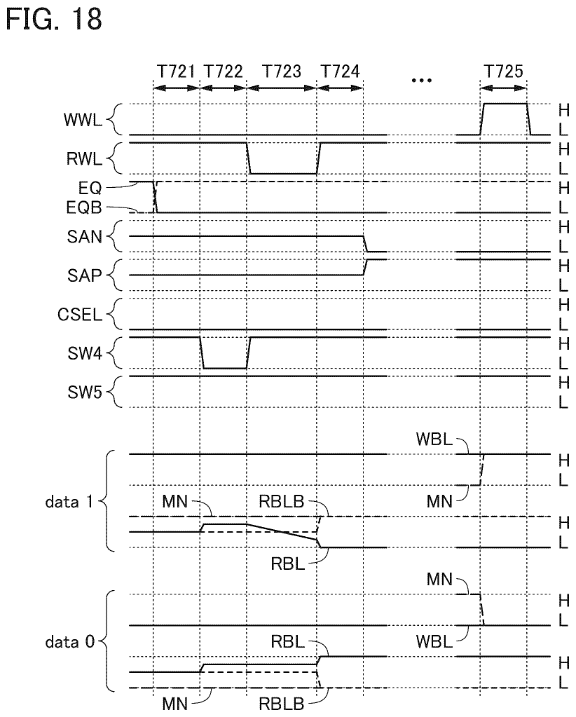

FIG. 18 is a timing chart illustrating an operation example of the semiconductor device 710 illustrated in FIG. 17.

In the following description of the operation, (the potential VDD−the potential VSS)/2 is supplied to the wiring VPRE. A potential (e.g., the potential VDD) that exceeds (the potential VDD−the potential VSS)/2 and does not exceed the potential VDD is supplied to the wiring VPRE2. Any fixed potential (e.g., the potential VSS) is supplied to the wiring CL.

The timing chart in FIG. 18 illustrates the states of signals (the potential H and the potential L) supplied to the wiring WWL, the wiring RWL, the wiring SW4, the wiring SW5, the wiring EQ, the wiring EQB, and the wiring CSEL in operation periods (Period T721 to Period T725). The potentials supplied to the wiring SAP and the wiring SAN are also shown. Changes in the potentials of the wiring MN, the wiring RBL, the wiring RBLB, and the wiring WBL in the case where data “1” is read and written (data 1) and the case where data “0” is read and written (data 0) are also shown.

Period T721 to period T724 are periods for reading data. Period T725 is a period for writing data.

Immediately before Period T721, the potential L is supplied to the wiring WWL, and the potential H is supplied to the wiring RWL. The potential H is supplied to each of the wiring SW4 and the wiring SW5. The potential H is supplied to the wiring EQ, and the potential L is supplied to the wiring EQB. The potential L is supplied to the wiring CSEL. In addition, (the potential VDD−the potential VSS)/2 is supplied to each of the wiring SAP and the wiring SAN. At this time, the wiring RBL and the wiring RBLB are each precharged with (the potential VDD−the potential VSS)/2. In addition, the wiring MN of the memory cell 741 retains the potential VDD (a potential corresponding to data “1”) or the potential VSS (a potential corresponding to data “0”). Note that in the following description, the immediately preceding state is maintained unless otherwise specified.

In Period T721, the potential L is supplied to the wiring EQ, and the potential H is supplied to the wiring EQB. This stops precharging of the wiring RBL and the wiring RBLB. Thus, the wiring RBL and the wiring RBLB each become floating.

In Period T722, the potential L is supplied to the wiring SW4. Then, the wiring RBL is precharged with a potential supplied to the wiring VPRE2. That is, the potential of the wiring RBL becomes higher than the potential of the wiring RBLB.

In Period T723, the potential H is supplied to the wiring SW4. This stops precharging of the wiring RBL. Then, the potential L is supplied to the wiring RWL. Then, the potential of the wiring RBL changes in accordance with the potential of the wiring MN. Thus, the wiring MN can be converted into a potential difference between the wiring RBL and the wiring RBLB.

Specifically, in the case where data stored in the memory cell 741 is “1” (i.e., the potential VDD is retained in the wiring MN), for example, the transistor M702 included in the memory cell 741 is brough into a conduction state, and a current flows from the wiring RBL to the wiring RWL, whereby the potential of the wiring RBL becomes lower than the potential of the wiring RBLB. Alternatively, in the case where the data stored in the memory cell 741 is “0” (i.e., the potential VSS is retained in the wiring MN), for example, the transistor M702 included in the memory cell 741 is brought into a non-conduction state, and a current does not flow from the wiring RBL to the wiring RWL, whereby the potential of the wiring RBL becomes higher than the potential of the wiring RBLB.

In Period T724, the potential H is supplied to the wiring RWL. After that, the potential VSS is supplied to the wiring SAN, and the potential VDD is supplied to the wiring SAP. Then, by the operation of the amplifier circuit 755, the potential difference between the wiring RBL and the wiring RBLB generated by the above-described operation in Period T723 is amplified. Thus, the potentials of the wiring RBL and the wiring RBLB are each determined to be either the potential VDD or the potential VSS. That is, reading of the data stored in the memory cell 741 is completed.

Specifically, in the case where the data stored in the memory cell 741 is “1”, for example, the potential of the wiring RBL becomes the potential VSS and the potential of the wiring RBLB becomes the potential VDD. Alternatively, in the case where the data stored in the memory cell 741 is “0”, for example, the potential of the wiring RBL becomes the potential VDD and the potential of the wiring RBLB becomes the wiring VSS.

In Period T725, the potential H is supplied to the wiring WWL. Then, the potential VDD or the potential VSS of the wiring WBL is supplied to the wiring MN. After that, the potential L is supplied to the wiring WWL, whereby data writing to the memory cell 741 is completed.

Note that the semiconductor device 710 illustrated in FIG. 17 may have a structure in which the wiring WBL and the wiring RBL are electrically connected to each other through a switch, for example. Alternatively, the semiconductor device 710 may have a structure in which the wiring WBL and the wiring RBLB are electrically connected to each other through a switch, for example. With such a structure, when data is written to the memory cell 741, for example, the potential VDD or the potential VSS can be supplied from the sensing circuit 751 to the wiring WBL through the switch. As the switch, a transistor provided in the layer 983 or a transistor provided in the layer 985 can be used, for example.

### Memory Device That Can Be Used for Memory Portion 920

A memory device 720 of one embodiment of the present invention will be described. At least part of the above-described semiconductor device 710 can be used for the memory device 720. At least part of the memory device 720 can be used for the above-described electronic computer 900 illustrated in FIG. 1A and the like, for example. At least part of the memory device 720 can be used for the memory portion 920, for example.

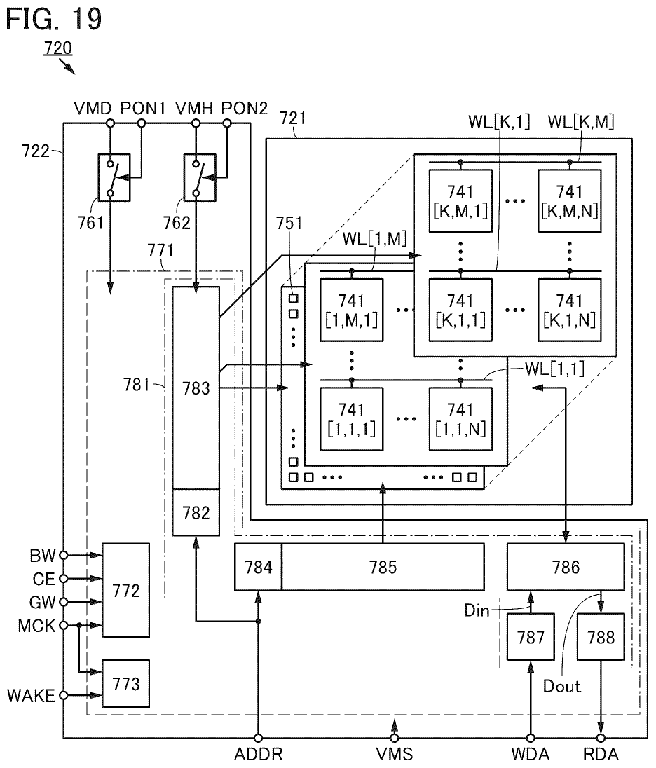

FIG. 19 is a block diagram illustrating a structure example of the memory device 720.

The memory device 720 illustrated in FIG. 19 includes a memory cell array 721 and a driver circuit 722.

In the case where the memory device 720 is used for the memory portion 920 included in the above-described electronic computer 900 in one embodiment of the present invention, the memory array 721 corresponds to the memory array portion 921 and the driver circuit 722 corresponds to the control portion 922, for example.

The memory array 721 includes a plurality of sensing circuits 751 and a plurality of memory cells 741.

In one embodiment of the present invention, the sensing circuits 751 are placed in the layer 985, and the plurality of memory cells 741 are placed in the layer 984[1] to the layer 984[K] as described above.

The plurality of memory cells 741 are placed in a three-dimensional matrix of K layers×M rows×N columns (K, M, and N are each an integer greater than or equal to 1).

Note that FIG. 19 selectively illustrates the memory cell 741[1,1,1] in the first layer, the first row, and the first column, the memory cell 741[1,1,N] in the first layer, the first row, and the N-th column, the memory cell 741[1,M,1] in the first layer, the M-th row, and the first column, the memory cell 741[K,1,1] in the K-th layer, the first row, and the first column, the memory cell 741[K,1,N] in the K-th layer, the first row, and the N-th column, the memory cell 741[K,M,1] in the K-th layer, the M-th row, and the first column, and the memory cell 741[K,M,N] in the K-th layer, the M-th row, and the N-th column.

In addition, FIG. 19 illustrates a wiring WL[1,1] electrically connected to the N memory cells 741 in the first layer and the first row, a wiring WL[1,M] electrically connected to the N memory cells 741 in the first layer and the M-th row, a wiring WL[K,1] electrically connected to the N memory cells 741 in the K-th layer and the first row, and a wiring WL[K,M] electrically connected to the N memory cells 741 in the K-th layer and the M-th row.

The driver circuit 722 includes a power switch 761, a power switch 762, and a peripheral circuit 771. The peripheral circuit 771 includes a peripheral circuit 781, a control circuit 772, and a voltage generation circuit 773.

In one embodiment of the present invention, the driver circuit 722 is placed in the layer 985, for example. Thus, a Si transistor can be used in the driver circuit 722, for example. Note that at least part of the driver circuit 722 can be placed in the layer 983 and the layer 984[1] to the layer 984[K]. Thus, a planar OS transistor and a vertical OS transistor can also be used in at least part of the driver circuit 722.

Signals are supplied to a terminal BW, a terminal CE, a terminal GW, a terminal MCK, a terminal WAKE, a terminal ADDR, a terminal WDA, a terminal PON1, and a terminal PON2 from the outside of the memory device 720, for example. Furthermore, for example, a signal is output from a terminal RDA to the outside of the memory device 720.

For example, a clock signal is supplied to the terminal MCK. Control signals are supplied to the terminal BW, the terminal CE, and the terminal GW. A chip enable signal is supplied to the terminal CE. A global write enable signal is supplied to the terminal GW. A byte write enable signal is supplied to the terminal BW. An address signal is supplied to the terminal ADDR. Data to be written is supplied to the terminal WDA. Read data is supplied to the terminal RDA. Power gating control signals are supplied to the terminal PON1 and the terminal PON2. Note that the signals supplied to the terminal PON1 and the terminal PON2 may be generated in the control circuit 772, for example.

The control circuit 772 has a function of controlling the operation of the memory device 720. The control circuit 772 has a function of performing a logical operation on the signals supplied to the terminal CE, the terminal GW, and the terminal BW to determine an operation mode (e.g., a writing operation or a reading operation) of the memory device 720, for example. The control circuit 772 also has a function of generating a signal for controlling the peripheral circuit 781 so that the operation mode is executed.

The voltage generation circuit 773 has a function of generating a given potential for operating the driver circuit 722. The voltage generation circuit 773 has a function of generating a given potential in response to the input of a clock signal supplied to the terminal MCK in accordance with the signal supplied to the terminal WAKE, for example. To the terminal WAKE, a signal for controlling whether the clock signal supplied to the terminal MCK is input to the voltage generation circuit 773 is supplied, for example.

The peripheral circuit 781 has a function of writing and reading data to and from the memory cells 741. The peripheral circuit 781 has a function of generating a variety of signals for controlling the operation of the memory cells 741 and the sensing circuit 751, for example. The peripheral circuit 781 includes a row decoder 782, a column decoder 784, a row driver 783, a column driver 785, a data driver 786, an input circuit 787, and an output circuit 788.

The row decoder 782 and the column decoder 784 have a function of decoding an address signal supplied to the terminal ADDR. The row decoder 782 has a function of specifying a row to be accessed. In addition, the row decoder 782 has a function of specifying a layer to be accessed. The column decoder 784 has a function of specifying a column to be accessed. The row driver 783 has a function of selecting the row and the layer specified by the row decoder 782 and supplying a desired signal to the corresponding memory cells 741, sensing circuit 751, and the like, for example. The column driver 785 has a function of selecting the column specified by the column decoder 784 and supplying a desired signal to the corresponding sensing circuit 751 or the like, for example.

The data driver 786 has a function of writing and reading data to and from the memory cells 741 selected by the row driver and the column driver. The input circuit 787 has a function of retaining data supplied to the terminal WDA from the outside of the memory device 720. Data (data Din) retained in the input circuit 787 is written to the memory cells 741 through the data driver 786. Data stored in the memory cells 741 is read out to the output circuit 788 through the data driver 786. The output circuit 788 has a function of retaining the read data (data Dout). In addition, the output circuit 788 has a function of outputting the retained data from the terminal RDA to the outside of the memory device 720.

The power switch 761 has a function of controlling whether a potential supplied to a terminal VMD is supplied to the peripheral circuit 771. The power switch 762 has a function of controlling whether a potential supplied to a terminal VMH is supplied to the row driver 783. Here, for example, a high power supply potential (e.g., the potential VDD) for operating the driver circuit 722 is supplied to the terminal VMD, and a low power supply potential (e.g., the potential VSS) is supplied to a terminal VMS. For example, a high power supply potential (e.g., the potential H) for operating the memory cells 741, the sensing circuit 751, and the like is supplied to the terminal VMH. The power switch 761 is controlled to be in the conduction state or the non-conduction state by the signal supplied to the terminal PON1. The power switch 762 is controlled to be in the conduction state or the non-conduction state by the signal supplied to the terminal PON2.

In the driver circuit 722, each circuit and each terminal can be appropriately selected as needed. Another circuit and another terminal may be added as appropriate.

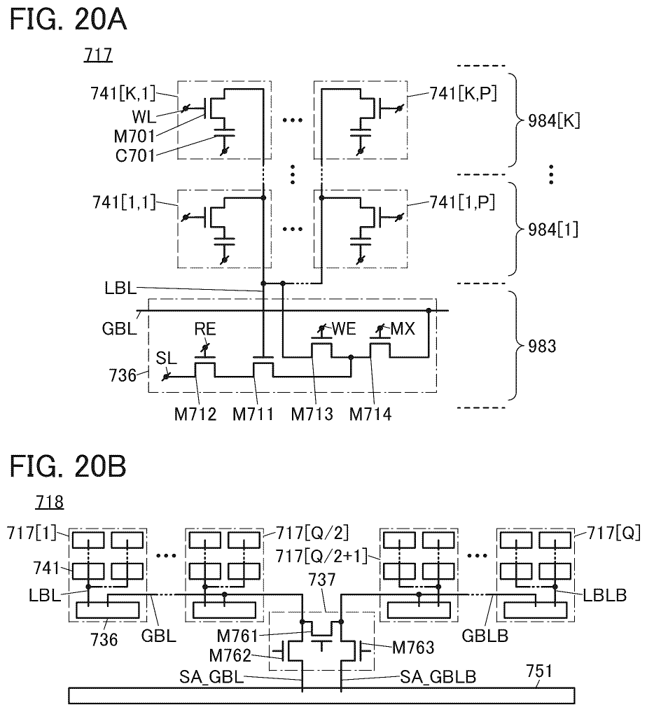

FIG. 20A is a circuit diagram of a memory unit 717 including one sub-sensing circuit 736, a plurality of memory cells 741, and a wiring LBL.

In the memory unit 717, P (P is an integer greater than or equal to 1) memory cells 741 are placed in each of the K layers, the layer 984[1] to the layer 984[K]. That is, the memory unit 717 includes K×P memory cells 741.

FIG. 20A selectively illustrates the memory cell 741[1,1] and the memory cell 741[1,P] placed in the first layer (the layer 984[1]), and the memory cell 741[K,1] and the memory cell 741[K,P] placed in the K-th layer (the layer 984[K]).

FIG. 20B is a circuit diagram of a memory block 718 including one sensing circuit 751, one switch circuit 737, a plurality of memory units 717, a wiring GBL, a wiring GBLB, a wiring SA_GBL, and a wiring SA_GBLB. Here, the memory block 718 corresponds to the semiconductor device 710 described above.

In the memory block 718, Q (Q is an even number greater than or equal to 2) memory units 717 are placed. That is, the memory block 718 includes K×P×Q memory cells 741.

FIG. 20B selectively illustrates the memory unit 717[1] and the memory unit 717[Q/2] which are electrically connected to the wiring GBL, and the memory unit 717[Q/2+1] and the memory unit 717[Q] which are electrically connected to the wiring GBLB.

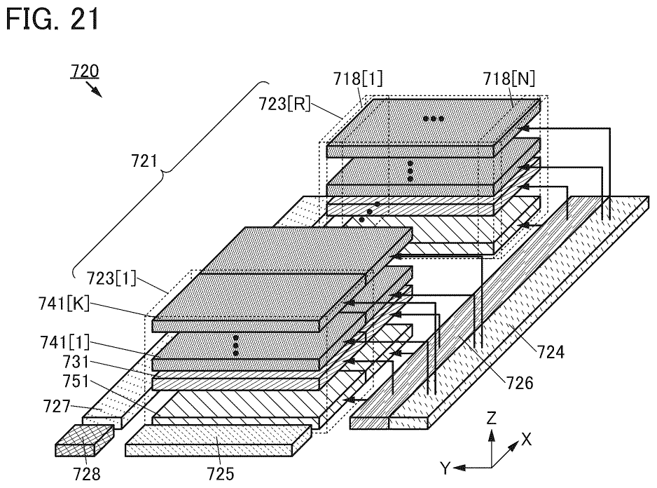

FIG. 21 is a schematic diagram illustrating an example of the placement of components included in the memory device 720.

In the memory device 720 illustrated in FIG. 21, the memory array 721 includes R (R is an integer greater than or equal to 1) memory subarrays 723 arranged in the column direction (X direction), and one memory subarray 723 includes N memory blocks 718 arranged in the row direction (Y direction). That is, the memory array 721 includes R×N memory blocks 718.

Note that FIG. 21 selectively illustrates three memory subarrays 723, two (the memory subarray 723[1] and the memory subarray 723[R]) of which are surrounded by dashed lines. In addition, two memory blocks 718 (the memory block 718[1] and the memory block 718[N]) are selectively surrounded by dashed lines.

As described above, the memory array 721 includes the R×N (R rows×N columns) memory blocks 718. The memory block 718 includes the K×P×Q (K layers×(P×Q rows)) memory cells 741. That is, the memory device 720 includes K×P×Q×R×N memory cells 741 placed in a three-dimensional matrix of K layers×M rows (P×Q×R rows)×N columns in the memory array 721. Since the memory device 720 includes R×N sensing circuits 751, massively parallel reading of data stored in the memory array 721 can be performed by simultaneous access to the plurality of sensing circuits 751.

In the memory device 720, a word line driver 724, a column driver 725, a sense amplifier driver 726, a data driver 727, and a memory controller 728 are placed in the layer 985 around the memory array 721.

Here, for example, the word line driver 724 and the sense amplifier driver 726 correspond to the row driver 783; the column driver 725 corresponds to the column driver 785; the data driver 727 corresponds to the data driver 786, the input circuit 787, and the output circuit 788; and the memory controller 728 corresponds to the control circuit 772 and the voltage generation circuit 773.

Although not illustrated, the memory device 720 can include a layer selection driver that is placed in the layer 983 and the layer 984[1] to the layer 984[K] over the word line driver 724. The layer selection driver can have a function of supplying a signal generated by the word line driver 724 to a given layer.

In the above description of the semiconductor device of one embodiment of the present invention, the OS transistor is a semiconductor element having three terminals of a gate (a first gate), a source, and a drain, but may be a four-terminal semiconductor element including a back gate (a second gate). In the case where the OS transistor includes a back gate, the on-state resistance can be decreased (and the on-state current can be increased) by supply of the same potential as the potential of the gate to the back gate, for example. When the same potential as the potential of the source is supplied to the back gate, for example, an electric field generated outside the transistor is unlikely to affect the channel formation region, and consequently the electrical characteristics can be stabilized and the reliability can be improved. When a given potential is supplied to the back gate, the threshold voltage can be changed, for example. Furthermore, current flowing between the source and the drain can be independently controlled in accordance with potentials supplied to the gate and the back gate, for example.

In the above description of the operation example of the semiconductor device, a rise time and a fall time sometimes are generated at the time of potential change owing to a load on a wiring (parasitic capacitance and parasitic resistance), for example. Such a time is, for example, longer than 0 seconds and is shorter than 1000 nanoseconds, shorter than 100 nanoseconds, shorter than 10 nanoseconds, or shorter than 1 nanosecond. Furthermore, for example, two different operations that appear to occur at the same timing do not necessarily occur at exactly the same timing. The operations can be sometimes considered to occur at the same timing even though a signal delay in a wiring or the like causes a slight time lag between the operations, for example. The time lag is, for example, longer than 0 seconds and is shorter than 1000 nanoseconds, shorter than 100 nanoseconds, shorter than 10 nanoseconds, or shorter than 1 nanosecond.

The plurality of wirings are not necessarily supplied with the same potential H or the same potential L. The potentials supplied to the wirings may be different from each other in consideration of the threshold voltage of the transistor supplied with the potential, for example. Note that the potential H or the potential L supplied to each wiring may have a potential drop due to the threshold voltage of the transistor, for example.

Although the lengths of periods in a timing chart are sometimes shown to be the same, the lengths of the periods may be different from one another. That is, the lengths of periods are set as appropriate for actual operation of the semiconductor device.

The electronic computer, the semiconductor device, and the memory device of one embodiment of the present invention are not limited to the above description. At least part of the structure examples, the operation examples, the drawings corresponding thereto, and the like described in this embodiment as examples can be combined with the other structure examples, the other operation examples, the other drawings, and the other embodiments described in this specification and the like as appropriate, for example.

### Semiconductor Device That Can Be Used for Processing Portion 910

A semiconductor device 810 of one embodiment of the present invention will be described. At least part of the semiconductor device 810 can be used for the above-described electronic computer 900 illustrated in FIG. 1A and the like, for example. At least part of the semiconductor device 810 can be used for the register unit 914 included in the processing portion 910, for example.

### Structure Example

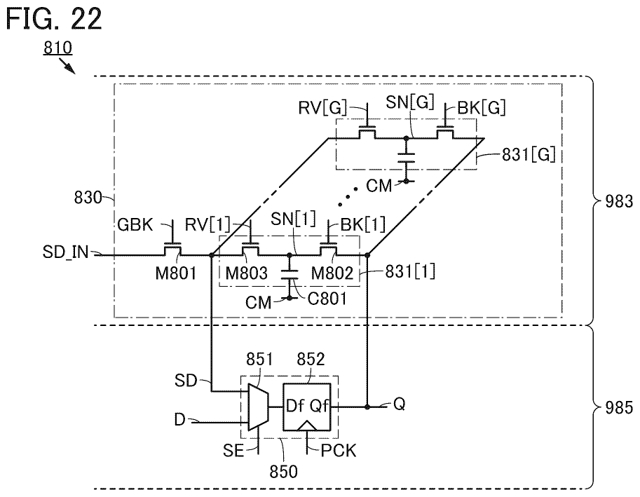

FIG. 22 is a circuit diagram illustrating a structure example of the semiconductor device 810.

The semiconductor device 810 illustrated in FIG. 22 includes a scan flip-flop circuit 850 and a backup circuit 830.

In the case where the semiconductor device 810 is used for the register unit 914 included in the above-described electronic computer 900 in one embodiment of the present invention, the scan flip-flop circuit 850 corresponds to the scan flip-flop 915, and the backup circuit 830 corresponds to the backup memory 916, for example. That is, for example, the scan flip-flop circuit 850 is placed in the layer 985, and the backup circuit 830 is placed in the layer 983. Thus, a Si transistor can be used in the scan flip-flop circuit 850, and an OS transistor can be used in the backup circuit 830, for example.

The scan flip-flop circuit 850 includes a selector circuit 851 and a flip-flop circuit 852. The backup circuit 830 includes a retention circuit 831[1] to a retention circuit 831[G] (G is an integer greater than or equal to 2) and a transistor M801. The retention circuit 831[1] to the retention circuit 831[G] each include a transistor M802, a transistor M803, and a capacitor C801.

A variety of signals for controlling the operation of the semiconductor device 810 are supplied to a wiring BK[1] to a wiring BK[G], a wiring RV[1] to a wiring RV[G], a wiring SE, a wiring PCK, and a wiring GBK.

The semiconductor device 810 can store and retain data input from a wiring D or data input from a wiring SD in the flip-flop circuit 852 in the scan flip-flop circuit 850 and can output the data to a wiring Q in synchronization with a clock signal supplied to the wiring PCK. The data retained in the flip-flop circuit 852 is retained after being written to any one of the retention circuit 831[1] to the retention circuit 831[G] in the backup circuit 830 through the wiring Q in accordance with signals supplied to the wiring BK[1] to the wiring BK[G]. Such an operation is sometimes referred to as saving, storage, backup, or the like. The data retained in any one of the retention circuit 831[1] to the retention circuit 831[G] is retained after being written back to the flip-flop circuit 852 through the wiring SD in accordance with signals supplied to the wiring RV[1] to the wiring RV[G]. Such an operation is sometimes referred to as loading, restoration, recovery, or the like.

The flip-flop circuit 852 has a function of storing and retaining data supplied to an input terminal Df and outputting the data from an output terminal Qf in synchronization with the clock signal supplied to the wiring PCK. As the flip-flop circuit 852, a flip-flop circuit prepared in a standard circuit library can be employed. A positive edge-triggered D flip-flop can be used, for example.

The selector circuit 851 has a function of transmitting data supplied to the wiring D or the wiring SD to the flip-flop circuit 852 in accordance with a signal supplied to the wiring SE. Data input from the outside of the semiconductor device 810 is supplied to the wiring D. The data retained in any one of the retention circuit 831[1] to the retention circuit 831[G] in the backup circuit 830 or data input from a wiring SD_IN is supplied to the wiring SD. Data for a scan test is supplied to the wiring SD_IN.

When a power gating operation is performed, the backup circuit 830 can retain the state of the scan flip-flop circuit 850 in any one of the retention circuit 831[1] to the retention circuit 831[G]. When processing is performed with switching between a plurality of tasks, the backup circuit 830 can retain the state of the scan flip-flop circuit 850 for each task in each of the retention circuit 831[1] to the retention circuit 831[G] in a one-to-one correspondence.

When data is saved in the backup circuit 830, any one of the retention circuit 831[1] to the retention circuit 831[G] is selected in accordance with the signals supplied to the wiring BK[1] to the wiring BK[G]. When data is loaded into the backup circuit 830, any one of the retention circuit 831[1] to the retention circuit 831[G] is selected in accordance with the signals supplied to the wiring RV[1] to the wiring RV[G]. Signals are supplied to the wiring BK[1] to the wiring BK[G] and the wiring RV[1] to the wiring RV[G] in a one-to-one correspondence to the retention circuit 831[1] to the retention circuit 831[G].

Note that a matter common to the retention circuit 831[1] to the retention circuit 831[G] is sometimes described as a matter of the retention circuit 831. In that case, each of the wiring BK[1] to the wiring BK[G] is referred to as the wiring BK, and each of the wiring RV[1] to the wiring RV[G] is referred to as the wiring RV in the description in some cases.

As illustrated in FIG. 22, the retention circuit 831 is electrically connected to each of the wiring Q and the wiring SD. In the retention circuit 831, a terminal (wiring) electrically connected to the wiring Q serves as an input terminal, and a terminal (wiring) electrically connected to the wiring SD serves as an output terminal. That is, in the semiconductor device 810, the output terminal Qf of the flip-flop circuit 852 is electrically connected to the input terminal of the retention circuit 831, and the input terminal Df of the flip-flop circuit 852 is electrically connected to the output terminal of the retention circuit 831 through the selector circuit 851.

In the retention circuit 831, one of a source and a drain of the transistor M802 is electrically connected to one terminal of the capacitor C801. One of a source and a drain of the transistor M803 is electrically connected to the one terminal of the capacitor C801. The other terminal of the capacitor C801 is electrically connected to a wiring CM. The other of the source and the drain of the transistor M802 is electrically connected to the input terminal of the retention circuit 831 (i.e., the wiring Q). The other of the source and the drain of the transistor M803 is electrically connected to the output terminal of the retention circuit 831 (i.e., the wiring SD). A gate of the transistor M802 is electrically connected to the wiring BK. A gate of the transistor M803 is electrically connected to the wiring RV.

In the retention circuit 831[1] to the retention circuit 831[G], wirings to each of which the one of the source and the drain of the transistor M802, the one of the source and the drain of the transistor M803, and the one terminal of the capacitor C801 are electrically connected are sometimes referred to as a wiring SN[1] to a wiring SN[G] in the description. In the case where a matter common to the retention circuit 831[1] to the retention circuit 831[G] is described, each of the wiring SN[1] to the wiring SN[G] is sometimes referred to as a wiring SN in the description.

In the backup circuit 830, one of a source and a drain of the transistor M801 is electrically connected to the wiring SD. The other of the source and the drain of the transistor M801 is electrically connected to the wiring SD_IN.

A gate of the transistor M801 is electrically connected to the wiring GBK. A signal for controlling whether a scan test is performed is supplied to the wiring GBK.

In one embodiment of the present invention, OS transistors can be used as the transistor M801, the transistor M802, and the transistor M803, for example. OS transistors have a characteristic of extremely low off-state current. In addition, OS transistors have a characteristic of off-state current that hardly increases and on-state current that is unlikely to decrease even in a high-temperature environment.

Accordingly, the retention circuit 831 can retain data written to the wiring SN for a long time when the transistor M802 and the transistor M803 are brought into a non-conduction state. For example, the data can be continuously retained even in a state where power is not supplied to the scan flip-flop circuit 850 for a power gating operation. That is, the retention circuit 831 can be used as a nonvolatile memory.

Here, when data retained in the wiring SN is written back to the flip-flop circuit 852 in the semiconductor device 810, the potential of the data may change owing to parasitic capacitance of the wiring SD. Thus, the electrostatic capacitance of the capacitor C801 is preferably larger than the parasitic capacitance of the wiring SD so that the amount of change in the potential of the data is smaller than the logic threshold value of the flip-flop circuit 852 or the like, for example.

In another structure example of the semiconductor device 810, a structure may be employed in which the transistor M801 is provided for every plurality of retention circuits 831. For example, a structure may be employed in which a Si transistor is used as the transistor M801.

The semiconductor device 810 may have a structure in which a plurality of layers 983 are stacked and each of the layers 983 is provided with the backup circuit 830 in order to increase the number of retention circuits 831 without increasing the area overhead.

In one embodiment of the present invention, the backup circuit 830 can be provided in the semiconductor device 810 without change in the circuit structure and layout of the scan flip-flop circuit 850. That is, the backup circuit 830 is a circuit that has very broad utility.

Since the semiconductor device 810 has a structure in which the backup circuit 830 is stacked over the scan flip-flop circuit 850, the lengths of wirings that electrically connect the two can be short. Accordingly, energy (access energy) necessary for data saving and data loading can be reduced. Thus, power consumption of the semiconductor device 810 can be reduced.

### Operation Example 1

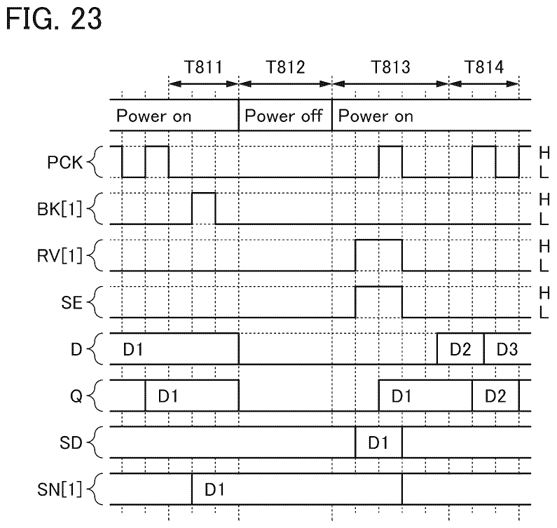

FIG. 23 is a timing chart illustrating an operation example of the semiconductor device 810 illustrated in FIG. 22.

Described in this operation example 1 is an operation example of the semiconductor device 810 in the case where a power gating operation is performed in the above-described electronic computer 900, for example.

Here, the operation of the semiconductor device 810 is described using an example where the number of retention circuits 831 included in the backup circuit 830 is four (G=4).

In the following description of the operation, the flip-flop circuit 852 stores data supplied to the input terminal Df and outputs the data from the output terminal Qf in synchronization with the timing at which the clock signal supplied to the wiring PCK switches from the potential L to the potential H (the rising edge). The potential L is supplied to the wiring GBK. A constant potential (e.g., the potential VSS) is supplied to the wiring CM.

The timing chart in FIG. 23 illustrates the states of signals (the potential H and the potential L) supplied to the wiring PCK, the wiring BK[1], the wiring RV[1], and the wiring SE in operation periods (Period T811 to Period T814). Note that illustrations for the wiring BK[2] to the wiring BK[4] and the wiring RV[2] to the wiring RV[4] are omitted. In addition, the timing chart in FIG. 23 illustrates the state of data (any one of data D1 to data D3) supplied to each of the wiring D, the wiring Q, the wiring SD, and the wiring SN[1]. Note that illustrations for the wiring SN[2] to the wiring SN[4] are omitted. In addition, the timing chart in FIG. 23 illustrates a state where power is supplied to the scan flip-flop circuit 850 (Power on) or a state where power is not supplied (Power off).

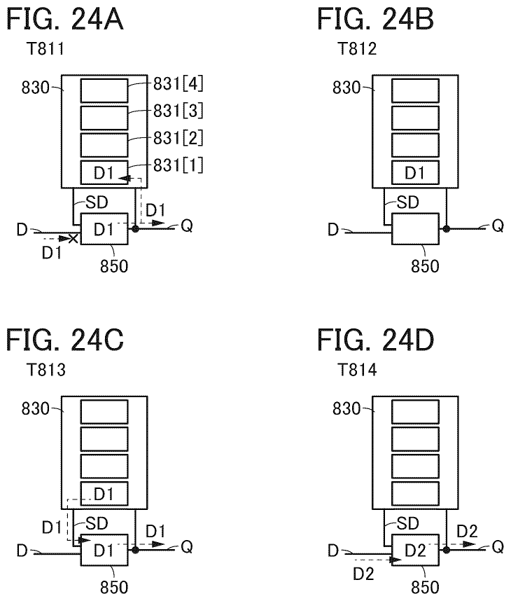

FIG. 24A to FIG. 24D are schematic diagrams illustrating the manner in which data is stored in the scan flip-flop circuit 850 and the retention circuit 831[1] to the retention circuit 831[4] included in the backup circuit 830 in the periods of the timing chart illustrated in FIG. 23. In the schematic diagrams, the manner in which data is input and output (data flow) is indicated by dashed arrows.

Immediately before Period T811, the potential L is supplied to each of the wiring BK[1] to the wiring BK[4], the wiring RV[1] to the wiring RV[4], and the wiring SE. The states of the data supplied to the wiring SN[1] and the wiring SN[2] are indeterminate (none of the data D1 to the data D3 is illustrated). The clock signal is supplied to the wiring PCK. Power is supplied to the scan flip-flop circuit 850. The data D1 is stored in the scan flip-flop circuit 850. Note that in the following description, the immediately preceding state is maintained unless otherwise specified.

In Period T811, first, the clock signal supplied to the wiring PCK is stopped.

Next, the potential H is supplied to the wiring BK[1], whereby the data D1 output to the wiring Q is stored in the wiring SN[1] of the retention circuit 831[1]. After that, the potential L is supplied to the wiring BK[1], whereby the data D1 stored in the wiring SN[1] is retained.

In Period T812, power supply to the scan flip-flop circuit 850 is stopped. Then, the data D1 stored in the scan flip-flop circuit 850 is lost. At that time, the data D1 retained in the wiring SN[1] of the retention circuit 831[1] is retained.

In Period T813, first, power supply to the scan flip-flop circuit 850 is restarted.

Next, the potential H is supplied to the wiring RV[1], whereby the data D1 stored in the wiring SN[1] of the retention circuit 831[1] is supplied to the wiring SD, and the potential H is supplied to the wiring SE, whereby the wiring SD is selected.

Next, a pulse signal is supplied to the wiring PCK, whereby the data D1 supplied to the wiring SD is stored in the scan flip-flop circuit 850 and output to the wiring Q in synchronization with the rising edge. After that, the potential L is supplied to the wiring RV[1] and the wiring SE.

In Period T814, first, the clock signal supplied to the wiring PCK is restarted. The data D2 is supplied to the wiring D. Then, the data D2 supplied to the wiring D is stored in the scan flip-flop circuit 850 and output to the wiring Q in synchronization with the rising edge of the clock signal.

In the above manner, the semiconductor device 810 can be operated as illustrated in the timing chart in FIG. 23. Accordingly, in the case where a power gating operation is performed in the electronic computer 900, when the scan flip-flop circuit 850 is powered on, for example, it can be promptly returned to a state immediately before power-off, and the time taken for the restart of processing can be shortened.

### Operation Example 2

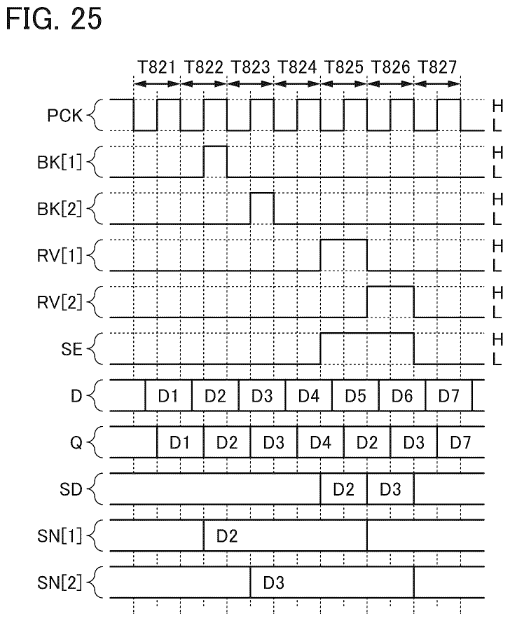

FIG. 25 is a timing chart illustrating an operation example of the semiconductor device 810 illustrated in FIG. 22.

Described in this operation example 2 is an operation example of the semiconductor device 810 in the case where processing is performed with switching between a plurality of tasks in the above-described electronic computer 900, for example.

Here, the operation of the semiconductor device 810 is described using an example where the number of retention circuits 831 included in the backup circuit 830 is four (G=4).

In the following description of the operation, the flip-flop circuit 852 stores data supplied to the input terminal Df and outputs the data from the output terminal Qf in synchronization with the timing at which the clock signal supplied to the wiring PCK switches from the potential L to the potential H (the rising edge). The potential L is supplied to the wiring GBK. A constant potential (e.g., the potential VSS) is supplied to the wiring CM.

The timing chart in FIG. 25 illustrates the states of signals (the potential H and the potential L) supplied to the wiring PCK, the wiring BK[1], the wiring BK[2], the wiring RV[1], the wiring RV[2], and the wiring SE in operation periods (Period T821 to Period T827). Note that illustrations for the wiring BK[3], the wiring BK[4], the wiring RV[3], and the wiring RV[4] are omitted. In addition, the timing chart in FIG. 25 illustrates the state of data (any one of data D1 to data D7) supplied to each of the wiring D, the wiring Q, the wiring SD, the wiring SN[1], and the wiring SN[2]. Note that illustrations for the wiring SN[3] and the wiring SN[4] are omitted.

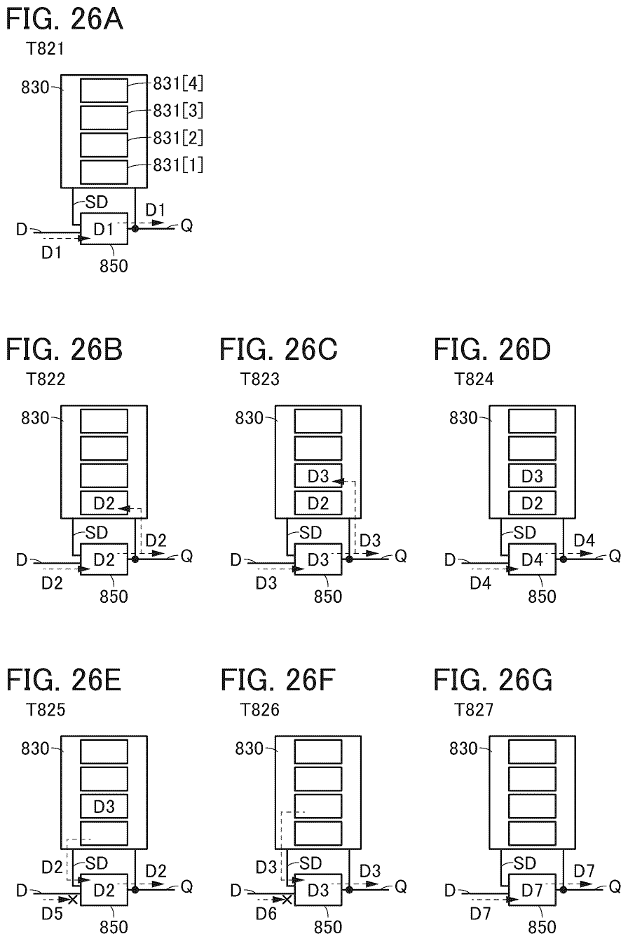

FIG. 26A to FIG. 26G are schematic diagrams illustrating the manner in which data is stored in the scan flip-flop circuit 850 and the retention circuit 831[1] to the retention circuit 831[4] included in the backup circuit 830 in the periods of the timing chart illustrated in FIG. 25. In the schematic diagrams, the manner in which data is input and output (data flow) is indicated by dashed arrows.

Immediately before Period T821, the potential L is supplied to each of the wiring BK[1] to the wiring BK[4], the wiring RV[1] to the wiring RV[4], and the wiring SE. The states of the data supplied to the wiring SN[1] and the wiring SN[2] are indeterminate (none of the data D1 to the data D7 is illustrated). Note that in the following description, the immediately preceding state is maintained unless otherwise specified.

In Period T821, the data D1 supplied to the wiring D is stored in the scan flip-flop circuit 850 and output to the wiring Q in synchronization with the rising edge of a signal supplied to the wiring PCK.

In Period T822, the data D2 supplied to the wiring D is stored in the scan flip-flop circuit 850 and output to the wiring Q in synchronization with the rising edge of the signal supplied to the wiring PCK.

At that time, the potential H is supplied to the wiring BK[1], whereby the data D2 output to the wiring Q is stored in the wiring SN[1] of the retention circuit 831[1]. After that, the potential L is supplied to the wiring BK[1], whereby the data D2 stored in the wiring SN[1] is retained.

In Period T823, the data D3 supplied to the wiring D is stored in the scan flip-flop circuit 850 and output to the wiring Q in synchronization with the rising edge of the signal supplied to the wiring PCK.

At that time, the potential H is supplied to the wiring BK[2], whereby the data D3 output to the wiring Q is stored in the wiring SN[2] of the retention circuit 831[2]. After that, the potential L is supplied to the wiring BK[2], whereby the data D3 stored in the wiring SN[2] is retained.

In Period T824, the data D4 supplied to the wiring D is stored in the scan flip-flop circuit 850 and output to the wiring Q in synchronization with the rising edge of the signal supplied to the wiring PCK.

In Period T825, first, the potential H is supplied to the wiring RV[1], whereby the data D2 stored in the wiring SN[1] of the retention circuit 831[1] is supplied to the wiring SD. Although the data D5 is supplied to the wiring D, the wiring SD is selected because the potential H is supplied to the wiring SE.

Next, the data D2 supplied to the wiring SD is stored in the scan flip-flop circuit 850 and output to the wiring Q in synchronization with the rising edge of the wiring PCK. After that, the potential L is supplied to the wiring RV[1].

In Period T826, first, the potential H is supplied to the wiring RV[2], whereby the data D3 stored in the wiring SN[2] of the retention circuit 831[2] is supplied to the wiring SD. Although the data D6 is supplied to the wiring D, the wiring SD is selected because the potential H is supplied to the wiring SE.

Next, the data D3 supplied to the wiring SD is stored in the scan flip-flop circuit 850 and output to the wiring Q in synchronization with the rising edge of the wiring PCK. After that, the potential L is supplied to the wiring RV[2], and the potential L is supplied to the wiring SE.

In Period T827, the data D7 supplied to the wiring D is stored in the scan flip-flop circuit 850 and output to the wiring Q in synchronization with the rising edge of the signal supplied to the wiring PCK.

In the above manner, the semiconductor device 810 can be operated as illustrated in the timing chart in FIG. 25. Accordingly, in the case where processing is performed with switching between a plurality of tasks in the electronic computer 900, a structure can be achieved in which data of a suspended task is saved and data of a resuming task is loaded, for example.

This embodiment can be combined with the other embodiments as appropriate. In this specification, in the case where a plurality of structure examples are shown in one embodiment, the structure examples can be combined as appropriate.

### Embodiment 2

In this embodiment, an example of an arithmetic processing device that can include the memory device 720 of one embodiment of the present invention will be described.

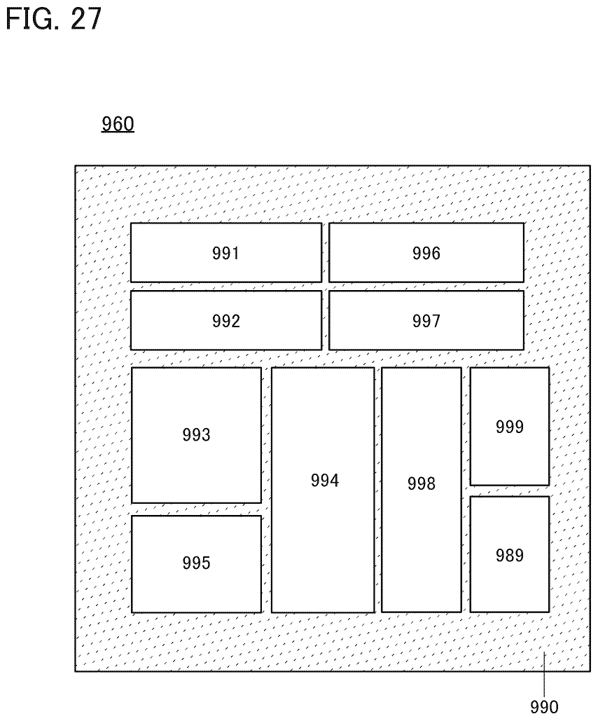

FIG. 27 illustrates a block diagram of an arithmetic device 960. The arithmetic device 960 illustrated in FIG. 27 can be used for a CPU, for example. The arithmetic device 960 can also be used for a processor including a larger number of (several tens to several hundreds of) processor cores capable of parallel processing than a CPU, such as a GPU, a TPU (Tensor Processing Unit), or an NPU (Neural Processing Unit).

The arithmetic device 960 illustrated in FIG. 27 includes, over a substrate 990, an ALU 991 (Arithmetic Logic Unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 721 can be stacked over the arithmetic device 960. The memory array 721 can be used as a cache. Here, the cache interface 989 may have a function of supplying data retained in the memory array 721 to the cache 999. Moreover, in this case, the driver circuit 722 is preferably included in part of the cache interface 989.

Note that it is also possible that the cache 999 is not provided and only the memory array 721 is used as a cache.

The arithmetic device 960 illustrated in FIG. 27 is only an example with a simplified structure, and the actual arithmetic device 960 has a variety of structures depending on the application. For example, what is called a multicore structure is preferably employed in which a plurality of cores each including the arithmetic device 960 in FIG. 27 operate in parallel. A larger number of cores can further enhance the arithmetic performance. The number of cores is preferably larger; for example, the number is preferably 2, further preferably 4, still further preferably 8, yet further preferably 12, still yet further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, which is then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 processes an interrupt request from an external input/output device, a peripheral circuit, or the like after making a determination based on its priority, a mask state, or the like while the arithmetic device 960 is executing a program. The register controller 997 generates the address of the register 996, and reads or writes data from or to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 in FIG. 27, the register controller 997 selects operation of retaining data in the register 996 in accordance with an instruction from the ALU 991. That is, the register controller 997 selects whether data is retained by a flip-flop or by a capacitor element in a memory cell included in the register 996. When data retention by the flip-flop is selected, power supply voltage is supplied to the memory cell in the register 996. When data retention by the capacitor element is selected, the data is rewritten into the capacitor element, and supply of power supply voltage to the memory cell in the register 996 can be stopped.

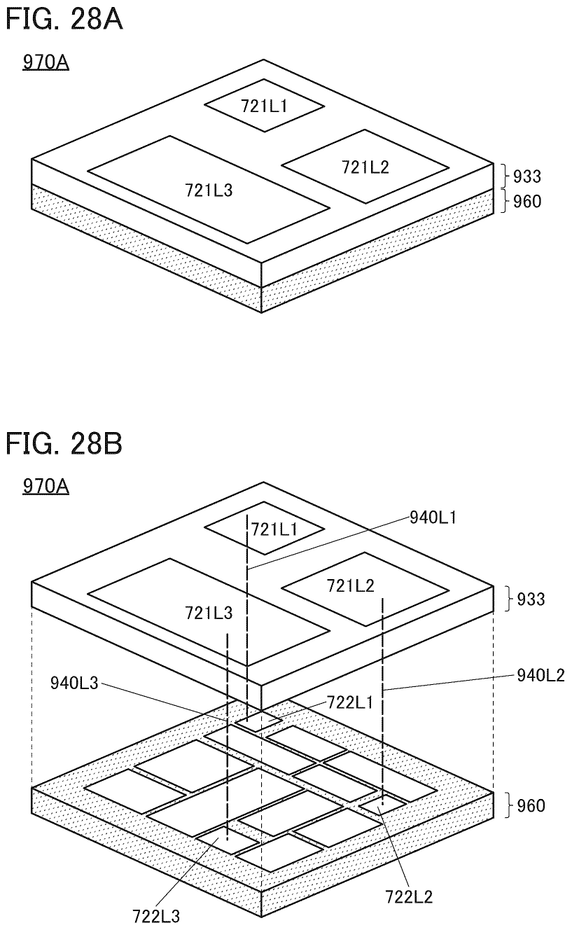

The memory array 721 and the arithmetic device 960 can be provided to overlap with each other. FIG. 28A and FIG. 28B illustrate perspective views of a semiconductor device 970A. The semiconductor device 970A includes a layer 933 provided with memory arrays over the arithmetic device 960. A memory array 721L1, a memory array 721L2, and a memory array 721L3 are provided in the layer 933. The arithmetic device 960 has an overlapping region with each of the memory arrays. For easy understanding of the structure of the semiconductor device 970A, the arithmetic device 960 and the layer 933 are separately illustrated in FIG. 28B.

Providing the arithmetic device 960 and the layer 933 including the memory arrays to overlap with each other can shorten the connection distance therebetween. Thus, the communication speed therebetween can be increased. Moreover, a short connection distance leads to lower power consumption.

As a method for stacking the layer 933 including the memory arrays and the arithmetic device 960, either of the following methods may be employed: a method in which the layer 933 including the memory arrays is stacked directly on the arithmetic device 960 (also referred to as monolithic stacking), and a method in which the arithmetic device 960 and the layer 933 are formed over two different substrates, the substrates are bonded to each other, and the arithmetic device 960 and the layer 933 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory array 721L1, the memory array 721L2, and the memory array 721L3 provided in the layer 933 are each used as a cache. In this case, for example, the memory array 721L1, the memory array 721L2, and the memory array 721L3 can be used as an L1 cache (also referred to as a level 1 cache), an L2 cache (also referred to as a level 2 cache), and an L3 cache (also referred to as a level 3 cache), respectively. Among the three memory arrays, the memory array 721L3 has the highest capacity and the lowest access frequency. The memory array 721L1 has the lowest capacity and the highest access frequency.

Note that in the case where the cache 999 provided in the arithmetic device 960 is used as the L1 cache, the memory arrays provided in the layer 933 can each be used as the lower-level cache or the main memory. The main memory has a higher capacity and a lower access frequency than the cache.

As illustrated in FIG. 28B, a driver circuit 722L1, a driver circuit 722L2, and a driver circuit 722L3 are provided. The driver circuit 722L1 is connected to the memory array 721L1 through a connection electrode 940L1. Similarly, the driver circuit 722L2 is connected to the memory array 721L2 through a connection electrode 940L2, and the driver circuit 722L3 is connected to the memory array 721L3 through a connection electrode 940L3.

Note that although the case where three memory arrays function as caches is described here, the number of memory arrays may be one, two, or four or more.

In the case where the memory array 721L1 is used as a cache, the driver circuit 722L1 may function as part of the cache interface 989 or the driver circuit 722L1 may have a structure to be connected to the cache interface 989. Similarly, each of the driver circuit 722L2 and the driver circuit 722L3 may have a structure to function as part of the cache interface 989 or be connected thereto.

Whether the memory array 721 functions as the cache or the main memory is determined by the control circuit 772 included in each of the driver circuits 722. The control circuit 772 can make some of the plurality of memory cells 741 included in the memory device 720 function as a RAM in accordance with a signal supplied from the arithmetic device 960.

In the memory device 720, some of the plurality of memory cells 741 can function as the cache and the other memory cells 741 can function as the main memory. That is, the memory device 720 can have both the function of the cache and the function of the main memory. The memory device 720 of one embodiment of the present invention can function as a universal memory, for example.

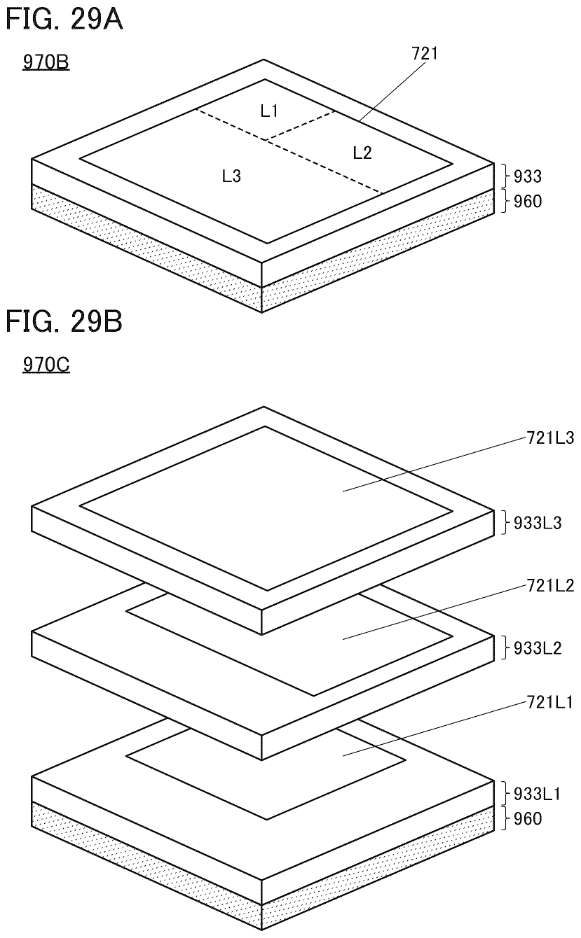

The layer 933 including one memory array 721 may be provided to overlap with the arithmetic device 960. FIG. 29A illustrates a perspective view of a semiconductor device 970B.

In the semiconductor device 970B, one memory array 721 can be divided into a plurality of areas having different functions. FIG. 29A illustrates an example in which a region L1, a region L2, and a region L3 are used as the L1 cache, the L2 cache, and the L3 cache, respectively.

In the semiconductor device 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 29B illustrates a perspective view of a semiconductor device 970C.

In the semiconductor device 970C, a layer 933L1 including the memory array 721L1, a layer 933L2 including the memory array 721L2 over the layer 933L1, and a layer 933L3 including the memory array 721L3 over the layer 933L2 are stacked. The memory array 721L1 physically closest to the arithmetic device 960 can be used as a high-level cache, and the memory array 721L3 physically farthest from the arithmetic device 960 can be used as a low-level cache or a main memory. Such a structure can increase the capacity of each memory array, leading to higher processing capability.

This embodiment can be combined with the other embodiments as appropriate.

### Embodiment 3

In this embodiment, application examples of the memory device of one embodiment of the present invention will be described.

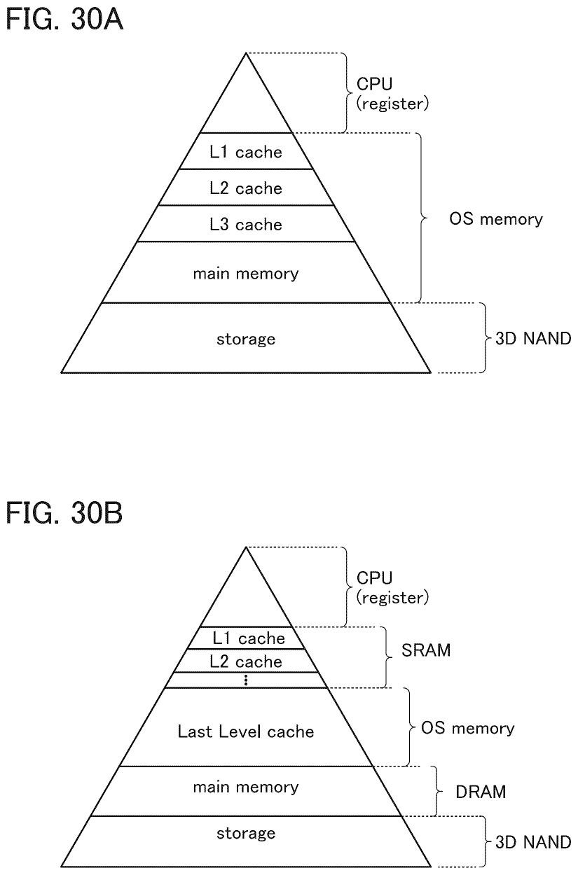

In general, a variety of memory devices are used in semiconductor devices such as computers depending on the application. FIG. 30A illustrates the hierarchy of various memory devices used in a semiconductor device. The memory devices at the upper levels require a higher operation speed, whereas the memory devices at the lower levels require a larger memory capacity and a higher memory density. FIG. 30A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

The memory included as the register in the arithmetic processing device such as a CPU is used for temporary storage of arithmetic operation results, for example, and thus is very frequently accessed by the arithmetic processing device. Thus, high operation speed is required rather than memory capacity. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operation speed than the main memory. Data that is rewritten in the cache is duplicated, and the duplicated data is supplied to the main memory.

The main memory has a function of retaining a program and data that are read from the storage, for example.

The storage has a function of retaining data that needs to be stored for a long time and a variety of programs used in the arithmetic processing device, for example. Thus, the storage needs to have a large memory capacity and a high memory density rather than operation speed. For example, a high-capacity nonvolatile memory device such as a 3D NAND can be used.

The memory device including an oxide semiconductor (the OS memory) of one embodiment of the present invention operates at high speed and can retain data for a long time. Thus, as illustrated in FIG. 30A, the memory device of one embodiment of the present invention can be suitably used at both the level where the cache is positioned and the level where the main memory is positioned. The memory device of one embodiment of the present invention can also be used at the level where the storage is positioned.

FIG. 30B illustrates an example in which an SRAM is used as at least one of the caches and the OS memory of one embodiment of the present invention is used as the other caches.

The lowest-level cache can be referred to as an LLC (Last Level Cache). The LLC does not require a higher operation speed than a higher-level cache, but desirably has large memory capacity. The OS memory of one embodiment of the present invention operates at high speed and can retain data for a long time, and thus can be suitably used as the LLC. Note that the OS memory of one embodiment of the present invention can also be used as an FLC (Final Level Cache).

For example, as illustrated in FIG. 30B, a structure can be employed in which an SRAM is used as the higher-level caches (the L1 cache, the L2 cache, and the like) and the OS memory of one embodiment of the present invention is used as the LLC. Moreover, instead of the OS memory, a DRAM can be used as the main memory as illustrated in FIG. 30B.

This embodiment can be combined with the other embodiments as appropriate.

### Embodiment 4

In this embodiment, an example of a method for manufacturing the memory device of one embodiment of the present invention will be described with reference to drawings.

### Example of Method for Manufacturing Memory Device

As a method for manufacturing the memory device of one embodiment of the present invention, an example of a method for manufacturing the memory device illustrated in FIG. 5A to FIG. 6B will be described below.

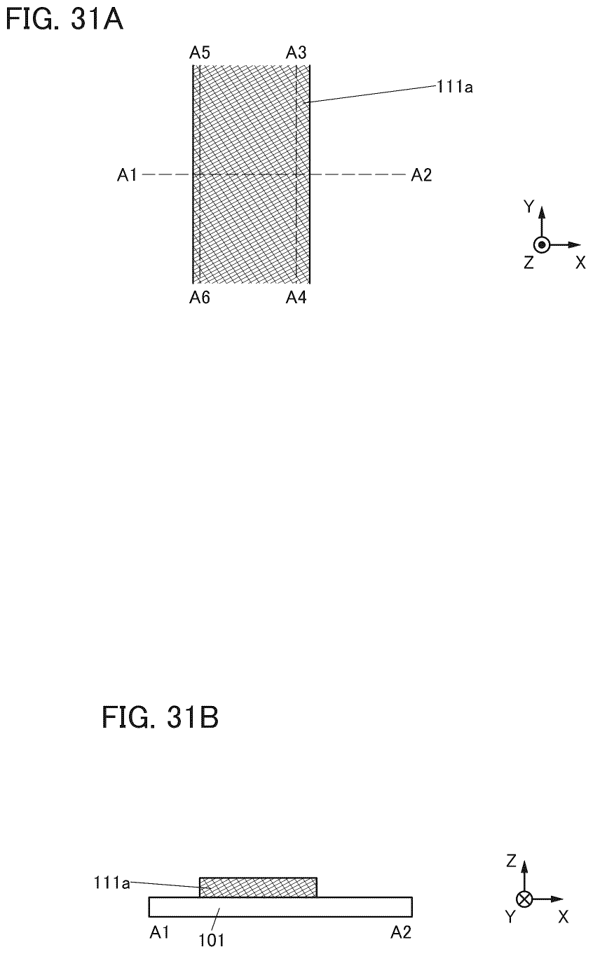

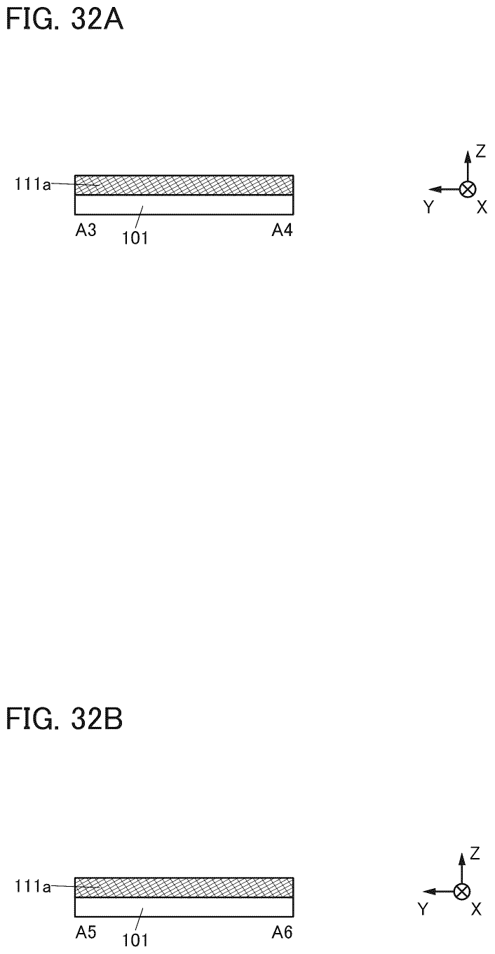

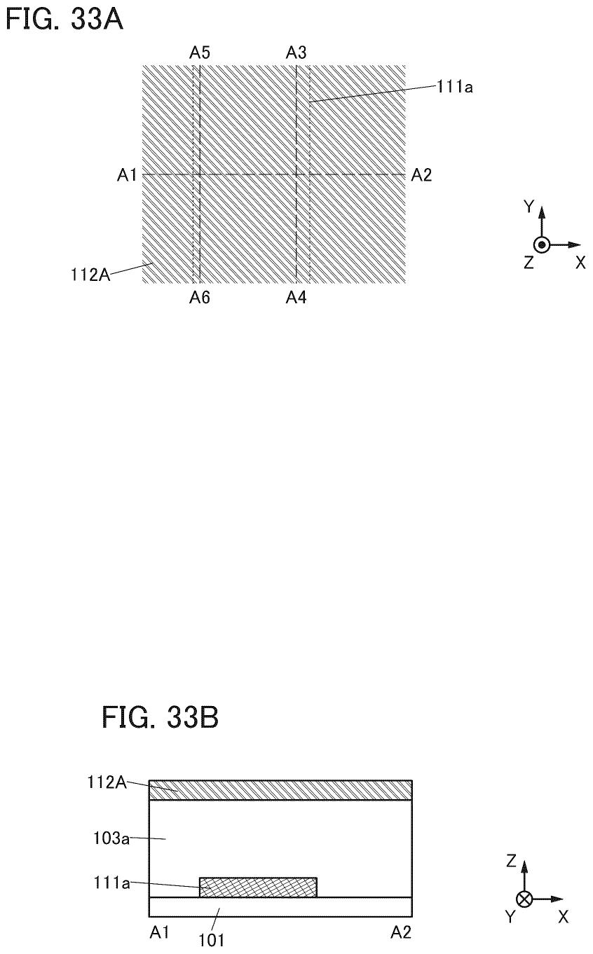

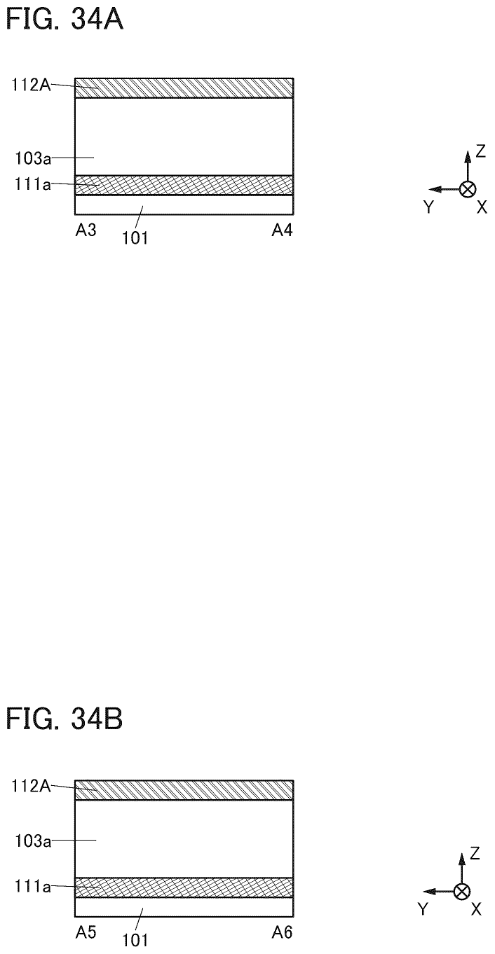

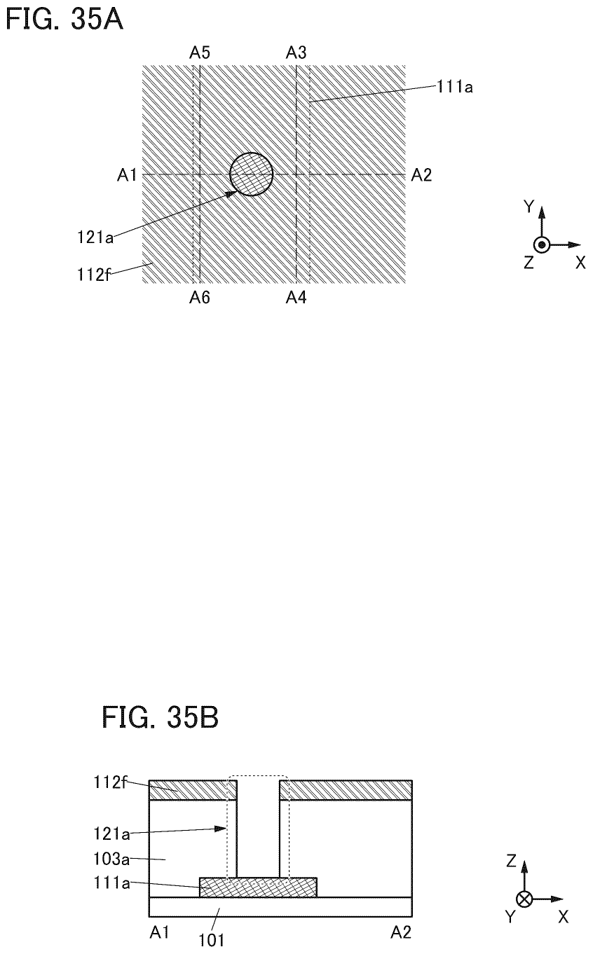

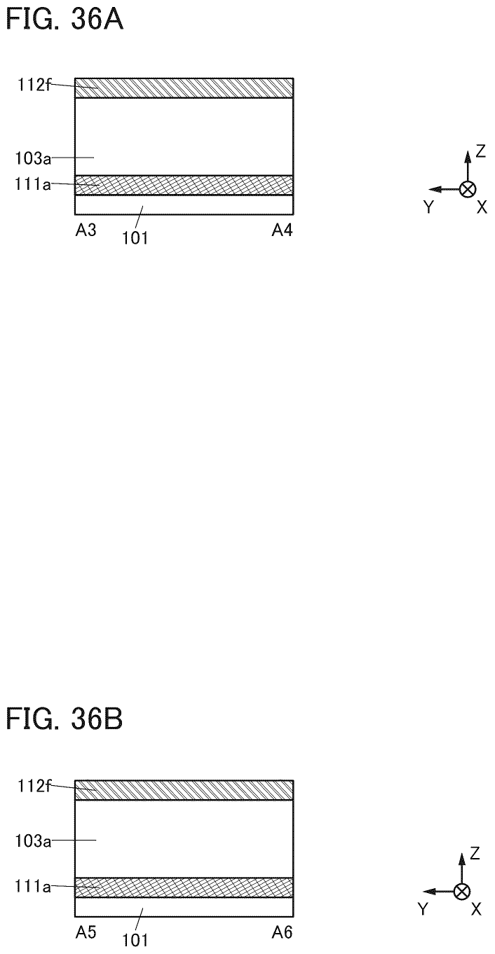

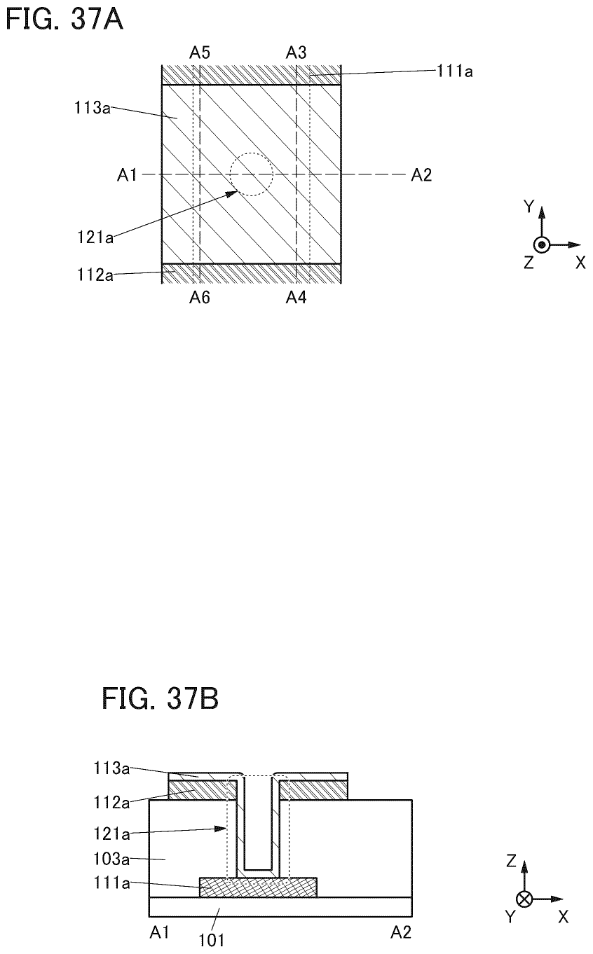

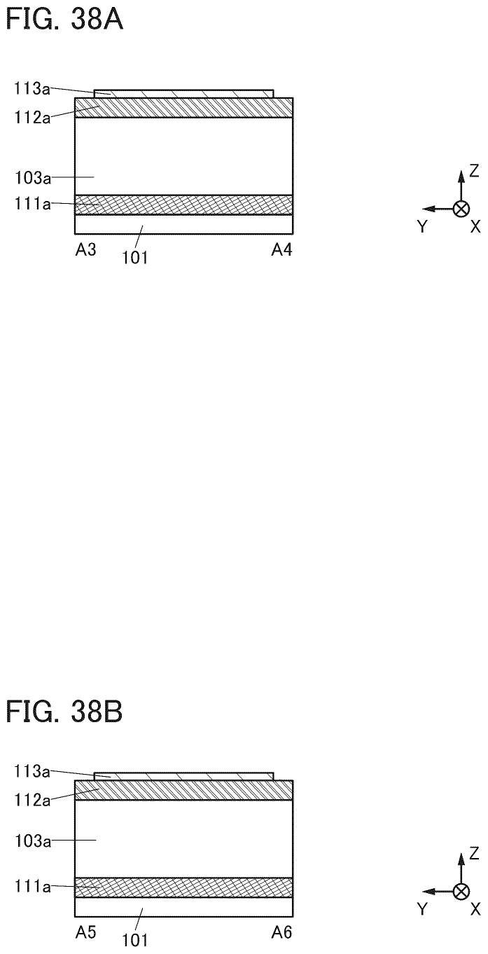

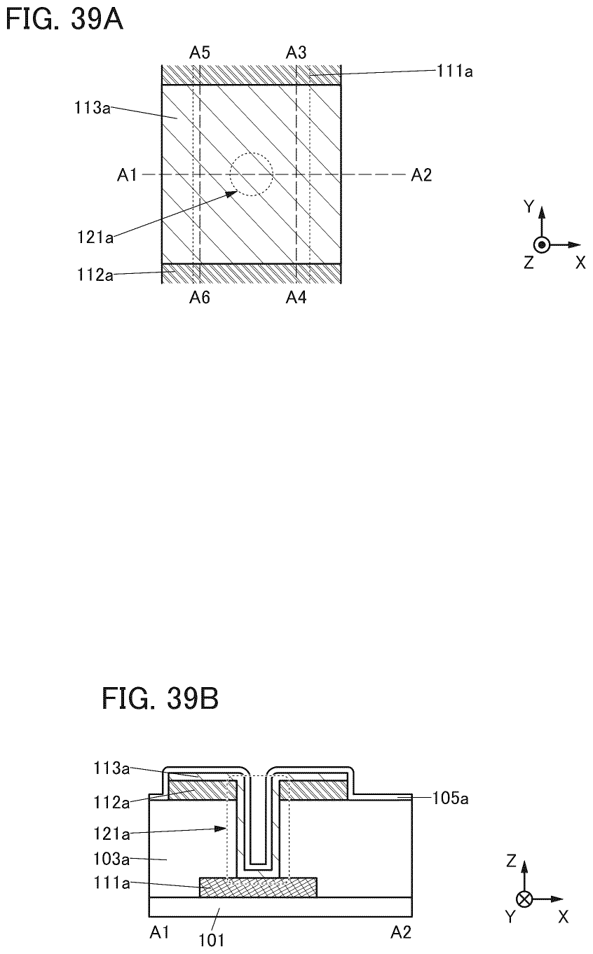

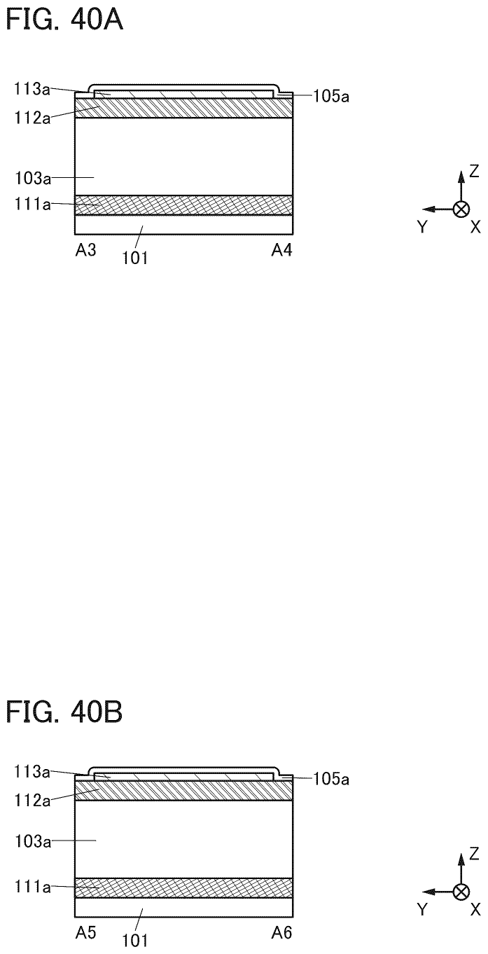

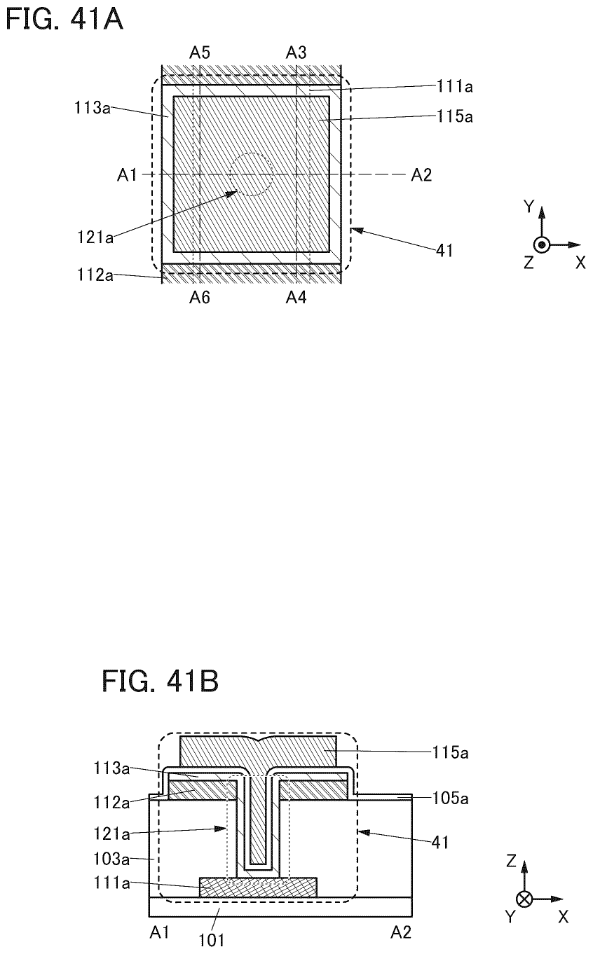

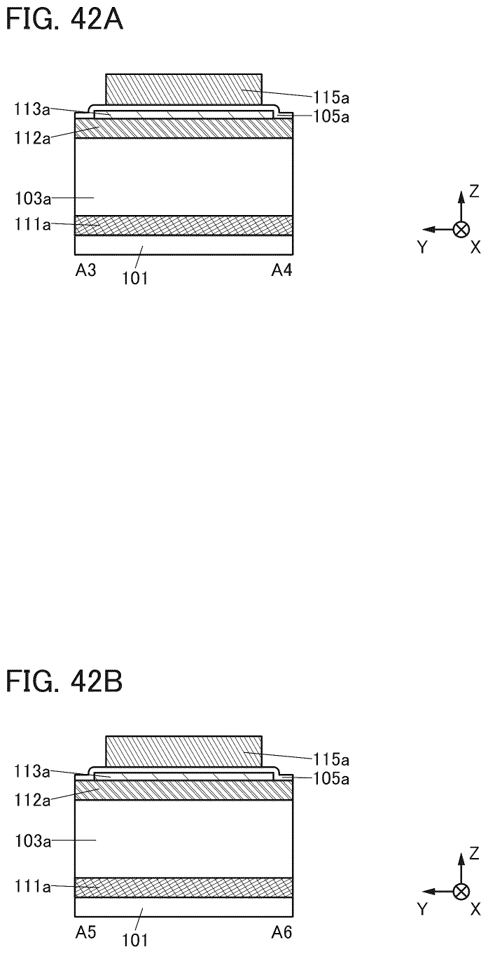

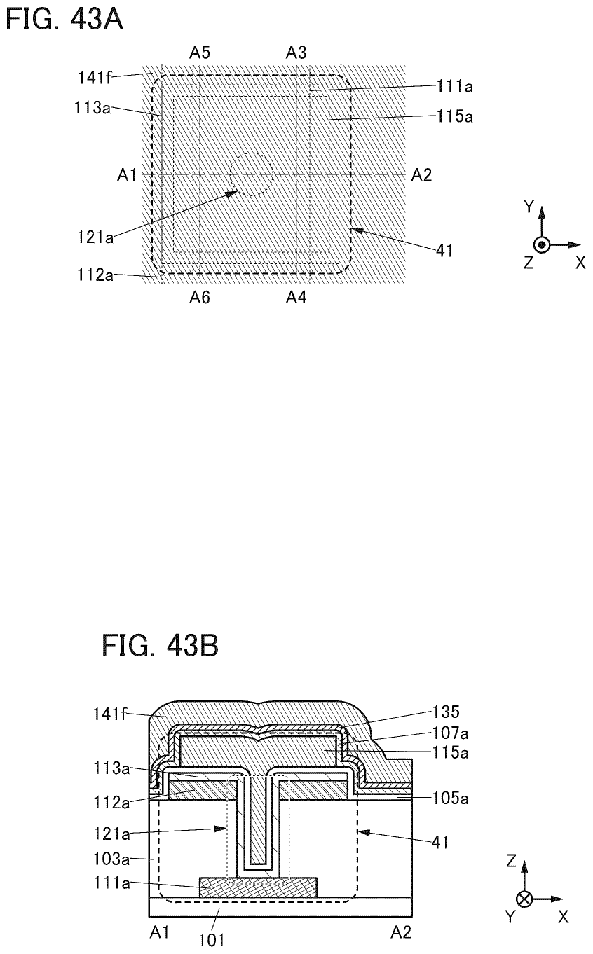

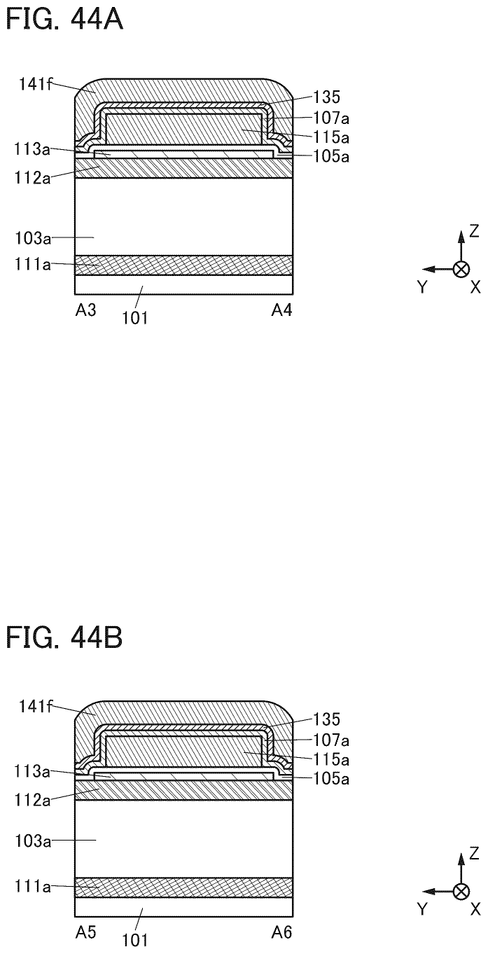

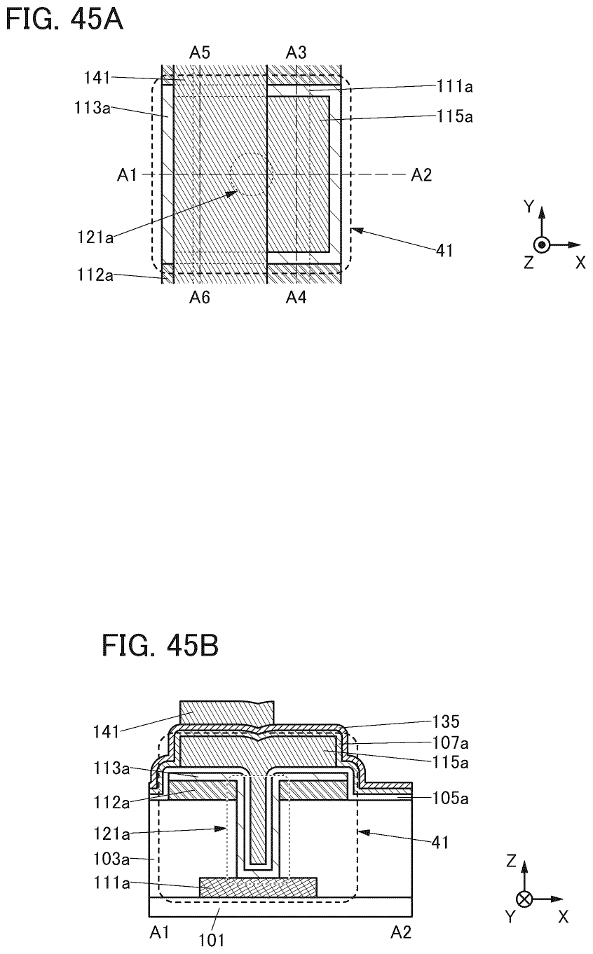

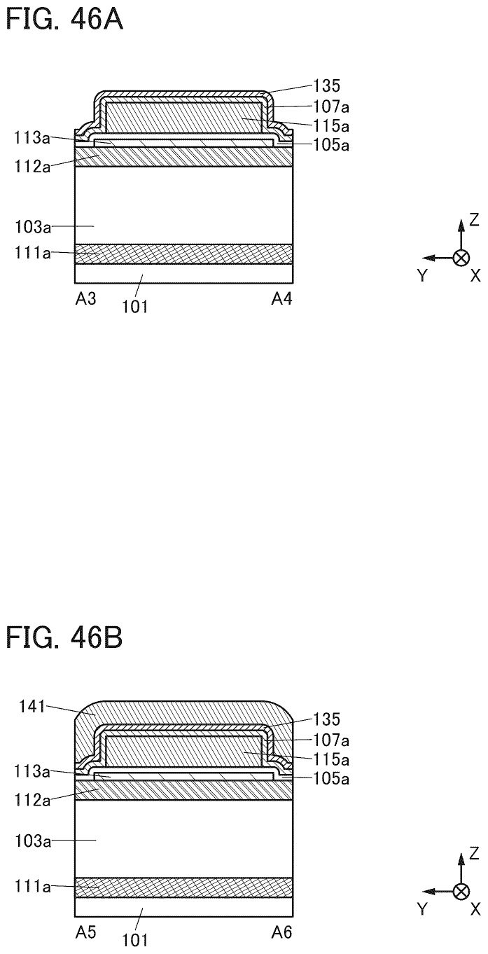

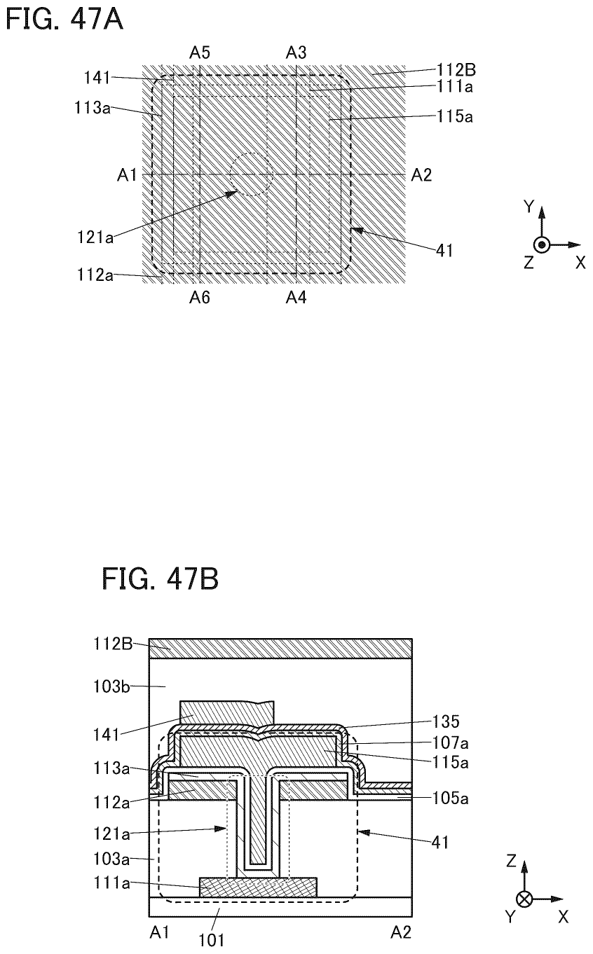

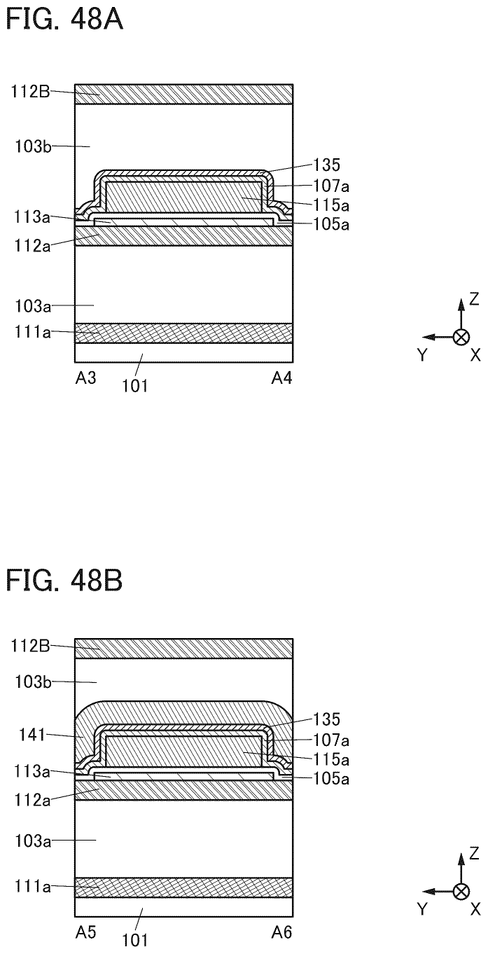

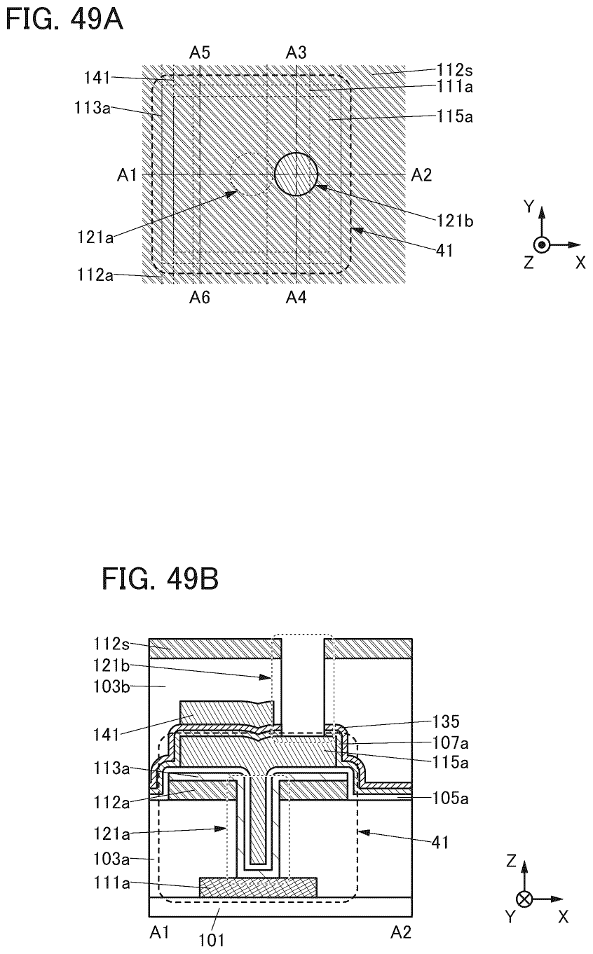

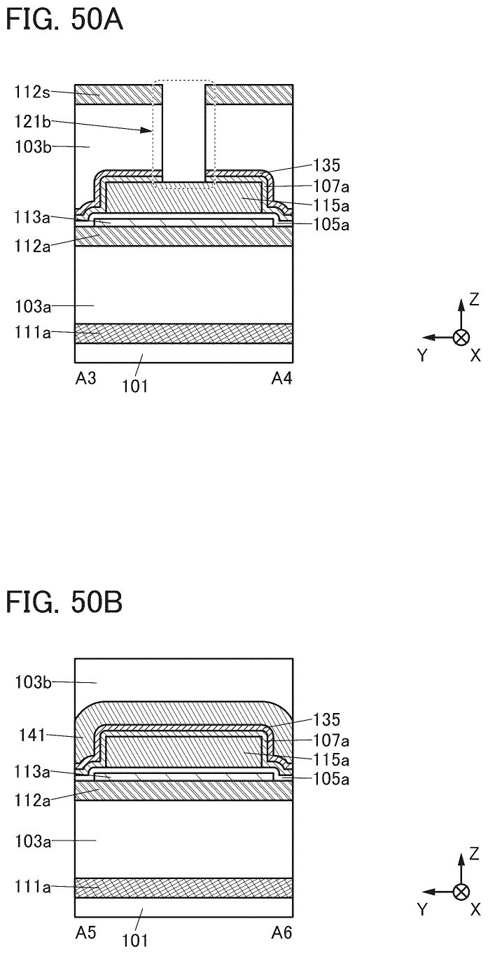

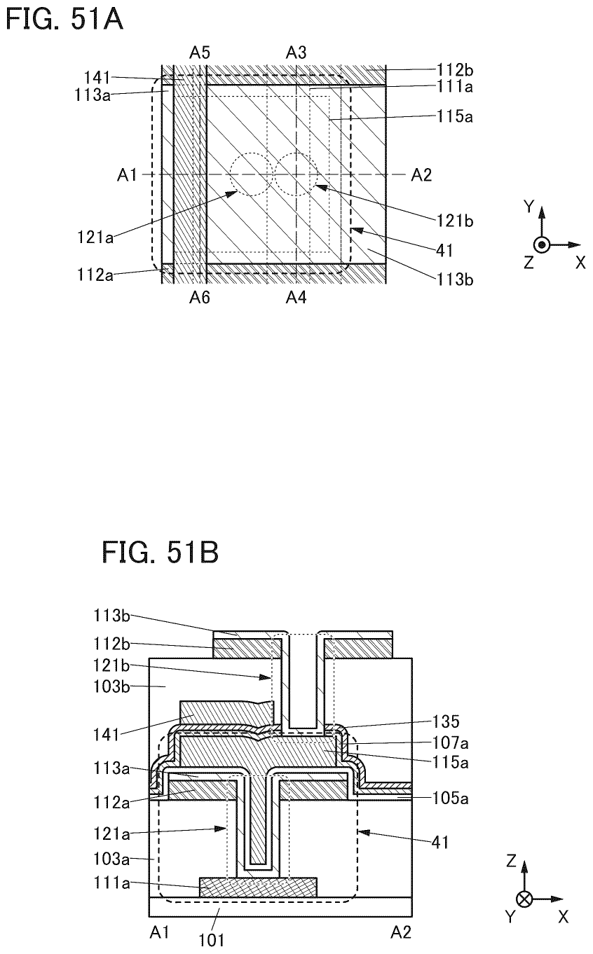

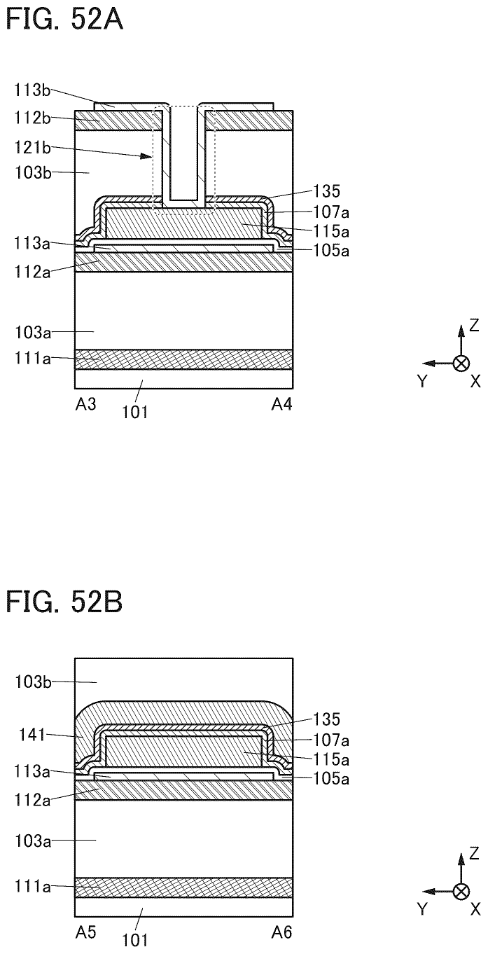

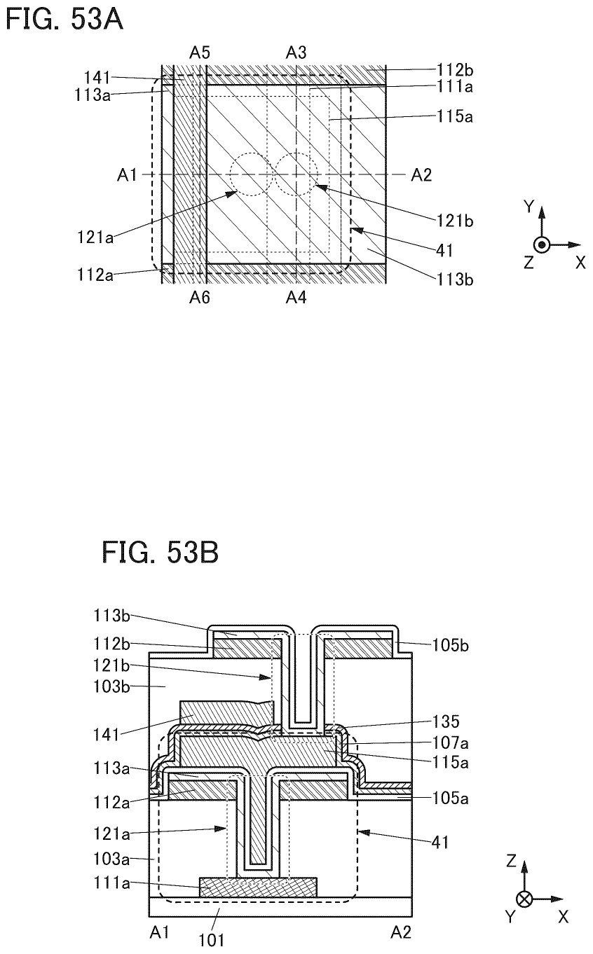

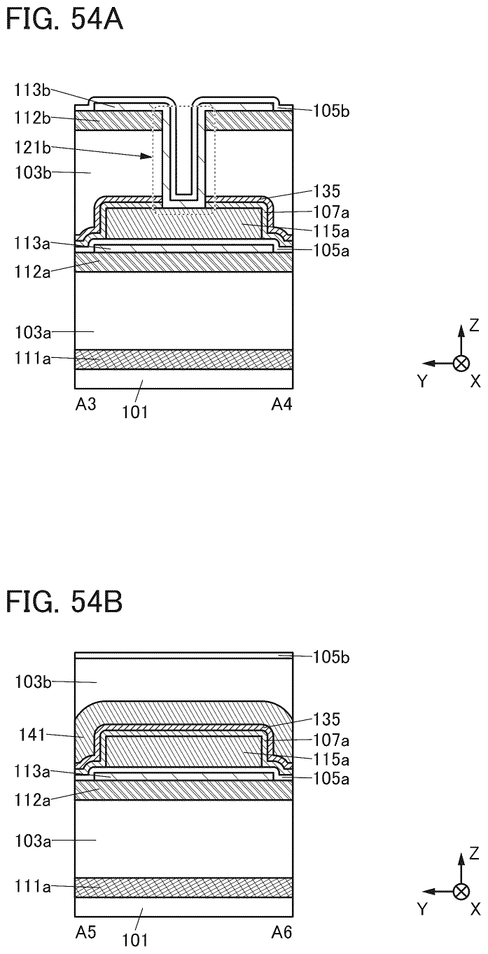

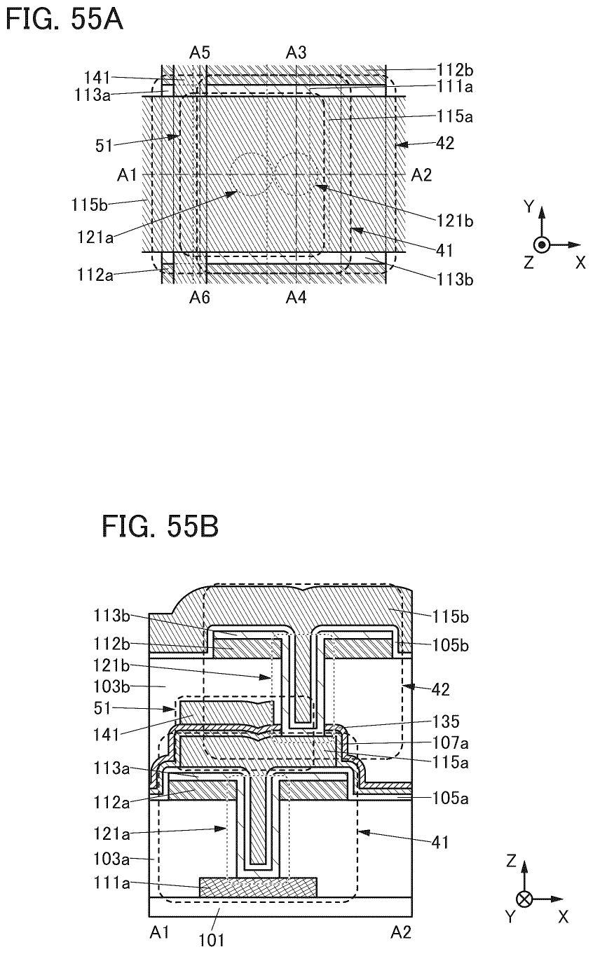

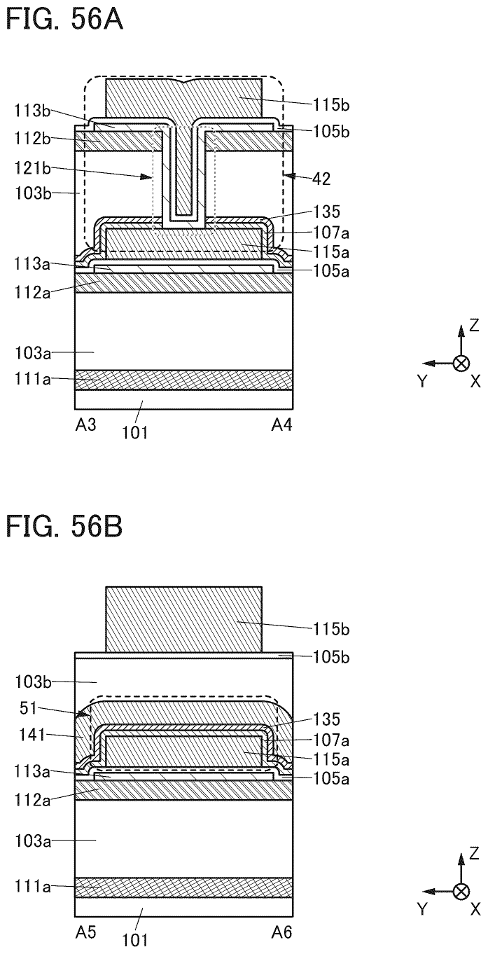

In FIG. 31, FIG. 33, FIG. 35, FIG. 37, FIG. 39, FIG. 41, FIG. 43, FIG. 45, FIG. 47, FIG. 49, FIG. 51, FIG. 53, and FIG. 55, A of each drawing illustrates a plan view. Moreover, B of each drawing is a cross-sectional view corresponding to a portion indicated by the dashed-dotted line A1-A2 in A of each drawing. In FIG. 32, FIG. 34, FIG. 36, FIG. 38, FIG. 40, FIG. 42, FIG. 44, FIG. 46, FIG. 48, FIG. 50, FIG. 52, FIG. 54, and FIG. 56, A of each drawing is a cross-sectional view corresponding to a portion indicated by the dashed-dotted line A3-A4 in A of the previous drawing. Moreover, B of each drawing is a cross-sectional view corresponding to a portion indicated by the dashed-dotted line A5-A6 in A of the previous drawing. Note that in FIG. 31, FIG. 33, FIG. 35, FIG. 37, FIG. 39, FIG. 41, FIG. 43, FIG. 45, FIG. 47, FIG. 49, FIG. 51, FIG. 53, and FIG. 55, some components are not illustrated in the plan view in A of each drawing for clarity of the drawings.

Hereinafter, an insulating material for forming an insulator, a conductive material for forming a conductor, or a semiconductor material for forming a semiconductor can be deposited by a deposition method such as a sputtering method, a CVD method, an MBE method, a PLD method, or an ALD method as appropriate.

Examples of the sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a memory device may be charged up by receiving electric charge from plasma. In that case, accumulated electric charge may break the wiring, the electrode, the element, or the like included in the memory device. In contrast, such plasma damage is not caused in the case of the thermal CVD method, which does not use plasma, and thus the yield of the memory device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, or the like can be used.

The CVD method and the ALD method are different from the sputtering method in which particles ejected from a target or the like are deposited. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the memory device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulating layer 101 is formed over the substrate. Any of the above-described insulating materials can be used for the insulating layer 101 as appropriate. The insulating layer 101 can be formed by a deposition method such as a sputtering method, a CVD method, an MBE method, a PLD method, or an ALD method as appropriate.

Next, the conductive layer 111a is formed over the insulating layer 101 (FIG. 31A to FIG. 32B). For example, a conductive film to be the conductive layer 111a is formed and processed, whereby the conductive layer 111a can be formed. For the conductive film to be the conductive layer 111a, any of the above-described conductive materials that can be used for the conductive layer 111a can be used as appropriate.

The conductive film to be the conductive layer 111a can be formed by a deposition method such as a sputtering method, a CVD method, an MBE method, a PLD method, or an ALD method as appropriate. For example, as the conductive film to be the conductive layer 111a, a stacked-layer film in which tungsten and titanium nitride are deposited in this order by a CVD method can be formed. After the conductive film to be the conductive layer 111a is formed, a pattern is formed by a lithography method, for example, and the conductive film is processed by a dry etching method, a wet etching method, or the like using the pattern, whereby the conductive layer 111a can be formed. Here, for microfabrication, the conductive film is preferably processed by a dry etching method.

Note that in the lithography method, first, a resist is exposed to light through a mask. Next, a region exposed to light is removed or left using a developing solution, so that a resist mask is formed. Thus, a pattern is formed.

The resist mask is formed through, for example, exposure of the resist to KrF excimer laser light, ArF excimer laser light, EUV light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

Next, etching treatment is performed using the resist mask. Thus, the conductive layer, a semiconductor layer, the insulating layer, and the like can be processed into desired shapes.

In the case of performing dry etching treatment as the above etching treatment, an etching gas including a halogen can be used as an etching gas; specifically, an etching gas including one or more of fluorine, chlorine, and bromine can be used. As the etching gas, for example, a C₄F₆ gas, a C₅F₆ gas, a C₄F₈ gas, a CF₄ gas, a SF₆ gas, a NF₃ gas, a CHF₃ gas, a Cl₂ gas, a BCl₃ gas, a SiCl₄ gas, a CCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus can be used, for example.

Then, the insulating layer 103a functioning as an interlayer insulating layer is formed over the insulating layer 101 and the conductive layer 111a. Any of the above-described insulating materials can be used for the insulating layer 103a as appropriate. The insulating layer 103a can be formed by a deposition method such as a sputtering method, a CVD method, an MBE method, a PLD method, or an ALD method as appropriate. A silicon oxide film is deposited by a sputtering method as the insulating layer 103a, for example. Note that it is preferable that the top surface of the deposited insulating layer 103a be planarized by chemical mechanical polishing (CMP) treatment. The planarization treatment performed on the insulating layer 103a enables the conductive layer 112a functioning as the other of the source electrode and the drain electrode of the transistor 41 to be favorably formed in a later step. Furthermore, aluminum oxide may be deposited over the insulating layer 103a by a sputtering method, and then subjected to CMP treatment until the insulating layer 103a is reached. The CMP treatment can planarize and smooth the surface of the insulating layer 103a. When the CMP treatment is performed on the aluminum oxide placed over the insulating layer 103a, it is easy to detect the endpoint of the CMP treatment.

Note that the CMP treatment may be skipped in some cases. In that case, the top surface of the insulating layer 103a has a convex curved shape. By not performing planarization treatment, manufacturing cost can be reduced and production yield can be increased.

Note that a depressed portion may be provided in the insulating layer 101, and the conductive layer 111a may be formed to fill the depressed portion. The conductive layer 111a may be formed such that the top surface of the insulating layer 101 and the top surface of the conductive layer 111a are substantially level with each other, and then the insulating layer 103a may be formed over the insulating layer 101 and the conductive layer 111a.

When the insulating layer 103a is deposited by a sputtering method in an oxygen-containing atmosphere, the insulating layer 103a containing excess oxygen can be formed. By using a sputtering method that does not need to use a molecule containing hydrogen as a deposition gas, the hydrogen concentration in the insulating layer 103a can be reduced. When the insulating layer 103a is deposited in this manner, oxygen can be supplied from the insulating layer 103a to the channel formation region of the semiconductor layer 113a formed in a later step, so that oxygen vacancies and VoH can be reduced.

Then, a conductive film 112A to be the conductive layer 112a later is formed over the insulating layer 103a (FIG. 33A to FIG. 34B). For the conductive film 112A, any of the above-described conductive materials that can be used for the conductive layer 112 can be used as appropriate. The conductive film 112A can be formed by a deposition method such as a sputtering method, a CVD method, an MBE method, a PLD method, or an ALD method as appropriate.

Next, part of the conductive film 112A and part of the insulating layer 103a are each processed to form the opening 121a that reaches the conductive layer 111a (FIG. 35A to FIG. 36B). The opening 121a can be formed by a lithography method and an etching method, for example. By this processing, a conductive layer 112f including an opening is formed from the conductive film 112A.

Here, the sidewall of the opening 121a is preferably perpendicular to the top surface of the conductive layer 111a. With the structure, the memory device can be miniaturized or highly integrated. Alternatively, the sidewall of the opening 121a may be tapered. The tapered shape of the sidewall of the opening 121a can improve the coverage with, for example, a metal oxide film to be the semiconductor layer 113a described later, so that defects such as voids can be reduced.

The maximum width of the opening 121a (the diameter in the case where the opening 121a is circular in a plan view) is preferably small. For example, the maximum width of the opening 121a is preferably greater than or equal to 1 nm and less than or equal to 60 nm, greater than or equal to 5 nm and less than or equal to 50 nm, greater than or equal to 5 nm and less than or equal to 40 nm, greater than or equal to 5 nm and less than or equal to 30 nm, or greater than or equal to 5 nm and less than or equal to 20 nm. As the maximum width of the opening 121a becomes smaller, the area occupied by the transistor in a plan view can become smaller. Thus, the area occupied by the memory device in a plan view can be reduced, and miniaturization and high integration of the memory device can be achieved.

Meanwhile, in the case where the maximum width of the opening 121a is large, the channel width of the transistor is increased and thus the on-state current thereof can be increased, which is preferable.

Since the opening 121a has a high aspect ratio, the part of the conductive film 112A and the part of the insulating layer 103a are each preferably processed by anisotropic etching. Processing by a dry etching method is particularly preferable because it is suitable for microfabrication. The processing may be performed under different conditions. Note that the inclination of the side surface of the conductive layer 112f in the opening 121a may be different from the inclination of the side surface of the insulating layer 103a in the opening 121a, depending on the conditions for processing the part of the conductive film 112A and the part of the insulating layer 103a.

Next, heat treatment may be performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C.. Note that the heat treatment is performed in an atmosphere of a nitrogen gas or an inert gas, for example. The heat treatment may be performed under reduced pressure. By the above-described heat treatment, impurities such as water contained in the insulating layer 103a or the like can be reduced before the metal oxide film to be the semiconductor layer 113a described later is deposited.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent, for example, entry of moisture into the insulating layer 103a as much as possible.

Then, the conductive layer 112f is processed, whereby the conductive layer 112a is formed to include a region overlapping with the conductive layer 111a in a plan view. For example, a pattern is formed by a lithography method, and the conductive layer 112f is processed by a dry etching method, a wet etching method, or the like using the pattern, whereby the conductive layer 112a can be formed. Here, for microfabrication, the conductive layer 112f is preferably processed by a dry etching method.

Next, the metal oxide film to be the semiconductor layer 113a later is formed in contact with the top surface of the conductive layer 112a, the side surface of the conductive layer 112a in the opening 121a, the side surface of the insulating layer 103a in the opening 121a, and the top surface of the conductive layer 111a in the opening 121a. For the metal oxide film to be the semiconductor layer 113a, any of the above-described metal oxides that can be used for the semiconductor layer 113 can be used as appropriate. The metal oxide film to be the semiconductor layer 113a can be formed by a deposition method such as a sputtering method, a CVD method, an MBE method, a PLD method, or an ALD method as appropriate. Here, the metal oxide film to be the semiconductor layer 113a is preferably formed in contact with the side surface of the conductive layer 112a, the side surface of the insulating layer 103a, and the top surface of the conductive layer 111a in the opening 121a with a high aspect ratio. Thus, the metal oxide film to be the semiconductor layer 113a is preferably formed by a deposition method with favorable coverage, and is further preferably formed by a CVD method, an ALD method, or the like. For example, an In—Ga—Zn oxide is deposited by an ALD method as the metal oxide film to be the semiconductor layer 113a.

In the case where the sidewall of the opening 121a is tapered, the method for depositing the metal oxide film to be the semiconductor layer 113a is not limited to a CVD method or an ALD method. For example, a sputtering method may be employed.

In the case where the semiconductor layer 113a has a stacked-layer structure, the layers included in the semiconductor layer 113a may be deposited by the same method or different methods from each other. For example, in the case where the semiconductor layer 113a has a stacked-layer structure of two layers, the lower layer of the metal oxide film to be the semiconductor layer 113a may be deposited by a sputtering method and the upper layer thereof may be deposited by an ALD method. A metal oxide film deposited by a sputtering method is likely to have crystallinity. Thus, when a metal oxide film having crystallinity is provided as the lower layer of the metal oxide film to be the semiconductor layer 113a, the crystallinity of the upper layer thereof can be increased. Even when a pin hole, disconnection, or the like is formed in the lower layer of the metal oxide film deposited by a sputtering method, a portion overlapping therewith can be filled with the upper layer of the metal oxide film deposited by an ALD method with favorable coverage.

Here, the metal oxide film to be the semiconductor layer 113a is preferably formed in contact with the top surface of the conductive layer 111a in the opening 121a, the side surface of the insulating layer 103a in the opening 121a, the side surface of the conductive layer 112a in the opening 121a, and the top surface of the conductive layer 112a. When the metal oxide film is formed in contact with the conductive layer 111a, the conductive layer 111a functions as one of the source electrode and the drain electrode of the transistor 41.

Next, heat treatment is preferably performed. The heat treatment is performed in a temperature range where the metal oxide film to be the semiconductor layer 113a does not become polycrystals, i.e., at higher than or equal to 250° C. and lower than or equal to 650° C., preferably higher than or equal to 400° C. and lower than or equal to 600° C.. For the details of the heat treatment, the above description can be referred to.

Here, the above-described heat treatment is preferably performed in the state where the metal oxide film to be the semiconductor layer 113a is in contact with the insulating layer 103a containing excess oxygen. By performing the heat treatment in such a manner, oxygen is supplied from the insulating layer 103a to the metal oxide film to be the semiconductor layer 113a, so that oxygen vacancies and VₒH in the semiconductor layer 113a to be formed later can be reduced.

Although the heat treatment is performed after the metal oxide film to be the semiconductor layer 113a is deposited in the above description, the present invention is not limited thereto. The heat treatment may be performed in a later step.

Next, the metal oxide film to be the semiconductor layer 113a is processed, whereby the semiconductor layer 113a is formed to include a region overlapping with the opening 121a in a plan view (FIG. 37A to FIG. 38B). For example, a pattern for the metal oxide film to be the semiconductor layer 113a is formed by a lithography method, and then, the metal oxide film is processed by an etching method using the pattern. Thus, the semiconductor layer 113a can be formed to include a region overlapping with the opening 121a. Thus, part of the semiconductor layer 113a is formed in the opening 121a. The semiconductor layer 113a is in contact with the top surface of the conductive layer 112a. Accordingly, the semiconductor layer 113a including a region in contact with the top surface of the conductive layer 111a in the opening 121a, a region in contact with the side surface of the insulating layer 103a in the opening 121a, a region in contact with the side surface of the conductive layer 112a in the opening 121a, and a region in contact with the top surface of the conductive layer 112a is formed.

Although FIG. 37A and FIG. 37B illustrate an example in which the end portion of the semiconductor layer 113a is formed to be substantially aligned with the end portion of the conductive layer 112a in the X direction, one embodiment of the present invention is not limited thereto. The end portion of the semiconductor layer 113a may be positioned inward from the end portion of the conductive layer 112a in the X direction. The end portion of the semiconductor layer 113a may be positioned outward from the end portion of the conductive layer 112a in the X direction, and the bottom surface of the semiconductor layer 113a may be in contact with the side surface of the conductive layer 112a on the side not facing the opening 121a and in contact with the top surface of the insulating layer 103a.

Although an example in which the semiconductor layer 113a is formed after the conductive layer 112a is formed is described above, one embodiment of the present invention is not limited thereto. For example, in one embodiment of the present invention, after the formation of the opening 121a (FIG. 35A to FIG. 36B), the metal oxide film to be the semiconductor layer 113a may be formed, the metal oxide film may be processed to form the semiconductor layer 113a, and then the conductive layer 112f may be processed to form the conductive layer 112a.

Next, the insulating layer 105a is formed in contact with the top surface of the semiconductor layer 113a (FIG. 39A to FIG. 40B). Any of the above-described insulating materials can be used for the insulating layer 105a as appropriate. The insulating layer 105a can be formed by a deposition method such as a sputtering method, a CVD method, an MBE method, a PLD method, or an ALD method as appropriate. Here, the insulating layer 105a is preferably formed in contact with the top surface of the semiconductor layer 113a in the opening 121a with a high aspect ratio. Thus, the insulating layer 105a is preferably deposited by a deposition method with favorable coverage, and is further preferably deposited by a CVD method, an ALD method, or the like. For example, silicon oxide is deposited as the insulating layer 105a by an ALD method.

In the case where the sidewall of the opening 121a is tapered, the method for depositing the insulating layer 105a is not limited to a CVD method or an ALD method. For example, a sputtering method may be employed.

When the insulating layer 105a is formed after the semiconductor layer 113a is formed, the side end portion of the semiconductor layer 113a is covered with the insulating layer 105a. Thus, a short circuit between the semiconductor layer 113a and the conductive layer 115a formed in a later step can be prevented. Furthermore, in the above-described structure, the side end portion of the conductive layer 112a is covered with the insulating layer 105a. Thus, a short circuit between the conductive layer 112a and the conductive layer 115a can be prevented.

Subsequently, a conductive film to be the conductive layer 115a is formed over the insulating layer 105a to fill the opening 121a. For the conductive film to be the conductive layer 115a, any of the above-described conductive materials that can be used for the conductive layer 115 can be used as appropriate. The conductive film to be the conductive layer 115a can be formed by a deposition method such as a sputtering method, a CVD method, an MBE method, a PLD method, or an ALD method as appropriate. Here, the conductive film to be the conductive layer 115a is preferably formed in contact with the insulating layer 105a provided in the opening 121a with a high aspect ratio. Thus, the conductive film to be the conductive layer 115a is preferably formed by a deposition method with favorable coverage or filling property, and is further preferably formed by a CVD method, an ALD method, or the like.

In the case where the conductive film to be the conductive layer 115a is formed by a CVD method, the top surface of the conductive film sometimes has high average surface roughness. In that case, the conductive film is preferably planarized by a CMP method. At that time, before the CMP treatment, a silicon oxide film or a silicon oxynitride film may be deposited over the conductive film and the CMP treatment may be performed until the silicon oxide film or the silicon oxynitride film is removed. Note that the CMP treatment is not necessarily performed.

Although the conductive film to be the conductive layer 115a is provided to fill the opening 121a in the above description, the present invention is not limited thereto. For example, a depressed portion reflecting the shape of the opening 121a is formed in the upper portion of the conductive film to be the conductive layer 115a in some cases. A structure may be employed in which the depressed portion is filled with an inorganic insulating material, for example. Note that the depressed portion is not necessarily filled with an inorganic insulating material or the like.

Next, part of the conductive film to be the conductive layer 115a is processed to form the conductive layer 115a (FIG. 41A to FIG. 42B). The conductive layer 115a can be formed by, for example, forming a pattern by a lithography method and then processing the conductive film to be the conductive layer 115a by an etching method using the pattern. Although the processing can be performed, for example, by a dry etching method or a wet etching method, processing by a dry etching method is preferable because it is suitable for microfabrication. The conductive layer 115a is formed over the insulating layer 105a to include a region overlapping with the semiconductor layer 113a.

In the above manner, the transistor 41 including the conductive layer 111a, the conductive layer 112a, the semiconductor layer 113a, the insulating layer 105a, and the conductive layer 115a can be formed.

As described above, the conductive layer 111a functions as one of the source electrode and the drain electrode of the transistor 41. The conductive layer 112a functions as the other of the source electrode and the drain electrode of the transistor 41. The insulating layer 105a functions as a gate insulating layer of the transistor 41. The conductive layer 115a functions as a gate electrode of the transistor 41.

Then, the insulating layer 107a is formed to cover the conductive layer 115a and the insulating layer 105a. After that, the insulating layer 135 is formed over the insulating layer 107a. For the insulating layer 107a and the insulating layer 135, any of the above-described insulating materials that can be used for the insulating layer 107 and the insulating layer 135, respectively, can be used as appropriate. The insulating layer 107a and the insulating layer 135 can each be formed by a deposition method such as a sputtering method, a CVD method, an MBE method, a PLD method, or an ALD method as appropriate.

Then, a conductive film 141f to be the conductive layer 141 later is formed over the insulating layer 135 (FIG. 43A to FIG. 44B). For the conductive film 141f, any of the above-described conductive materials that can be used for the conductive layer 141 can be used as appropriate. The conductive film 141f can be formed by a deposition method such as a sputtering method, a CVD method, an MBE method, a PLD method, or an ALD method as appropriate.

Then, the conductive film 141f is processed, whereby the conductive layer 141 is formed to include a region overlapping with the conductive layer 115a in a plan view (FIG. 45A to FIG. 46B). The conductive layer 141 can be formed by, for example, forming a pattern by a lithography method and then processing the conductive film 141f by an etching method using the pattern. Although the processing can be performed, for example, by a dry etching method or a wet etching method, processing by a dry etching method is preferable because it is suitable for microfabrication. Note that the conductive layer 141 is formed apart from the opening 121b to be formed later in a plan view.

Then, the insulating layer 103b functioning as an interlayer insulating layer is formed over the insulating layer 141 and the insulating layer 135. The insulating layer 103b can be formed using the same material and the same method as those for the above-described insulating layer 103a. Note that it is preferable that the top surface of the deposited insulating layer 103b be planarized by CMP treatment. The planarization treatment performed on the insulating layer 103b enables the conductive layer 112b functioning as the other of the source electrode and the drain electrode of the transistor 42 to be favorably formed in a later step.

Note that the CMP treatment may be skipped in some cases. In that case, the top surface of the insulating layer 103b has a convex curved shape. By not performing planarization treatment, manufacturing cost can be reduced and production yield can be increased.

When the insulating layer 103b is deposited by a sputtering method in an oxygen-containing atmosphere, the insulating layer 103b containing excess oxygen can be formed. By using a sputtering method that does not need to use a molecule containing hydrogen as a deposition gas, the hydrogen concentration in the insulating layer 103b can be reduced. When the insulating layer 103b is deposited in this manner, oxygen can be supplied from the insulating layer 103b to the channel formation region of the semiconductor layer 113b formed in a later step, so that oxygen vacancies and VoH can be reduced.

Then, a conductive film 112B to be the conductive layer 112b later is formed over the insulating layer 103b (FIG. 47A to FIG. 48B). The conductive film 112B can be formed using the same material and the same method as those for the above-described conductive film 112A.

Next, part of the conductive film 112B, part of the insulating layer 103b, part of the insulating layer 135, and part of the insulating layer 107a are each processed to form the opening 121b that reaches the conductive layer 115a (FIG. 49A to FIG. 50B). The opening 121b is formed apart from the conductive layer 141 in a plan view. The opening 121b is preferably formed in a region overlapping with the substantially flat top surface of the conductive layer 115a. This can inhibit defective contact from being caused between the bottom surface of the semiconductor layer 113b to be formed later in the opening 121b and the top surface of the conductive layer 115a. The opening 121b can be formed by the same method as that for forming the above-described opening 121a. By this processing, a conductive layer 112s including an opening is formed from the conductive film 112B.

Here, the sidewall of the opening 121b is preferably perpendicular to the top surface of the conductive layer 115a. With the structure, the memory device can be miniaturized or highly integrated. Alternatively, the sidewall of the opening 121b may have a tapered shape. The tapered shape of the sidewall of the opening 121b can improve the coverage with, for example, a metal oxide film to be the semiconductor layer 113b described later, so that defects such as voids can be reduced.

The maximum width of the opening 121b (the diameter in the case where the opening 121b is circular in a plan view) is preferably small. For example, the maximum width of the opening 121b is preferably greater than or equal to 1 nm and less than or equal to 60 nm, greater than or equal to 5 nm and less than or equal to 50 nm, greater than or equal to 5 nm and less than or equal to 40 nm, greater than or equal to 5 nm and less than or equal to 30 nm, or greater than or equal to 5 nm and less than or equal to 20 nm.

Since the opening 121b has a high aspect ratio, the part of the conductive film 112B, the part of the insulating layer 103b, the part of the insulating layer 135, and the part of the insulating layer 107a are each preferably processed by anisotropic etching. Processing by a dry etching method is particularly preferable because it is suitable for microfabrication. The processing may be performed under different conditions. Note that the inclination of the side surface of the conductive layer 112s in the opening 121b, the inclination of the side surface of the insulating layer 103b in the opening 121b, the inclination of the side surface of the insulating layer 135 in the opening 121b, and the inclination of the side surface of the insulating layer 107a in the opening 121b may be different from each other, depending on the conditions for processing the part of the conductive film 112B, the part of the insulating layer 103b, the part of the insulating layer 135, and the part of the insulating layer 107a.

Next, heat treatment may be performed. For the details of the heat treatment, the above description of the heat treatment that can be performed after the formation of the opening 121a can be referred to. By the heat treatment, impurities such as water contained in the insulating layer 103b or the like can be reduced before the metal oxide film to be the semiconductor layer 113b described later is deposited.

Then, the conductive layer 112s is processed, whereby the conductive layer 112b is formed to include a region overlapping with the conductive layer 115a in a plan view. For example, a pattern is formed by a lithography method, and the conductive layer 112s is processed by a dry etching method, a wet etching method, or the like using the pattern, whereby the conductive layer 112b can be formed. Here, for microfabrication, the conductive layer 112s is preferably processed by a dry etching method.

Next, the metal oxide film to be the semiconductor layer 113b later is formed in contact with the top surface of the conductive layer 112b, the side surface of the conductive layer 112b in the opening 121b, the side surface of the insulating layer 103b in the opening 121b, the side surface of the insulating layer 135 in the opening 121b, the side surface of the insulating layer 107a in the opening 121b, and the top surface of the conductive layer 115a in the opening 121b. The metal oxide film to be the semiconductor layer 113b can be formed using the same material and the same method as those for the above-described metal oxide film to be the semiconductor layer 113a. Here, the metal oxide film to be the semiconductor layer 113b is preferably formed in contact with the side surface of the conductive layer 112b, the side surface of the insulating layer 103b, the side surface of the insulating layer 135, the side surface of the insulating layer 107a, and the top surface of the conductive layer 115a in the opening 121b with a high aspect ratio. Thus, the metal oxide film to be the semiconductor layer 113b is preferably formed by a deposition method with favorable coverage, and is further preferably formed by a CVD method, an ALD method, or the like. For example, an In—Ga—Zn oxide is deposited by an ALD method as the metal oxide film to be the semiconductor layer 113b.

In the case where the sidewall of the opening 121b is tapered, the method for depositing the metal oxide film to be the semiconductor layer 113b is not limited to a CVD method or an ALD method. For example, a sputtering method may be employed.

The semiconductor layer 113b may have a stacked-layer structure. For the method for depositing each layer in the case where the semiconductor layer 113b has a stacked-layer structure, the above description of the method for depositing each layer in the case where the semiconductor layer 113a has a stacked-layer structure can be referred to.

Here, the metal oxide film to be the semiconductor layer 113b is preferably formed in contact with the top surface of the conductive layer 115a in the opening 121b, the side surface of the insulating layer 107a in the opening 121b, the side surface of the insulating layer 135 in the opening 121b, the side surface of the insulating layer 103b in the opening 121b, the side surface of the conductive layer 112b in the opening 121b, and the top surface of the conductive layer 112b. When the metal oxide film is formed in contact with the conductive layer 115a, the conductive layer 115a, which functions as the gate electrode of the transistor 41, functions also as one of the source electrode and the drain electrode of the transistor 42.

Next, heat treatment is preferably performed. For the details of the heat treatment, the above description of the heat treatment that can be performed after the formation of the metal oxide film to be the semiconductor layer 113a can be referred to.

Next, the metal oxide film to be the semiconductor layer 113b is processed, whereby the semiconductor layer 113b is formed to include a region overlapping with the opening 121b in a plan view (FIG. 51A to FIG. 52B). For the method for forming the semiconductor layer 113b, the above description of the method for forming the semiconductor layer 113a can be referred to. Thus, the semiconductor layer 113b can be formed to include a region overlapping with the opening 121b. Thus, part of the semiconductor layer 113b is formed in the opening 121b. The semiconductor layer 113b is in contact with the top surface of the conductive layer 115a. Accordingly, the semiconductor layer 113b including a region in contact with the top surface of the conductive layer 115a in the opening 121b, a region in contact with the side surface of the insulating layer 107a in the opening 121b, a region in contact with the side surface of the insulating layer 135 in the opening 121b, a region in contact with the side surface of the insulating layer 103b in the opening 121b, a region in contact with the side surface of the conductive layer 112b in the opening 121b, and a region in contact with the top surface of the conductive layer 112b is formed.

Although FIG. 51A and FIG. 51B illustrate an example in which the end portion of the semiconductor layer 113b is formed to be substantially aligned with the end portion of the conductive layer 112b in the X direction, one embodiment of the present invention is not limited thereto. The end portion of the semiconductor layer 113b may be positioned inward from the end portion of the conductive layer 112b in the X direction. The end portion of the semiconductor layer 113b may be positioned outward from the end portion of the conductive layer 112b in the X direction, and the bottom surface of the semiconductor layer 113b may be in contact with the side surface of the conductive layer 112b on the side not facing the opening 121b and in contact with the top surface of the insulating layer 103b.

Although an example in which the semiconductor layer 113b is formed after the conductive layer 112b is formed is described above, one embodiment of the present invention is not limited thereto. For example, in one embodiment of the present invention, after the formation of the opening 121b (FIG. 49A to FIG. 50B), the metal oxide film to be the semiconductor layer 113b may be formed, the metal oxide film may be processed to form the semiconductor layer 113b, and then the conductive layer 112s may be processed to form the conductive layer 112b.

Next, the insulating layer 105b is formed in contact with the top surface of the semiconductor layer 113b (FIG. 53A to FIG. 54B). The insulating layer 105b can be formed using the same material and the same method as those for the above-described insulating layer 105a. Here, the insulating layer 105b is preferably formed in contact with the top surface of the semiconductor layer 113b in the opening 121b with a high aspect ratio. Thus, the insulating layer 105b is preferably deposited by a deposition method with favorable coverage, and is further preferably deposited by a CVD method, an ALD method, or the like. For example, silicon oxide is deposited as the insulating layer 105b by an ALD method.

In the case where the sidewall of the opening 121b is tapered, the method for depositing the insulating layer 105b is not limited to a CVD method or an ALD method. For example, a sputtering method may be employed.

When the insulating layer 105b is formed after the semiconductor layer 113b is formed, the side end portion of the semiconductor layer 113b is covered with the insulating layer 105b. Thus, a short circuit between the semiconductor layer 113b and the conductive layer 115b formed in a later step can be prevented. Furthermore, in the above-described structure, the side end portion of the conductive layer 112b is covered with the insulating layer 105b. Thus, a short circuit between the conductive layer 112b and the conductive layer 115b can be prevented.

Subsequently, a conductive film to be the conductive layer 115b is formed over the insulating layer 105b to fill the opening 121b. The conductive film to be the conductive layer 115b can be formed using the same material and the same method as those for the above-described conductive film to be the conductive layer 115a. Here, the conductive film to be the conductive layer 115b is preferably formed in contact with the insulating layer 105b provided in the opening 121b with a high aspect ratio. Thus, the conductive film to be the conductive layer 115b is preferably formed by a deposition method with favorable coverage or filling property, and is further preferably formed by a CVD method, an ALD method, or the like.

In the case where the conductive film to be the conductive layer 115b is formed by a CVD method, the top surface of the conductive film sometimes has high average surface roughness. In that case, the conductive film is preferably planarized by a CMP method. At that time, before the CMP treatment, a silicon oxide film or a silicon oxynitride film may be deposited over the conductive film and the CMP treatment may be performed until the silicon oxide film or the silicon oxynitride film is removed. Note that the CMP treatment is not necessarily performed.

Although the conductive film to be the conductive layer 115b is provided to fill the opening 121b in the above description, the present invention is not limited thereto. For example, a depressed portion reflecting the shape of the opening 121b is formed in the upper portion of the conductive film to be the conductive layer 115b in some cases. A structure may be employed in which the depressed portion is filled with an inorganic insulating material, for example. Note that the depressed portion is not necessarily filled with an inorganic insulating material or the like.

Next, part of the conductive film to be the conductive layer 115b is processed to form the conductive layer 115b (FIG. 55A to FIG. 56B). The conductive layer 115b can be formed by the same method as that for forming the above-described conductive layer 115a. The conductive layer 115b is formed over the insulating layer 105b to include a region overlapping with the semiconductor layer 113b.

In the above manner, the transistor 42 including the conductive layer 115a, the conductive layer 112b, the semiconductor layer 113b, the insulating layer 105b, and the conductive layer 115b can be formed.

As described above, the conductive layer 115a functions as one of the source electrode and the drain electrode of the transistor 42. The conductive layer 112b functions as the other of the source electrode and the drain electrode of the transistor 42. The insulating layer 105b functions as a gate insulating layer of the transistor 42. The conductive layer 115b functions as the gate electrode of the transistor 42.

In addition, the capacitor 51 can be formed which includes the conductive layer 115a, the conductive layer 141, part of the insulating layer 107a (a portion sandwiched between the conductive layer 115a and the conductive layer 141), part of the insulating layer 135 (a portion sandwiched between the conductive layer 115a and the conductive layer 141), part of the conductive layer 115b (a portion positioned in the opening 121b), and the insulating layer 103b, the semiconductor layer 113b, and the insulating layer 105b in a region sandwiched between the conductive layer 141 and the part of the conductive layer 115b.

As described above, the conductive layer 115a functions as one electrode of the capacitor 51. The conductive layer 141 functions as the other electrode of the capacitor 51. Part of the insulating layer 107 (a portion sandwiched between the conductive layer 115a and the conductive layer 141) and part of the insulating layer 135 (a portion sandwiched between the conductive layer 115a and the conductive layer 141) function as the dielectric layer of the capacitor 51.

In addition to the above, part of the conductive layer 115b (a portion positioned in the opening 121b) can function as the gate electrode of the transistor 42 and can also function as one electrode or the other electrode of the capacitor 51. The insulating layer 103b, the semiconductor layer 113b, and the insulating layer 105b in a region sandwiched between the conductive layer 141 and the part of the conductive layer 115b can function as an interlayer insulating layer, the semiconductor layer of the transistor 42, and the gate insulating layer of the transistor 42, respectively, and can also function as the dielectric layer of the capacitor 51.

Then, the insulating layer 107b is formed over the conductive layer 115b and the insulating layer 105b (FIG. 5A to FIG. 6). The insulating layer 107b can be formed using the same material and the same method as those for the above-described insulating layer 107a.

In the above manner, the memory device including the transistor 41, the transistor 42, the capacitor 51, the insulating layer 103a, and the insulating layer 103b illustrated in FIG. 5A to FIG. 6B can be manufactured.

As described above, in the memory device of one embodiment of the present invention, the transistor 41, the capacitor 51, and the transistor 42 are stacked. In each of the transistor 41 and the transistor 42, the semiconductor layer, the gate insulating layer, and the gate electrode are provided in the opening formed in the interlayer insulating layer, one of the source electrode and the drain electrode is provided under the opening, and the other of the source electrode and the drain electrode is provided over the interlayer insulating layer. Accordingly, the area occupied by the memory device in a plan view can be reduced. Thus, the memory device can be miniaturized. Therefore, one embodiment of the present invention can provide a memory device that can be highly integrated.

In the memory device of one embodiment of the present invention, the transistor 42 is not stacked to completely overlap with the transistor 41 in a plan view (which may be said that the transistor 42 is not provided such that the opening 121b completely overlaps with the opening 121a in a plan view) but is stacked to partly overlap therewith in a plan view. In other words, the transistor 42 is stacked to be positioned diagonally above the transistor 41 (which may be said that the transistor 42 is provided such that the opening 121b is positioned diagonally above the opening 121a) as illustrated in FIG. 5B and the like. In this case, as illustrated in FIG. 5A, the transistor 42 is preferably stacked over the transistor 41 such that the opening 121a and the opening 121b do not overlap with each other (i.e., the opening 121a and the opening 121b are at least slightly apart from each other) in a plan view. This enables the bottom surface of the semiconductor layer 113b in the opening 121b to be in contact with the substantially flat top surface of the conductive layer 115a; thus, there is no concern that defective contact between the semiconductor layer 113b and the conductive layer 115a is caused by the depressed portion at the top of the conductive layer 115a. Thus, a memory device with favorable electrical characteristics can be provided. In addition, a method for manufacturing a memory device with a high yield can be provided.

When the transistor 41 and the transistor 42 are in the above-described relationship of placement, the step of planarizing the top surface of the conductive layer 115a is not necessary. Thus, the total number of steps can be reduced, and an inexpensive memory device can be obtained.

In the memory device of one embodiment of the present invention, part of a component of the transistor 41 serves also as part of a component of the transistor 42. In addition, part of a component of the transistor 41 serves also as part of a component of the capacitor 51. Furthermore, part of a component of the transistor 42 serves also as part of a component of the capacitor 51.

Therefore, in the case of the memory device of one embodiment of the present invention, the number of steps can be significantly reduced as compared with the case of manufacturing the transistor 41 and the transistor 42 independently. In addition, the number of steps can be significantly reduced as compared with the case of manufacturing the capacitor 51 and the transistor 41 independently. Furthermore, the number of steps can be significantly reduced as compared with the case of manufacturing the capacitor 51 and the transistor 42 independently. Thus, an inexpensive memory device can be obtained. Furthermore, a method for manufacturing a memory device with a high yield can be provided.

This embodiment can be combined with the other embodiments as appropriate. In this specification, in the case where a plurality of structure examples are shown in one embodiment, the structure examples can be combined as appropriate.

### Embodiment 5

In this embodiment, a structure example of a memory device in which a plurality of layers each including the memory cells 741 described in the above embodiment are stacked will be described with reference to a drawing.

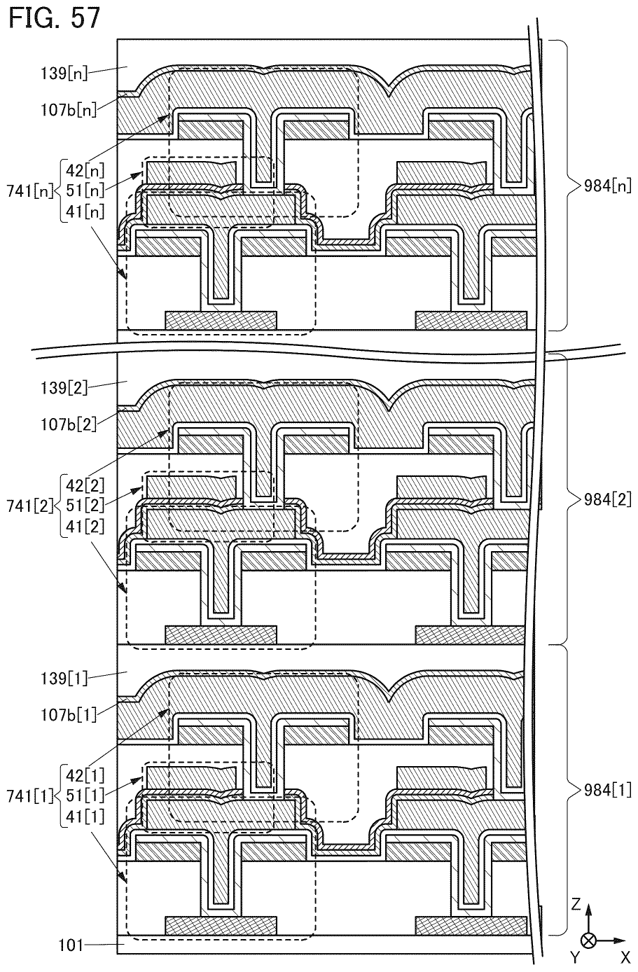

FIG. 57 is a cross-sectional view illustrating a structure example of the layer 984[1] to a layer 984[n] (n is an integer greater than or equal to 1) included in the electronic computer 900 illustrated in FIG. 1B, and illustrates an XZ plane. As illustrated in FIG. 57, the layer 984[1] is provided over the insulating layer 101, the layer 984[2] is provided over the layer 984[1], and the layer 984[n] is provided as the uppermost layer. As described above, the memory cells 741 are provided in the layers 984. FIG. 57 illustrates a structure example of the memory cells 741 in n rows and two columns. Thus, the area occupied by the memory device can be reduced. Furthermore, the memory capacity per unit area can be increased.

The memory cells 741 each include the transistor 41, the transistor 42, and the capacitor 51. In this embodiment, for example, the transistor 41, the transistor 42, and the capacitor 51 included in the layer 984[1] are referred to as a transistor 41[1], a transistor 42[1], and a capacitor 51[1], respectively; the transistor 41, the transistor 42, and the capacitor 51 included in the layer 984[2] are referred to as a transistor 41[2], a transistor 42[2], and a capacitor 51[2], respectively; and the transistor 41, the transistor 42, and the capacitor 51 included in the layer 984[n] are referred to as a transistor 41[n], a transistor 42[n], and a capacitor 51[n], respectively. The transistor 41[1], the transistor 42[1], and the capacitor 51[1] form a memory cell 741[1] in the layer 984[1]. The transistor 41[2], the transistor 42[2], and the capacitor 51[2] form a memory cell 741[2] in the layer 984[2]. The transistor 41[n], the transistor 42[n], and the capacitor 51[n] form a memory cell 741[n] in the layer 984[n]. As described above, the insulating layer 107b is provided over the transistor 42. In this embodiment, for example, the insulating layer 107b provided over the transistor 42[1] is referred to as an insulating layer 107b[1], the insulating layer 107b provided over the transistor 42[2] is referred to as an insulating layer 107b[2], and the insulating layer 107b provided over the transistor 42[n] is referred to as an insulating layer 107b[n].

Here, an insulating layer 139 functioning as an interlayer insulating layer is provided over the insulating layer 107b. In this embodiment, for example, the insulating layer 139 provided in the layer 984[1] is referred to as an insulating layer 139[1], the insulating layer 139 provided in the layer 984[2] is referred to as an insulating layer 139[2], and the insulating layer 139 provided in the layer 984[n] is referred to as an insulating layer 139[n]. The transistor 41[2] is provided over the insulating layer 139[1], for example. For the insulating layer 139, a material similar to the material that can be used for the interlayer insulating layer described in the above embodiment can be used.

This embodiment can be combined with the other embodiments as appropriate. In this specification, in the case where a plurality of structure examples are shown in one embodiment, the structure examples can be combined as appropriate.

### Embodiment 6

In this embodiment, application examples of the memory device of one embodiment of the present invention will be described with reference to drawings. The memory device of one embodiment of the present invention can be used for an electronic component, an electronic appliance, a large computer, a device for space, and a data center (also referred to as DC), for example. An electronic component, an electronic appliance, a large computer, a device for space, and a data center each employing the memory device of one embodiment of the present invention are effective in improving performance, for example, reducing power consumption.

### Electronic Component

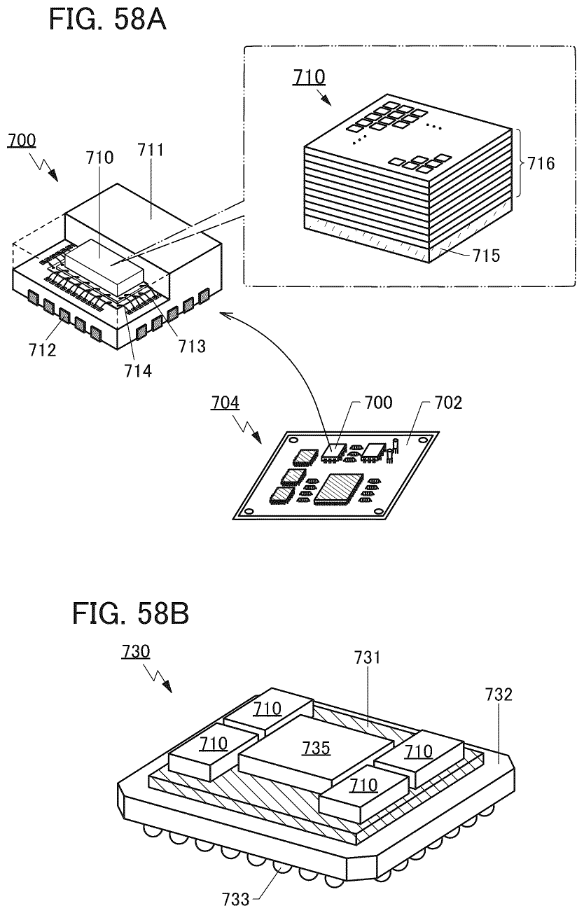

FIG. 58A illustrates a perspective view of a substrate (a mounting board 704) on which an electronic component 700 is mounted. The electronic component 700 illustrated in FIG. 58A includes a semiconductor device 710 in a mold 711. FIG. 58A omits illustrations of some parts to show the inside of the electronic component 700. The electronic component 700 includes a land 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected to each other on the printed circuit board 702, whereby the mounting board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a TSV (Through Silicon Via) and a bonding technique such as Cu-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the size of, for example, a connection wiring can be smaller than that in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer volume per unit time, and the access latency refers to a period of time from data access to the start of data transmission. Note that in the case where the memory layer 716 is formed using Si transistors, the monolithic stacked-layer structure is difficult to form compared with the case where the memory layer 716 is formed using OS transistors. Thus, the OS transistors are superior to the Si transistors in the monolithic stacked-layer structure.

The semiconductor device 710 may be referred to as a die. In this specification and the like, a die refers to each of chip pieces obtained by dividing a circuit pattern formed on, for example, a circular substrate (also referred to as a wafer) into dice in the manufacturing process of a semiconductor chip. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 58B illustrates a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU, or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. Thus, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are placed side by side on the interposer.

Meanwhile, in the case where a plurality of integrated circuits with different terminal pitches are electrically connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. In the electronic component 730 of this embodiment, the heights of the semiconductor device 710 and the semiconductor device 735 are preferably equal to each other, for example.

An electrode 733 may be provided on the bottom portion of the package substrate 732 to mount the electronic component 730 on another substrate. FIG. 58B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### Electronic Appliance

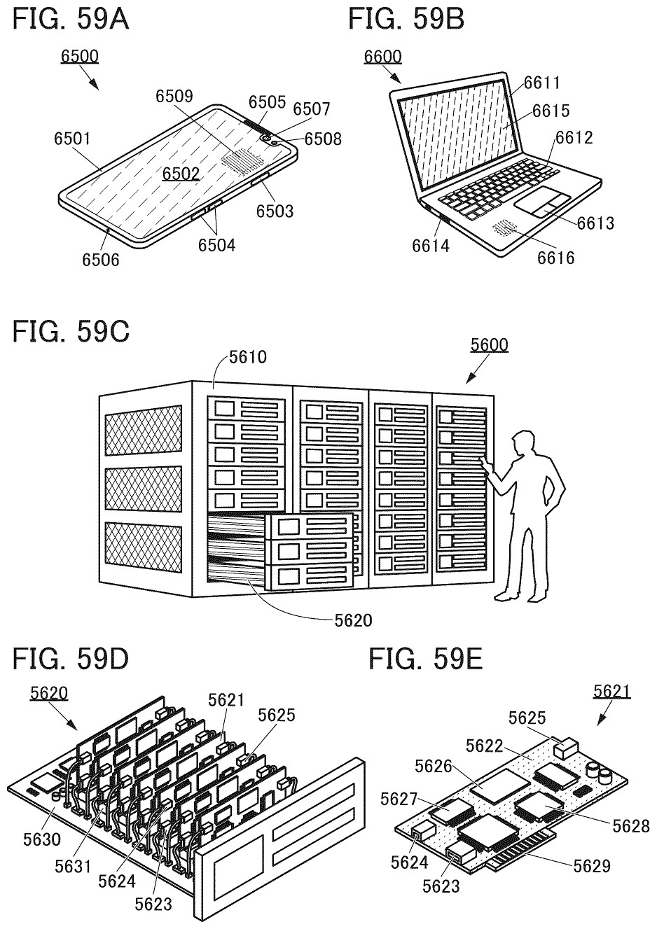

Next, FIG. 59A illustrates a perspective view of an electronic appliance 6500. The electronic appliance 6500 illustrated in FIG. 59A is a portable information terminal device that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The memory device of one embodiment of the present invention can be used for the display portion 6502, the control device 6509, and the like.

An electronic appliance 6600 illustrated in FIG. 59B is an information terminal device that can be used as a laptop personal computer. The electronic appliance 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The memory device of one embodiment of the present invention can be used for the display portion 6615, the control device 6616, and the like. Note that the memory device of one embodiment of the present invention is preferably used for the control device 6509 and the control device 6616, in which case power consumption can be reduced.

### Large Computer

Next, FIG. 59C illustrates a perspective view of a large computer 5600. In the large computer 5600 illustrated in FIG. 59C, a plurality of rack mount computers 5620 are stored in a rack 5610. Note that the large computer 5600 may be referred to as a supercomputer.

The computer 5620 can have a structure in a perspective view illustrated in FIG. 59D, for example. In FIG. 59D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 59E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 59E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### Device for Space

The memory device of one embodiment of the present invention can be suitably used for a device for space.

The memory device of one embodiment of the present invention includes an OS transistor. A change in electrical characteristics of the OS transistor due to exposure to radiation is small. That is, the OS transistor is highly resistant to radiation, and thus can be suitably used in an environment where radiation can enter. For example, the OS transistor can be suitably used in outer space. Specifically, the OS transistor can be used as a transistor included in a memory device provided in a space shuttle, an artificial satellite, or a space probe. Examples of radiation include X-rays and a neutron beam. Note that outer space refers to, for example, space at an altitude greater than or equal to 100 km, and outer space in this specification may also include one or more of thermosphere, mesosphere, and stratosphere.

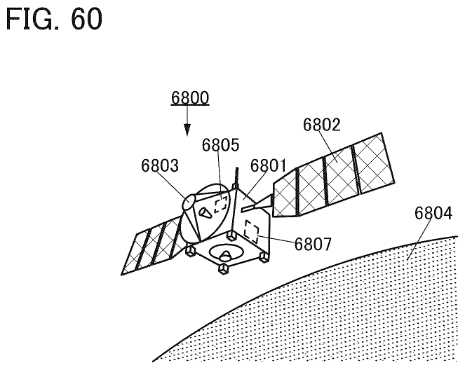

FIG. 60 illustrates an artificial satellite 6800 as an example of a device for space. The artificial satellite 6800 includes a body 6801, a solar panel 6802, an antenna 6803, a secondary battery 6805, and a control device 6807. Note that FIG. 60 illustrates a planet 6804 in outer space, for example.

Although not illustrated in FIG. 60, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Thus, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the memory device including the OS transistor, which is one embodiment of the present invention, is suitably used for the control device 6807. A change in electrical characteristics of the OS transistor due to exposure to radiation is smaller than that of a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The memory device of one embodiment of the present invention can be suitably used for a device for space such as a spacecraft, a space capsule, or a space probe, for example.

As described above, the OS transistor has excellent effects of achieving a wide memory bandwidth and being highly resistant to radiation as compared with the Si transistor.

### Data Center

The memory device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With use of the memory device of one embodiment of the present invention for a storage system in a data center, electric power required for retaining data can be reduced and a memory device for retaining data can be reduced in size. Accordingly, reductions in sizes of the storage system and the power supply for retaining data, downscaling of the cooling equipment, and the like can be achieved. Therefore, a space of the data center can be reduced.

Since the memory device of one embodiment of the present invention has low power consumption, heat generation from a circuit can be reduced. Accordingly, adverse effects of the heat generation on the circuit itself, the peripheral circuit, and the module can be reduced. Furthermore, the use of the memory device of one embodiment of the present invention can achieve a data center that operates stably even in a high temperature environment. Thus, the reliability of the data center can be improved.

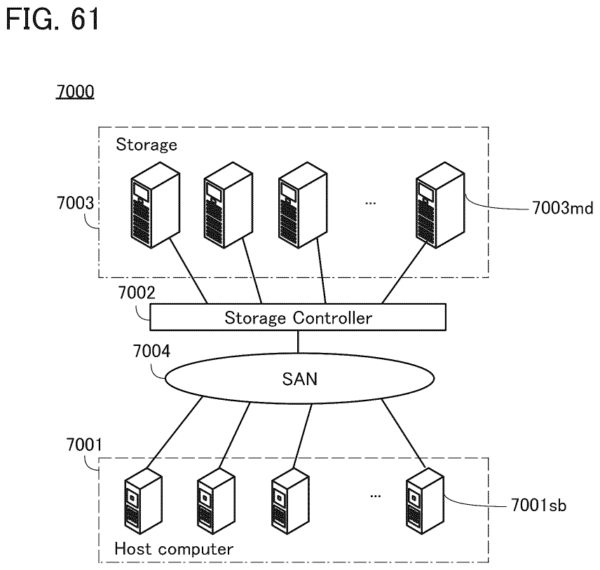

FIG. 61 illustrates a storage system that can be used in a data center. A storage system 7000 illustrated in FIG. 61 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the time required for a DRAM that can be used as a cache memory in the storage. In the storage system, in order to solve the problem of low access speed of the storage 7003, a cache memory is normally provided in the storage to shorten data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on the data can reduce the frequency of refreshing, so that power consumption can be reduced. Furthermore, downscaling is possible by stacking memory cell arrays.

The use of the memory device of one embodiment of the present invention for one or more selected from an electronic component, an electronic appliance, a large computer, a device for space, and a data center can be expected to produce an effect of reducing power consumption. Although demand for energy will increase with increasing performance and integration degree of memory devices, the use of the memory device of one embodiment of the present invention can thus reduce the emission amount of greenhouse gas typified by carbon dioxide (CO₂). Furthermore, the memory device of one embodiment of the present invention has low power consumption and thus is effective as a global warming countermeasure.

This embodiment can be combined with the other embodiments as appropriate.

### REFERENCE NUMERALS

41[1]: transistor, 41[2]: transistor, 41[n]: transistor, 41: transistor, 42[1]: transistor, 42[2]: transistor, 42[n]: transistor, 42: transistor, 51[1]: capacitor, 51[2]: capacitor, 51[n]: capacitor, 51: capacitor, 101: insulating layer, 103a: insulating layer, 103b: insulating layer, 103: insulating layer, 105a: insulating layer, 105b: insulating layer, 105: insulating layer, 107a: insulating layer, 107b[1]: insulating layer, 107b[2]: insulating layer, 107b[n]: insulating layer, 107b: insulating layer, 107: insulating layer, 111a: conductive layer, 112a: conductive layer, 112f: conductive layer, 112s: conductive layer, 112A: conductive film, 112b: conductive layer, 112B: conductive film, 112: conductive layer, 113a: semiconductor layer, 113b: semiconductor layer, 113i: region, 113na: region, 113nb: region, 113: semiconductive layer, 115a: conductive layer, 115b: conductive layer, 115: conductive layer, 121a: opening, 121b: opening, 121: opening, 127: opening, 135: insulating layer, 139[1]: insulating layer, 139[2]: insulating layer, 139[n]: insulating layer, 139: insulating layer, 141f: conductive film, 141: conductive layer, 700: electronic component, 702: printed circuit board, 704: mounting board, 710: semiconductor device, 711: mold, 712: land, 713: electrode pad, 714: wire, 715: driver circuit layer, 716: memory layer, 717: memory unit, 718[1]: memory block, 718[N]: memory block, 718: memory block, 720: memory device, 721L1: memory array, 721L2: memory array, 721L3: memory array, 721: memory array, 722L1: deriver circuit, 722L2: driver circuit, 722L3: driver circuit, 722: driver circuit, 723[1]: memory subarray, 723[R]: memory subarray, 723: memory subarray, 724: word line driver, 725: column driver, 726: sense amplifier driver, 727: data driver, 728: memory controller, 730: electronic component, 731: interposer, 732: package substrate, 733: electrode, 735: semiconductor device, 736: sub-sensing circuit, 737: switch circuit, 741a: memory cell, 741b: memory cell, 741c: memory cell, 741d: memory cell, 741[1]: memory cell, 741[2]: memory cell, 741[n]: memory cell, 741: memory cell, 751: sensing circuit, 752: switch circuit, 753: precharge circuit, 754: precharge circuit, 755: amplifier circuit, 756: precharge circuit, 761: power switch, 762: power switch, 771: peripheral circuit, 772: control circuit, 773: voltage generation circuit, 781: peripheral circuit, 782: row decoder, 783: row driver, 784: column decoder, 785: column driver, 786: data driver, 787: input circuit, 788: output circuit, 810: semiconductor device, 830: backup circuit, 831[1]: retention circuit, 831[2]: retention circuit, 831[4]: retention circuit, 831[G]: retention circuit, 831: retention circuit, 850: scan flip-flop circuit, 851: selector circuit, 852: flip-flop circuit, 900: electronic computer, 910: processing portion, 911: arithmetic portion, 912: control portion, 913: register portion, 914: register unit, 915: scan flip-flop, 916: backup memory, 920: memory portion, 921: memory array portion, 922: control portion, 923: memory block, 924: memory unit, 925: memory cell, 926: sense amplifier, 930: control portion, 933L1: Layer, 933L2: layer, 933L3: layer, 933: layer, 940L1: connection electrode, 940L2: connection electrode, 940L3: connection electrode, 960: arithmetic device, 970A: semiconductor device, 970B: semiconductor device, 970C: semiconductor device, 971: bus line, 982[1]: layer, 982[L]: layer, 982: layer, 983[1]: layer, 983[H]: layer, 983: layer, 984[1]: layer, 984[2]: layer, 984[K]: layer, 984[n]: layer, 984: layer, 985: layer, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage, 7004: storage area network

1. A semiconductor device comprising:
a first transistor, a second transistor, and a capacitor; and
a first insulating layer and a second insulating layer,
wherein the second transistor is provided over and overlapping with the first transistor,
wherein the capacitor is provided over and overlapping with the first transistor,
wherein a distance from a substrate to the source electrode of the first transistor and a distance from the substrate to the drain electrode of the first transistor are different from each other,
wherein the first insulating layer is provided between the source electrode and the drain electrode of the first transistor and comprises a first opening reaching one of the source electrode and the drain electrode of the first transistor,
wherein the other of the source electrode and the drain electrode of the first transistor is provided over the first insulating layer,
wherein a semiconductor layer of the first transistor comprises a region in contact with a top surface of the one of the source electrode and the drain electrode of the first transistor in the first opening, a side surface of the first insulating layer in the first opening, and a top surface of the other of the source electrode and the drain electrode of the first transistor,
wherein a gate insulating layer of the first transistor is provided over and in contact with the semiconductor layer of the first transistor,
wherein a gate electrode of the first transistor is provided over the gate insulating layer of the first transistor to comprise a region overlapping with the semiconductor layer of the first transistor and is configured to serve as one of the source electrode and the drain electrode of the second transistor and as one electrode of the capacitor,
wherein the second insulating layer is provided between the source electrode and the drain electrode of the second transistor and comprises a second opening reaching the gate electrode of the first transistor,
wherein the second opening is positioned diagonally above the first opening,
wherein the other of the source electrode and the drain electrode of the second transistor is provided over the second insulating layer,
wherein a semiconductor layer of the second transistor comprises a region in contact with a top surface of the gate electrode of the first transistor in the second opening, a side surface of the second insulating layer in the second opening, and a top surface of the other of the source electrode and the drain electrode of the second transistor,
wherein a gate insulating layer of the second transistor is provided over and in contact with the semiconductor layer of the second transistor,
wherein a gate electrode of the second transistor is provided over the gate insulating layer of the second transistor to comprise a region overlapping with the semiconductor layer of the second transistor,
wherein a dielectric layer of the capacitor is provided over the gate electrode of the first transistor, and
wherein the other electrode of the capacitor comprises a region overlapping with the gate electrode of the first transistor and is provided over the dielectric layer of the capacitor and apart from the second opening in a plan view.

2. The semiconductor device according to claim 1, wherein at least one of the semiconductor layer of the first transistor and the semiconductor layer of the second transistor comprises a metal oxide.

3. The semiconductor device according to claim 1, further comprising:
a region in which a side surface of the semiconductor layer of the first transistor is aligned or substantially aligned with a side surface of the other of the source electrode and the drain electrode of the first transistor; and
a region in which a side surface of the semiconductor layer of the second transistor is aligned or substantially aligned with a side surface of the other of the source electrode and the drain electrode of the second transistor.

4. The semiconductor device according to claim 1, wherein an end portion of the other electrode of the capacitor on a side not facing the first opening is positioned outward from an end portion of the gate electrode of the first transistor.

5. The semiconductor device according to claim 1, wherein the other electrode of the capacitor comprises a region overlapping with the top surface of the gate electrode of the first transistor to surround the second opening.

6. The semiconductor device according to claim 1,
wherein an end portion of the gate electrode of the first transistor is positioned inward from an end portion of the other of the source electrode and the drain electrode of the first transistor in a first direction, and comprises a region that comprises a flat or substantially flat top surface and is positioned outward from an end portion of the other of the source electrode and the drain electrode of the first transistor in a second direction opposite to the first direction, and
wherein the second opening is provided to overlap with the region in a plan view.

7. The semiconductor device according to claim 1, wherein the dielectric layer of the capacitor comprises any of an oxide comprising any of aluminum, gallium, hafnium, tantalum, and zirconium, an oxide comprising hafnium and zirconium, an oxide comprising aluminum and hafnium, an oxynitride comprising aluminum and hafnium, an oxide comprising silicon and hafnium, an oxynitride comprising silicon and hafnium, and a nitride comprising silicon and hafnium.

8. The semiconductor device according to claim 1, wherein the dielectric layer of the capacitor comprises any of hafnium oxide, zirconium oxide, lead titanate, barium strontium titanate, strontium titanate, lead zirconate titanate, strontium bismuth tantalate, bismuth ferrite, and barium titanate, or any of hafnium oxide, zirconium oxide, lead titanate, barium strontium titanate, strontium titanate, lead zirconate titanate, strontium bismuth tantalate, bismuth ferrite, and barium titanate to which lanthanum or yttrium is added.

9. The semiconductor device according to claim 1, wherein the first insulating layer and the second insulating layer each comprise any of silicon oxide, silicon oxynitride, silicon nitride oxide, polyester, polyolefin, polyamide, polyimide, polycarbonate, and acrylic.

10. A method for manufacturing a semiconductor device, comprising:
forming a first conductive layer;
forming a first insulating layer and a first conductive film over the first conductive layer;
processing the first insulating layer and the first conductive film to form a second conductive layer from the first conductive film and to form a first opening reaching the first conductive layer in the first conductive film and the first insulating layer;
processing the second conductive layer to form a third conductive layer;
forming a first metal oxide film in contact with a top surface of the first conductive layer in the first opening, a side surface of the first insulating layer in the first opening, a side surface of the third conductive layer in the first opening, and a top surface of the third conductive layer;
processing the first metal oxide film to form a first semiconductor layer comprising a region overlapping with the first opening;
forming a second insulating layer in contact with a top surface of the first semiconductor layer;
forming a second conductive film over the second insulating layer;
processing the second conductive film to form a fourth conductive layer comprising a region overlapping with the first semiconductor layer;
forming a third insulating layer over the fourth conductive layer and the second insulating layer;
forming a third conductive film over the third insulating layer;
processing the third conductive film to form a fifth conductive layer comprising a region overlapping with the fourth conductive layer;
forming a fourth insulating layer and a fourth conductive film over the fifth conductive layer and the third insulating layer;
processing the fourth insulating layer and the fourth conductive film to form a sixth conductive layer from the fourth conductive film and to form, in the fourth conductive film and the fourth insulating layer, a second opening overlapping with a flat or substantially flat top surface of the fourth conductive layer so as to be apart from the fifth conductive layer in a plan view;
processing the sixth conductive layer to form a seventh conductive layer;
forming a second metal oxide film in contact with a top surface of the fourth conductive layer in the second opening, a side surface of the third insulating layer in the second opening, a side surface of the seventh conductive layer in the second opening, and a top surface of the seventh conductive layer;
processing the second metal oxide film to form a second semiconductor layer comprising a region overlapping with the second opening;
forming a fifth insulating layer in contact with a top surface of the second semiconductor layer;
forming a fifth conductive film over the fifth insulating layer; and
processing the fifth conductive film to form an eighth conductive layer comprising a region overlapping with the second semiconductor layer.

11. A method for manufacturing a semiconductor device, comprising:
forming a first conductive layer;
forming a first insulating layer and a first conductive film over the first conductive layer;
processing the first insulating layer and the first conductive film to form a second conductive layer from the first conductive film and to form a first opening reaching the first conductive layer in the first conductive film and the first insulating layer;
forming a first metal oxide film in contact with a top surface of the first conductive layer in the first opening, a side surface of the first insulating layer in the first opening, a side surface of the second conductive layer in the first opening, and a top surface of the second conductive layer;
processing the first metal oxide film to form a first semiconductor layer comprising a region overlapping with the first opening;
processing the second conductive layer to form a third conductive layer comprising a region overlapping with the first semiconductor layer;
forming a second insulating layer in contact with a top surface of the first semiconductor layer;
forming a second conductive film over the second insulating layer;
processing the second conductive film to form a fourth conductive layer comprising a region overlapping with the first semiconductor layer;
forming a third insulating layer over the fourth conductive layer and the second insulating layer;
forming a third conductive film over the third insulating layer;
processing the third conductive film to form a fifth conductive layer comprising a region overlapping with the fourth conductive layer;
forming a fourth insulating layer and a fourth conductive film over the fifth conductive layer and the third insulating layer;
processing the fourth insulating layer and the fourth conductive film to form a sixth conductive layer from the fourth conductive film and to form, in the fourth conductive film and the fourth insulating layer, a second opening overlapping with a flat or substantially flat top surface of the fourth conductive layer so as to be apart from the fifth conductive layer in a plan view;
forming a second metal oxide film in contact with a top surface of the fourth conductive layer in the second opening, a side surface of the third insulating layer in the second opening, a side surface of the fourth insulating layer in the second opening, a side surface of the sixth conductive layer in the second opening, and a top surface of the sixth conductive layer;
processing the second metal oxide film to form a second semiconductor layer comprising a region overlapping with the second opening;
processing the sixth conductive layer to form a seventh conductive layer comprising a region overlapping with the second semiconductor layer;
forming a fifth insulating layer in contact with a top surface of the second semiconductor layer;
forming a fifth conductive film over the fifth insulating layer; and
processing the fifth conductive film to form an eighth conductive layer comprising a region overlapping with the second semiconductor layer.

12. A semiconductor device comprising:
a memory portion and a processing portion,
wherein the memory portion comprises a memory device and a sense amplifier,
wherein the processing portion comprises a CPU, an MPU, or a GPU,
wherein the sense amplifier and the processing portion are placed on a first layer,
wherein the memory device is placed on a second layer and comprises a first transistor, a second transistor, a capacitor, a first insulating layer, and a second insulating layer,
wherein the second layer is stacked over the first layer,
wherein the second transistor is provided over and overlapping with the first transistor,
wherein the capacitor is provided over and overlapping with the first transistor,
wherein a distance from a substrate to the source electrode of the first transistor and a distance from the substrate to the drain electrode of the first transistor are different from each other,
wherein the first insulating layer is provided between the source electrode and the drain electrode of the first transistor and comprises a first opening reaching one of the source electrode and the drain electrode of the first transistor,
wherein the other of the source electrode and the drain electrode of the first transistor is provided over the first insulating layer,
wherein a semiconductor layer of the first transistor comprises a region in contact with a top surface of the one of the source electrode and the drain electrode of the first transistor in the first opening, a side surface of the first insulating layer in the first opening, and a top surface of the other of the source electrode and the drain electrode of the first transistor,
wherein a gate insulating layer of the first transistor is provided over and in contact with the semiconductor layer of the first transistor,
wherein a gate electrode of the first transistor is provided over the gate insulating layer of the first transistor to comprise a region overlapping with the semiconductor layer of the first transistor and is configured to serve as one of the source electrode and the drain electrode of the second transistor and as one electrode of the capacitor,
wherein the second insulating layer is provided between the source electrode and the drain electrode of the second transistor and comprises a second opening reaching the gate electrode of the first transistor,
wherein the second opening is positioned diagonally above the first opening,
wherein the other of the source electrode and the drain electrode of the second transistor is provided over the second insulating layer,
wherein a semiconductor layer of the second transistor comprises a region in contact with a top surface of the gate electrode of the first transistor in the second opening, a side surface of the second insulating layer in the second opening, and a top surface of the other of the source electrode and the drain electrode of the second transistor,
wherein a gate insulating layer of the second transistor is provided over and in contact with the semiconductor layer of the second transistor,
wherein a gate electrode of the second transistor is provided over the gate insulating layer of the second transistor so as to comprise a region overlapping with the semiconductor layer of the second transistor,
wherein a dielectric layer of the capacitor is provided over the gate electrode of the first transistor, and
wherein the other electrode of the capacitor comprises a region overlapping with the gate electrode of the first transistor and is provided over the dielectric layer of the capacitor and apart from the second opening in a plan view.

13. The semiconductor device according to claim 12, wherein at least one of the semiconductor layer of the first transistor and the semiconductor layer of the second transistor comprises a metal oxide.

14. The semiconductor device according to claim 12, further comprising:
a region in which a side surface of the semiconductor layer of the first transistor is aligned or substantially aligned with a side surface of the other of the source electrode and the drain electrode of the first transistor; and
wherein a region in which a side surface of the semiconductor layer of the second transistor is aligned or substantially aligned with a side surface of the other of the source electrode and the drain electrode of the second transistor.

15. The semiconductor device according to claim 12, wherein an end portion of the other electrode of the capacitor on a side not facing the first opening is positioned outward from an end portion of the gate electrode of the first transistor.

16. The semiconductor device according to claim 12, wherein the other electrode of the capacitor comprises a region overlapping with the top surface of the gate electrode of the first transistor to surround the second opening.

17. The semiconductor device according to claim 12,
wherein an end portion of the gate electrode of the first transistor is positioned inward from an end portion of the other of the source electrode and the drain electrode of the first transistor in a first direction, and comprises a region that comprises a flat or substantially flat top surface and is positioned outward from an end portion of the other of the source electrode and the drain electrode of the first transistor in a second direction opposite to the first direction, and
wherein the second opening is provided to overlap with the region in a plan view.

18. The semiconductor device according to claim 12, wherein the dielectric layer of the capacitor comprises any of an oxide comprising any of aluminum, gallium, hafnium, tantalum, and zirconium, an oxide comprising hafnium and zirconium, an oxide comprising aluminum and hafnium, an oxynitride comprising aluminum and hafnium, an oxide comprising silicon and hafnium, an oxynitride comprising silicon and hafnium, and a nitride comprising silicon and hafnium.

19. The semiconductor device according to claim 12, wherein the dielectric layer of the capacitor comprises any of hafnium oxide, zirconium oxide, lead titanate, barium strontium titanate, strontium titanate, lead zirconate titanate, strontium bismuth tantalate, bismuth ferrite, and barium titanate, or any of hafnium oxide, zirconium oxide, lead titanate, barium strontium titanate, strontium titanate, lead zirconate titanate, strontium bismuth tantalate, bismuth ferrite, and barium titanate to which lanthanum or yttrium is added.

20. The semiconductor device according to claim 12, wherein the first insulating layer and the second insulating layer each comprise any of silicon oxide, silicon oxynitride, silicon nitride oxide, polyester, polyolefin, polyamide, polyimide, polycarbonate, and acrylic.
